(19) United States
(12) Patent Application Publication
(10) Pub. No.: US 2013/0286146 A1
(43) Pub. Date: Oct. 31, 2013

(54) PLASTIC ROD LENS, PLASTIC ROD LENS ARRAY, COLOR IMAGE SENSOR HEAD, AND LED PRINTER HEAD

(71) Applicants: Masafumi Kitamura, Otake-shi (JP); Kikue Irie, Otake-shi (JP); Yoshikazu Saito, Toyohashi-shi (JP); Ryuichi Ansai, Toyohashi-shi (JP); Hiroyuki Nogami, Yokohama-shi (JP); Yasushi Kawaharada, Otake-shi (JP); Takashi Saeki, Otake-shi (JP)

(72) Inventors: Masafumi Kitamura, Otake-shi (JP); Kikue Irie, Otake-shi (JP); Yoshikazu Saito, Toyohashi-shi (JP); Ryuichi Ansai, Toyohashi-shi (JP); Hiroyuki Nogami, Yokohama-shi (JP); Yasushi Kawaharada, Otake-shi (JP); Takashi Saeki, Otake-shi (JP)

(73) Assignee: Mitsubishi Rayon Co., Ltd., Tokyo (JP)

(21) Appl. No.: 13/978,288

(22) PCT Filed: Jan. 6, 2012
(86) PCT No.: PCT/JP2012/050190

§ 371 Date: Jul. 10, 2013

(30) Foreign Application Priority Data
Jan. 6, 2011 (JP) 2011-001496
Jan. 6, 2011 (JP) 2011-001497

(51) Int. Cl. G02B 1/04; H01L 27/146; G02B 3/00

(52) U.S. Cl. CPC G02B 1/041; G02B 3/0087; G02B 3/0037; H01L 27/14625
USPC 347/224; 359/654; 250/208.1

(57) ABSTRACT

A transparent plastic rod lens which has a cylindrical shape with a radius r in which a refractive index n_{D} is reduced from a center thereof to an outer periphery thereof, the plastic rod lens includes a polymer mixture (I), in which the polymer mixture (I) includes, as constitutional units, an aromatic ring-containing monomer (a) unit and at least one monomer unit selected from a group consisting of a (meth)acrylate (b) unit which has a branched hydrocarbon group having 3 or more carbon atoms, a fluorine-containing monomer (c) unit, and an alicyclic ring-containing (meth)acrylate (d) unit, and a glass transition temperature is higher than or equal to 100° C.

### TECHNICAL FIELD

The present invention relates to a plastic rod lens which is desirable as an optical transmission medium for light emitting diode printers or as an optical transmission medium for copying machines, a plastic rod lens array, a color image sensor head, and an LED printer head.

Priority is claimed on Japanese Patent Application No. 2011-001496 and Japanese Patent Application No. 2011-001497, filed Jan. 6, 2011, the contents of which are incorporated herein by reference.

### BACKGROUND ART

A rod lens is a cylindrical lens having a refractive index distribution in which a refractive index is continuously reduced from the center toward the outer periphery.

This rod lens may be used in the form of a rod lens array in which plural rod lenses are arranged in one or two or more lines such that central axes of the rod lenses are substantially parallel to each other; and the rod lenses are bonded and fixed between two substrates. The rod lens array is widely used as an image sensor component in various scanners such as a hand scanner, copying machines, fax machines, and the like; or as an optical transmission medium in writing devices such as a light emitting diode (LED) printer and the like.

The rod lens includes a glass rod lens and a plastic rod lens. In particular, a plastic rod lens is widely used in a home multi-function machine and the like from the viewpoints that use of heavy metal as a raw material is not necessary; and an environmental load is small.

Incidentally, in recent years, demand for a plastic rod lens has been increased for use in LED printers, copying machines, and the like. However, a rod lens with a high light intensity is required for LED printers, and a rod lens with a small chromatic aberration is required for copying machines.

In order to meet these requirements, a plastic rod lens has been studied in the related art.

For example, PTL 1 discloses a plastic rod lens in which, when light sources of three primary colors (RGB) or a white light source is used as a light source, a clear color image can be transmitted with a small number of light sources in a small space

In addition, for example, PTL 2 discloses a plastic rod lens which has excellent color characteristics, that is, which has a small chromatic aberration and is suitable for copying machines.

### CITATION LIST

### Patent Literature

[PTL 1] Japanese Unexamined Patent Application, First Publication No. H11-352307
[PTL 2] PCT International Publication No. WO 2007/011013

### SUMMARY OF INVENTION

### Technical Problem

However, recently, an increase in the print speed of LED printers and copying machines and a reduction in the size of the apparatuses have been rapidly progressed. Correspondingly, the temperature in the usage environment of a rod lens increases and thus, a plastic rod lens of the related art is intolerable for the use. That is, when a plastic rod lens of the related art is used in a high-temperature environment, there is a problem in that optical characteristics such as resolution and light intensity deteriorate.

A first object of the present invention is to provide a plastic rod lens which can be used in a high-temperature environment, has excellent heat resistance, and is transparent; and a rod lens array.

In addition, a second object of the present invention is to provide a plastic rod lens which has a high light intensity, has excellent heat resistance, and is suitable for LED printers; and a rod lens array.

In addition, a third object of the present invention is to provide a plastic rod lens which has a small chromatic aberration, has excellent heat resistance, and is suitable for copying machines; and a rod lens array.

### Solution to Problem

A first aspect of the present invention relates to a plastic rod lens, a rod lens array having the rod lens, and a color image sensor head and an LED printer head having the rod lens array.

In this aspect, the plastic rod lens is a transparent plastic rod lens which has a cylindrical shape with a radius r in which a refractive index n_{D} is reduced from a center thereof to an outer periphery thereof, the plastic rod lens including

a polymer mixture (I),

wherein the polymer mixture (I) includes, as constitutional units,

an aromatic ring-containing monomer (a) unit and

at least one monomer unit selected from a group consisting of a (meth)acrylate (b) unit which has a branched hydrocarbon group having 3 or more carbon atoms, a fluorine-containing monomer (c) unit, and an alicyclic ring-containing (meth)acrylate (d) unit, and

a glass transition temperature is higher than or equal to 100° C.

A second aspect of the present invention relates to a plastic rod lens, a rod lens array having the rod lens, and an LED printer head having the rod lens array.

In this aspect, the plastic rod lens is the plastic rod lens according to the first aspect in which the polymer mixture (I) is a polymer mixture (II) which includes, as constitutional units, the (a) unit and at least one of the (b) unit and the (c) unit,

a difference in refractive index between a center portion and an outer peripheral portion is 0.02 to 0.06, and

compositions of the constitutional units of the polymer mixture (II) satisfy the following expression (1) at any position in a range of 0 to r from the center to the outer periphery.

0.357[b]−1.786<[a]<65−1.063[b] (1)

(wherein in the expression (1), [a] represents the content (mass %) of the constitutional unit (a); and [b] represents the content (mass %) of the constitutional unit (b))

A third aspect of the present invention relates to a plastic rod lens, a rod lens array having the rod lens, and a color image sensor head having the rod lens array.

In this aspect, the plastic rod lens is the plastic rod lens according to the first aspect in which the polymer mixture (I) is a polymer mixture (III) which includes, as constitutional units, the (a) unit, the (b) unit, and the (d) unit,

refractive indices and Abbe numbers satisfy the following expression (4) at different arbitrary positions α and β in a range of 0 to r from the center to the outer periphery, and

|{n_{α}×ν_{α}/(n_{α}−1)}−{n_{β}×ν_{β}/(n_{β}−1)}|<5 (4)

(wherein n_{α} and n_{β} represent the refractive indices n_{D} at the positions α and β, respectively; and ν_{α} and ν_{β} represent the Abbe numbers at the positions α and β, respectively)

compositions of the constitutional units of the polymer mixture (III) satisfy the following expression (5) at any position in a range of 0 to r from the center to the outer periphery

0.5[b]−10<[a]<72.5−1.75[b] (5)

(wherein, in the expression (5), [a] represents the content (mass %) of the constitutional unit (a); and [b] represents the content (mass %) of the constitutional unit (b))

As solutions to the above-described problems, the present invention adopts the following configurations.

[1] A transparent plastic rod lens which has a cylindrical shape with a radius r in which a refractive index n_{D} is reduced from a center thereof to an outer periphery thereof, the plastic rod lens comprising

a polymer mixture (I),

wherein the polymer mixture (I) includes, as constitutional units,

an aromatic ring-containing monomer (a) unit and

at least one monomer unit selected from a group consisting of a (meth)acrylate (b) unit which has a branched hydrocarbon group having 3 or more carbon atoms, a fluorine-containing monomer (c) unit, and an alicyclic ring-containing (meth)acrylate (d) unit, and

a glass transition temperature is higher than or equal to 100° C.

[2] The plastic rod lens according to [1],

wherein the polymer mixture (I) further includes a methyl methacrylate (m) unit as a constitutional unit.

[3] The plastic rod lens according to [1],

wherein the polymer mixture (I) is a polymer mixture (II) which includes, as constitutional units, the (a) unit and at least one of the (b) unit and the (c) unit,

a difference in refractive index between a center portion and an outer peripheral portion is 0.02 to 0.06, and

compositions of the constitutional units of the polymer mixture (II) satisfy the following expression (1) at any position in a range of 0 to r from the center to the outer periphery.

0.357[b]−1.786<[a]<65−1.063[b] (1)

(wherein in the expression (1), [a] represents the content (mass %) of the constitutional unit (a); and [b] represents the content (mass %) of the constitutional unit (b))

[4] The plastic rod lens according to [3],

wherein the polymer mixture (II) further includes a methyl methacrylate (m) unit as a constitutional unit.

[5] The plastic rod lens according to [3],

wherein the (a) unit is phenyl methacrylate,

the (b) unit is at least one selected from a group consisting of t-butyl methacrylate, isobutyl methacrylate, and isopropyl methacrylate, and

the (c) unit is 2,2,3,3-tetrafluoropropyl methacrylate.

[6] The plastic rod lens according to [3],

wherein the content [a] of the (a) unit in the polymer mixture (II) is 10 mass % to 60 mass % at any position in a range of 0 to 0.5r from the center to the outer periphery, and

the content [c] of the (c) unit in the polymer mixture (II) is 5 mass % to 45 mass % at any position in a range of 0.8r to r from the center to the outer periphery.

[7] The plastic rod lens according to [3],

wherein compositions of the constitutional units of the polymer mixture (II) satisfy the following expression (2) at any position in a range of 0.8r to r from the center to the outer periphery.

[c]<47.143−0.429[b] (2)

(wherein in the expression (2), [b] represents the content (mass %) of the constitutional unit (b); and [c] represents the content (mass %) of the constitutional unit (c))

[8] The plastic rod lens according to [3],

wherein compositions of the constitutional units of the polymer mixture (II) satisfy the following expression (3) at any position in a range of 0 to 0.8r from the center to the outer periphery.

[c]<21.786−0.357[b] (3)

(wherein in the expression (3), [b] represents the content (mass %) of the constitutional unit (b); and [c] represents the content (mass %) of the constitutional unit (c))

[9] The plastic rod lens according to [1],

wherein the polymer mixture (I) is a polymer mixture (III) which includes, as constitutional units, the (a) unit, the (b) unit, and the (d) unit,

refractive indices and Abbe numbers satisfy the following expression (4) at different arbitrary positions α and β in a range of 0 to r from the center to the outer periphery, and

|{n_{α}×ν_{α}/(n_{α}−1)}−{n_{β}×ν_{β}/(n_{β}−1)}|<5 (4)

(wherein n_{α} and n_{β} represent the refractive indices n_{D} at the positions α and β, respectively; and ν_{α} and ν_{β} represent the Abbe numbers at the positions α and β, respectively)

compositions of the constitutional units of the polymer mixture (III) satisfy the following expression (5) at any position in a range of 0 to r from the center to the outer periphery

0.5[b]−10<[a]<72.5−1.75[b] (5)

(wherein, in the expression (5), [a] represents the content (mass %) of the constitutional unit (a); and [b] represents the content (mass %) of the constitutional unit (b))

[10] The plastic rod lens according to [9],

wherein the polymer mixture (III) further includes a methyl methacrylate (m) unit as a constitutional unit.

[11] The plastic rod lens according to [9],

wherein the (a) unit is phenyl methacrylate,

the (b) unit is at least one selected from a group consisting of t-butyl methacrylate, isobutyl methacrylate, and isopropyl methacrylate, and

the (d) unit is tricyclo[5.2.1.0^{2,6}]decanyl methacrylate.

[12] The plastic rod lens according to [9],

wherein the content [a] of the (a) unit in the polymer mixture (III) is 5 mass % to 72.5 mass % and the content [b] of the (b) unit in the polymer mixture (III) is 2 mass % to 36.7 mass % in a range of 0.5r to r from the center to the outer periphery

[13] A plastic rod lens array comprising

at least one rod lens line that is provided between two substrates,

wherein the rod lens line is formed by arranging a plurality of the plastic rod lenses according to [1] such that central axes of the plastic rod lenses are substantially parallel to each other.

[14] A plastic rod lens array comprising

at least one rod lens line that is provided between two substrates,

wherein the rod lens line is formed by arranging a plurality of the plastic rod lenses according to [3] such that central axes of the plastic rod lenses are substantially parallel to each other.

[15] A plastic rod lens array comprising

at least one rod lens line that is provided between two substrates,

wherein the rod lens line is formed by arranging a plurality of the plastic rod lenses according to [9] such that central axes of the plastic rod lenses are substantially parallel to each other.

[16] A color image sensor head into which the plastic rod lens array according to [13] is incorporated.

[17] An LED printer head into which the plastic rod lens array according to [13] is incorporated.

[18] An LED printer head into which the plastic rod lens array according to [14] is incorporated.

[19] A color image sensor head into which the plastic rod lens array according to [15] is incorporated.

### Advantageous Effects of Invention

The plastic rod lens, the plastic rod lens array, and the color image sensor head and the LED printer head having the plastic rod lens according to the present invention have excellent transparency and excellent heat resistance. Therefore, since deterioration in optical characteristics is small even after use in a high-temperature environment, they can be suitably used in various optical uses.

In addition, the plastic rod lens, the plastic rod lens array, and the LED printer head having the plastic rod lens according to the present invention have excellent transparency, a high lens light intensity, and excellent heat resistance. Therefore, since a high resolution can be maintained even after use in a high-temperature environment, they can be suitably used for a writing member for LED printers.

In addition, the plastic rod lens, the plastic rod lens array, and the color image sensor head having the plastic rod lens according to the present invention have excellent transparency and a small chromatic aberration. In addition, since a high resolution can be maintained even after use in a high-temperature environment, they can be suitably used for a reading member for copying machines.

### BRIEF DESCRIPTION OF DRAWINGS

FIG. 1 is a cross-sectional view illustrating an example of a cross-section perpendicular to the central axis of a plastic rod lens according to the present invention.

FIG. 2 is a diagram schematically illustrating a configuration example of a device for manufacturing a base fiber of a plastic rod lens.

FIG. 3 is a diagram schematically illustrating a configuration example of a device for subjecting a base fiber of a plastic rod lens to heating drawing and relaxing.

FIG. 4 is a cross-sectional view illustrating an example of a plastic rod lens array according to the present invention.

FIG. 5 is a triangular phase diagram illustrating the transparency of a polymer mixture containing 0% of monomer (b) unit.

FIG. 6 is a triangular phase diagram illustrating the transparency of a polymer mixture containing 5% of the monomer (b) unit.

FIG. 7 is a triangular phase diagram illustrating the transparency of a polymer mixture containing 20% of the monomer (b) unit.

FIG. 8 is a triangular phase diagram illustrating the transparency of a polymer mixture including 40% of the monomer (b) unit.

FIG. 9 is a triangular phase diagram illustrating the transparency of a polymer mixture including 50% of the monomer (b) unit.

FIG. 10 is a diagram, illustrating the transparency of a polymer mixture, in which contents of a monomer (a) unit and the monomer (b) unit are plotted.

FIG. 11 is a triangular phase diagram illustrating a glass transition temperature of a polymer mixture containing 0% of the monomer (b) unit.

FIG. 12 is a triangular phase diagram illustrating a glass transition temperature of a polymer mixture containing 5% of the monomer (b) unit.

FIG. 13 is a triangular phase diagram illustrating a glass transition temperature of a polymer mixture containing 20% of the monomer (b) unit.

FIG. 14 is a triangular phase diagram illustrating a glass transition temperature of a polymer mixture containing 40% of the monomer (b) unit.

FIG. 15 is a triangular phase diagram illustrating a glass transition temperature of a polymer mixture containing 50% of the monomer (b) unit.

FIG. 16 is a diagram, illustrating the glass transition temperature of a polymer mixture, in which contents of the monomer (b) unit and a monomer (c) unit are plotted.

FIG. 17 is a graph illustrating a relationship between a refractive index and an Abbe number when respective monomers are homopolymers.

FIG. 18 is a diagram, illustrating the transparency of a polymer mixture, in which contents of the monomer (a) unit and the monomer (b) unit are plotted.

FIG. 19 is a diagram schematically illustrating a structure of an LED printer head according to the present invention.

FIG. 20 is a diagram schematically illustrating a structure of a color image sensor head according to the present invention.

### DESCRIPTION OF EMBODIMENTS

Hereinbelow, the present invention will be described in detail.

### [Plastic Rod Lens]

First, a first aspect of the present invention will be described.

According to the first aspect of the present invention, there is provided a transparent plastic rod lens which has a cylindrical shape with a radius r in which a refractive index n_{D} is reduced from a center thereof to an outer periphery thereof, the plastic rod lens including

a polymer mixture (I),

wherein the polymer mixture (I) includes, as constitutional units,

an aromatic ring-containing monomer (a) unit and

at least one monomer unit selected from a group consisting of a (meth)acrylate (b) unit which has a branched hydrocarbon group having 3 or more carbon atoms, a fluorine-containing monomer (c) unit, and an alicyclic ring-containing (meth)acrylate (d) unit, and

a glass transition temperature is higher than or equal to 100° C.

The polymer mixture (I) includes, as constitutional units, the aromatic ring-containing monomer (a) unit and at least one monomer unit selected from a group consisting of the (meth)acrylate (b) unit which has a branched hydrocarbon group having 3 or more carbon atoms, the fluorine-containing monomer (c) unit, and the alicyclic ring-containing (meth)acrylate (d) unit.

The polymer mixture described herein represents a mixture of two or more kinds of polymers. In addition, “the polymer mixture includes specific monomer units as constitutional units” described herein represents “when the polymer mixture is considered as a whole, the specific monomer units are included therein as the units constituting polymers”. That is, this represents that the specific monomer units are included in any of the polymers constituting the polymer mixture as constitutional units For example, an example where “a polymer mixture includes, as constitutional units, the monomer (a) unit, the monomer (b) unit, the monomer (c) unit, and the monomer (d) unit” will be described. In this example, the polymer mixture may be a mixture of “a polymer including at least all the monomer units (a) to (d)” and “another polymer”. In addition, for example, the polymer mixture may be a mixture of “a polymer (A) including at least the monomer (a) unit”, “a polymer (B) including at least the monomer (b) unit”, “a polymer (C) including at least the monomer (c) unit”, and “a polymer (D) including at least the monomer (d) unit”. As intermediate cases between the above-described two cases, for example, the polymer mixture may be a mixture of “the polymer (A) including at least the monomer (a) unit” and “a polymer including at least the monomer (b) to (d) units”; a mixture of “a polymer including at least the monomer (a) unit and the monomer (b) unit” and “a polymer including at least the monomer (c) unit and the monomer (d) unit”; and a mixture of “the polymer (A) including at least the monomer (a) unit”, “the polymer (B) including at least the monomer (b) unit”, and “a polymer including at least the monomer (c) unit and the monomer (d) unit”.

Accordingly, the polymer monomer (I) includes, as constitutional units, “the aromatic ring-containing monomer (a) unit” and “at least one selected from a group consisting of the (meth)acrylate (b) unit which has a branched hydrocarbon group having 3 or more carbon atoms, the fluorine-containing monomer (c) unit, and the alicyclic ring-containing (meth)acrylate (d) unit. Therefore, examples of the polymer mixture (I) include:

(1) a mixture of “a polymer including, as constitutional units, at least <the aromatic ring-containing monomer (a) unit> and <at least one monomer unit selected from a group consisting of the (meth)acrylate (b) unit which has a branched hydrocarbon group having 3 or more carbon atoms, the fluorine-containing monomer (c) unit, and the alicyclic ring-containing (meth)acrylate (d) unit>” and “another polymer”; and

(2) a mixture of “a polymer including at least the aromatic ring-containing monomer (a) unit as a constitutional unit” and “at least one polymer selected from a group consisting of <a polymer including at least the (meth)acrylate (b) unit which has a branched hydrocarbon group having 3 or more carbon atoms as a constitutional unit>, <a polymer including at least the fluorine-containing monomer (c) unit as a constitutional unit>, and <a polymer including at least the alicyclic ring-containing (meth)acrylate (d) unit as a constitutional unit>”.

The (a) unit is the aromatic ring-containing monomer unit.

A monomer which is used as a material of the (a) unit is not particularly limited as long as it can be used for the plastic rod lens according to the present invention, and examples of the monomer include phenyl acrylate (n=1.57, ν=38, Tg=114° C.), phenyl methacrylate (n=1.56, ν=36, Tg=122° C.), benzyl methacrylate (n=1.56, ν=38, Tg=59° C.), phenethyl methacrylate (n=1.53, ν=41, Tg=42° C.), styrene (n=1.59, ν=34, Tg=98° C.), 2-chlorostyrene (n=1.58, ν=37, Tg=120° C.), 3-chlorostyrene (n=1.60, ν=36, Tg=85° C.), 4-chlorostyrene (n=1.59, ν=37, Tg=121° C.), and 2-vinylnaphthalene (n=1.66, ν=21, Tg=142° C.). Among these, phenyl methacrylate is preferable from the viewpoints of polymerizability with a monomer, which is a material of another constitutional monomer, and improvement in heat resistance. The numerical values in the parentheses are physical property values in the case of a homopolymer, and “n” represents the refractive index, “ν” represents the Abbe number, and “Tg” represents the glass transition temperature.

A content [a] of the (a) unit is not particularly limited, but is preferably 5 mass % to 72.5 mass % in the polymer mixture (I). In the polymer mixture (I), when [a] is greater than or equal to 5 mass %, a lens having excellent heat resistance is likely to be obtained. In addition, in the polymer mixture (I), when [a] is less than or equal to 72.5 mass %, a lens having excellent transparency is likely to be obtained.

The (b) unit is the (meth)acrylate unit which has a branched hydrocarbon group having 3 or more carbon atoms.

A monomer which is used as a material of the (b) unit is not particularly limited as long as it can be used for the plastic rod lens according to the present invention, and examples of the monomer include propyl methacrylate (n=1.48, ν=57, Tg=43° C.), isopropyl methacrylate (n=1.47, ν=55, Tg=81° C.), isobutyl methacrylate (n=1.48, ν=47, Tg=64° C.), sec-butyl methacrylate (n=1.48, ν=55, Tg=59° C.), t-butyl acrylate (n=1.47, ν=56, Tg=42° C.), and t-butyl methacrylate (n=1.47, ν=60 Tg=107° C.). Among these, isobutyl methacrylate, t-butyl methacrylate, and isopropyl methacrylate are preferable from the viewpoints of a low refractive index and improvement in heat resistance. The numerical values in the parentheses are physical property values in the case of a homopolymers.

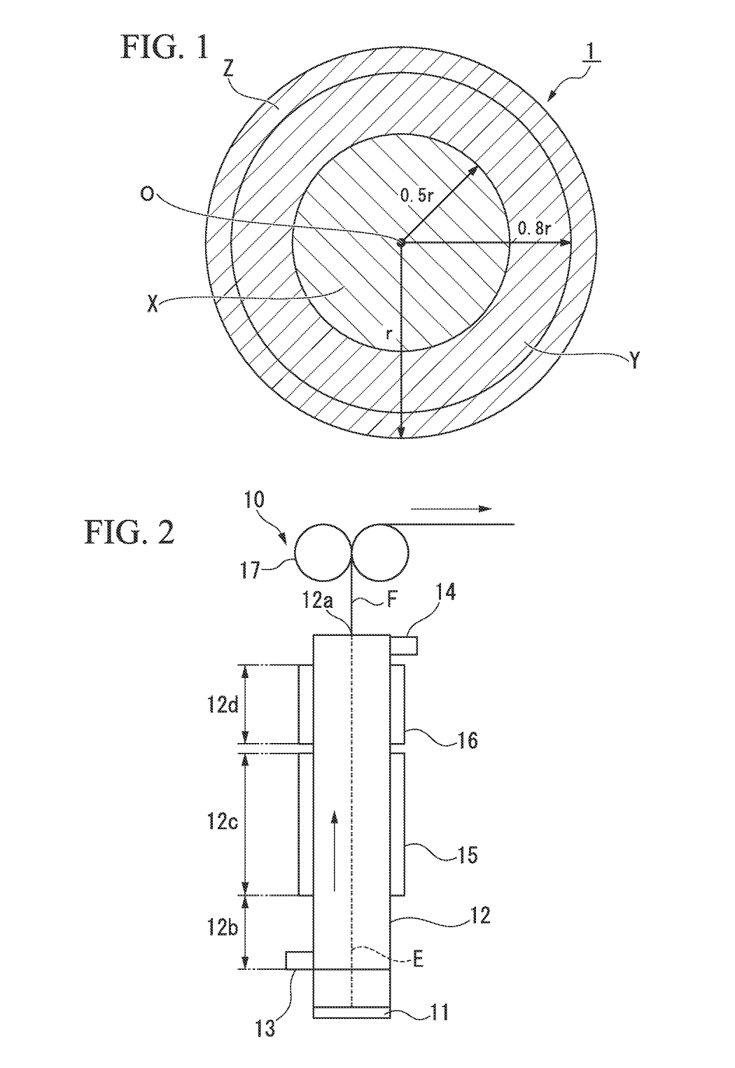

A content [b] of the (b) unit is not particularly limited, but it is preferable that a large part of the (b) unit be included in a polymer which is positioned closer to the outer periphery with a low refractive index. That is, in the cross-sectional view of the rod lens illustrated in FIG. 1, [b] is preferably 0 mass % to 47 mass % in the polymer mixture (I) which is positioned in a range (Y, Z) of 0.5r to r from the center to the outer periphery. When [b] is greater than or equal to 0 mass % in the polymer mixture (I) positioned in the above-described range, a lens having a great aperture angle and excellent heat resistance is likely to be obtained. In addition, when [b] is less than or equal to 47 mass % in the polymer mixture (I) positioned in the above-described range, a lens having excellent transparency is likely to be obtained.

The (c) unit is the fluorine-containing monomer unit, for example, a unit obtained by substituting hydrogen of an alkyl group of alkyl(meth)acrylate with fluorine.

A monomer which is used as a material of the (c) unit is not particularly limited as long as it can be used for the plastic rod lens according to the present invention, and examples of the monomer include 2,2,2-trifluoroethyl methacrylate (n=1.42, ν=68, Tg=80° C.), 2,2,3,3-tetrafluoropropyl methacrylate (n=1.41, ν=70, Tg=79° C.), and 2,2,3,3,4,4,5,5,-octafluoropentyl methacrylate (n=1.40, ν=66, Tg=31° C.). The numerical values in the parentheses are physical property values in the case of a homopolymers. Among these, 2,2,3,3-tetrafluoropropyl methacrylate is preferable from the viewpoints of a low refractive index and improvement in heat resistance.

A content [c] of the (c) unit is not particularly limited, but it is preferable that a large part of the (c) unit be included in a polymer which is positioned closer to the outer periphery with a low refractive index. That is, in the cross-sectional view of the rod lens illustrated in FIG. 1, [c] is preferably 0 mass % to 47 mass % in the polymer mixture (I) which is positioned in a range (Z) of 0.8r to r from the center to the outer periphery. When [c] is greater than or equal to 0 mass % in the polymer mixture (I) positioned in the above-described range, a lens having a great aperture angle and a high light intensity is likely to be obtained. In addition, when [c] is less than or equal to 47 mass % in the polymer mixture (I) positioned in the above-described range, a lens having excellent heat resistance is likely to be obtained.

The (d) unit is the alicyclic ring-containing (meth)acrylate unit.

A monomer which is used as a material of the (d) unit is not particularly limited as long as it can be used for the plastic rod lens according to the present invention, and examples of the monomer include 1-adamantyl methacrylate (n=1.53, ν=57, Tg=183° C.), isobornyl methacrylate (n=1.53, ν=56, Tg=155° C.), and tricyclo[5.2.1.0^{2,6}]decanyl methacrylate (n=1.52, ν=55, Tg=150° C.). Among these, tricyclo[5.2.1.0^{2,6}]decanyl methacrylate is preferable from the viewpoints of improvement in heat resistance and solubility in the other components. The numerical values in the parentheses are physical property values in the case of a homopolymer.

A content [d] of the (d) unit is not particularly limited, but it is preferable that a large part of the (d) unit be included in a polymer which is positioned closer to the center with a high refractive index. That is, in the cross-sectional view of the rod lens illustrated in FIG. 1, [d] is preferably 0 mass % to 50 mass % in the polymer mixture (I) which is positioned in a range (X) of 0 to 0.5r from the center to the outer periphery. When [d] is greater than or equal to 0 mass % in the polymer mixture (I) positioned in the above-described range, a lens having excellent heat resistance is likely to be obtained. In addition, when [d] is less than or equal to 50 mass % in the polymer mixture (I) positioned in the above-described range, a difference in refractive index is appropriate and thus, a sufficient focal depth is likely to be obtained.

Optionally, in addition to the (a) to (d) units, the polymer mixture (I) may further include another monomer unit as a constitutional unit. Among these, it is preferable that the polymer mixture (I) further include a methyl methacrylate unit (m) as a constitutional unit from the viewpoints of adjusting transparency, refractive index, and the like.

The rod lens according to the first aspect has a cylindrical shape having a radius r, in which a refractive index n_{D} is reduced from the center to the outer periphery. Regarding a refractive index distribution of the rod lens, in a cross-section perpendicular to the central axis of the rod lens, it is preferable that at least a refractive index distribution in a range of 0.2r to 0.8r from the center to the outer periphery approximate a quadratic curve distribution defined by the following expression (6).

n(L)=n_{0{}1−(g²/2)L²} (6)

(In the expression (6), n₀ represents the refractive index (central refractive index) in the center of the rod lens; L represents the distance (0≦L≦r) from the center on the circular cross-section of the rod lens; g represents the refractive index distribution constant of the rod lens; and n(L) represents the refractive index at a position which is distant from the center of the rod lens by the distance L)

The radius r of the rod lens is not particularly limited. From the viewpoint of reducing the size of an optical system, it is preferable that the radius r be small; and from the viewpoint of handleability during the processing of the rod lens, it is preferable that the radius r be large. Therefore, the radius r of the rod lens is preferably in a range of 0.1 mm to 0.5 mm and more preferably in a range of 0.15 mm to 0.40 mm.

In addition, the central refractive index n₀ of the rod lens is not particularly limited. In light having a wavelength of 525 nm, the central refractive index is preferably 1.45 to 1.60 from the viewpoints of increasing options of materials constituting the rod lens and promoting the formation of a superior refractive index distribution.

In the rod lens according to the present invention, the refractive index is reduced from the center to the outer periphery. A difference in refractive index between the center and the outer periphery of the rod lens according to the first aspect is not particularly limited, but is preferably 0.003 to 0.06. When the difference in refractive index is greater than or equal to 0.003, an aperture angle of the lens is sufficiently great and thus, a required lens light intensity for high-speed printing is likely to be obtained. On the other hand, when the difference in refractive index is less than or equal to 0.06, deterioration in resolution due to out-of-focus caused by a narrow focal depth can be prevented; and a sufficient working distance is likely to be secured, thereby making an optical design easy.

Furthermore, the refractive index distribution constant g of the rod lens is not particularly limited. However, in light having a wavelength of 525 nm, the refractive index distribution constant g is preferably in a range of 0.10 mm⁻¹ to 1.50 mm⁻¹ and more preferably in a range of 0.25 mm⁻¹ to 1.00 mm⁻¹, from the viewpoint of reducing the size of an optical system; and securing the working distance and handleability in an optical system. When the refractive index distribution constant g is greater than or equal to 0.10 mm⁻¹, the working distance of an optical system is likely to be shortened, thereby promoting a reduction in size. On the other hand, when the refractive index distribution constant g is less than or equal to 1.50 mm⁻¹, the working distance is appropriate and an optical system is likely to be easily designed.

The glass transition temperature of the rod lens according to the first aspect is higher than or equal to 100° C. When the glass transition temperature of the rod lens is higher than or equal to 100° C., sufficient heat resistance can be imparted to the lens and thus, deterioration in resolution can be suppressed even after use in a high-temperature environment.

In order to control the glass transition temperature of the rod lens to be higher than or equal to 100° C., the content [a] of the (a) unit in the polymer mixture (I) is preferably 5 mass % to 72.5 mass %.

In addition, the content [b] of the (b) unit is preferably 0 mass % to 47 mass % in the polymer mixture (I) in the range (Y, Z) of 0.5r to r from the center to the outer periphery of the rod lens.

In addition, the content [c] of the (c) unit is preferably 0 mass % to 47 mass % in the polymer mixture (I) in the range (Z) of 0.8r to r from the center to the outer periphery of the rod lens.

In addition, the content [d] of the (d) unit is preferably 0 mass % to 50 mass % in the polymer mixture (I) in the range (X) of 0 to 0.5r from the center to the outer periphery of the rod lens.

Next, a second aspect of the present invention will be described.

In the plastic rod lens according to the second aspect,

the polymer mixture (I) is a polymer mixture (II) which includes, as constitutional units, the (a) unit and at least one of the (b) unit and the (c) unit,

a difference in refractive index between a center portion and an outer peripheral portion is 0.02 to 0.06, and

compositions of the constitutional units of the polymer mixture (II) satisfy the following expression (1) at any position in a range of 0 to r from the center to the outer periphery.

0.357[b]−1.786<[a]<65−1.063[b] (1)

(wherein in the expression (1), [a] represents the content (mass %) of the constitutional unit (a); and [b] represents the content (mass %) of the constitutional unit (b))

The polymer mixture (II) includes, as constitutional units, the (a) unit and at least one of the (b) unit and the (c) unit. Therefore, examples of the polymer mixture (II) include:

(1) a mixture of “a polymer including at least, as constitutional units, <the (a) unit> and at least one monomer unit of <the (b) unit> and <the (c) unit>” and “another polymer”; and

(2) a mixture of “a polymer including at least the (a) unit as a constitutional unit” and “at least one polymer of <a polymer including at least the (b) unit as a constitutional unit> and <a polymer including at least the (c) unit as a constitutional unit>.

Optionally, in addition to the (a) to (c) units, the polymer mixture (II) may further include the (d) unit, the (m) unit, and another monomer unit as constitutional units. Among these, it is preferable that the polymer mixture (II) include the (m) unit as a constitutional unit from the viewpoint of adjusting transparency, refractive index, and the like.

In the rod lens according to the second aspect, the difference in refractive index between the center and the outer periphery is 0.02 to 0.06. When the difference in refractive index is greater than or equal to 0.02, an aperture angle of the lens is sufficiently great and thus, a required lens light intensity for high-speed printing is likely to be obtained. On the other hand, when the difference in refractive index is less than or equal to 0.06, deterioration in resolution due to out-of-focus caused by a narrow focal depth can be prevented; and a sufficient working distance is likely to be secured, thereby making an optical design easy.

Furthermore, the refractive index distribution constant g of the rod lens according to the second aspect is not particularly limited. However, in light having a wavelength of 525 nm, the refractive index distribution constant g is preferably in a range of 0.50 mm⁻¹ to 1.50 mm⁻¹ and more preferably in a range of 0.60 mm⁻¹ to 1.00 mm⁻¹, from the viewpoint of reducing the size of an optical system; and securing the working distance and handleability in an optical system. When the refractive index distribution constant g is greater than or equal to 0.50 mm⁻¹, the working distance of an optical system is likely to be shortened, thereby promoting a reduction in size. On the other hand, when the refractive index distribution constant g is less than or equal to 1.50 mm⁻¹, the working distance is appropriate and an optical system is likely to be easily designed.

It is preferable that a large part of the monomer (a) unit be included in a polymer which is positioned closer to the center with a high refractive index, and it is preferable that large amounts of the monomer (b) unit and the monomer (c) unit be included in a polymer which is positioned closer to the outer periphery with a lower refractive index. By constituting a lens with such a polymer mixture, a difference in refractive index between the center and the outer periphery of the lens increases. Therefore, an aperture angle of the lens increases and thus, a lens having a high light intensity is likely to be obtained.

Specifically, in the cross section of a rod lens 1 illustrated in FIG. 1, [a] is preferably 10 mass % to 60 mass % and more preferably 25 mass % to 50 mass % in the polymer mixture (II) which is positioned in the range (X) of 0 to 0.5r from the center O to the outer periphery. When [a] is greater than or equal to 10 mass % in the polymer mixture (II) positioned in the above-described range, the difference in refractive index between the center O and the outer periphery of the rod lens is likely to increase and thus, the aperture angle of the lens increases. As a result, a sufficient lens light intensity is likely to be maintained. On the other hand, when [a] is less than or equal to 60 mass % in the polymer mixture (II) positioned in the above-described range, the polymer mixture is not likely to become cloudy and thus, a lens having excellent transparency is likely to be obtained.

In addition, [c] is preferably 5 mass % to 45 mass % and more preferably 15 mass % to 35 mass % in the polymer mixture (II) which is positioned in the range (Z) of 0.8r to r from the center O to the outer periphery. When [c] is greater than or equal to 5 mass % in the polymer mixture (II) positioned in the above-described range, the difference in refractive index between the center O and the outer periphery of the rod lens is likely to increase and thus, the aperture angle of the lens increases. As a result, a sufficient lens light intensity is likely to be secured. On the other hand, when [c] is less than or equal to 45 mass % in the polymer mixture (II) positioned in the above-described range, deterioration in heat resistance is likely to be suppressed.

In addition, in the rod lens according to the second aspect, compositions of the constitutional units of the polymer mixture (II) satisfy the following expression (1) at any position in a range of 0 to r from the center to the outer periphery.

0.357[b]−1.786<[a]<65−1.063[b] (1)

Generally, it is known that a mixture of plural kinds of polymers becomes cloudy because the polymers are not compatible to each other; and phase separation occurs. In particular, when monomers with a high refractive index and a high Tg are used, this tendency becomes significant. When the polymer mixture becomes cloudy, the intensity of transmitted light is reduced and thus, the lens light intensity is reduced. Furthermore, since light in the lens is diffused, the resolution significantly deteriorates.

However, in the rod lens according to the second aspect, the composition of the polymer mixture constituting the rod lens satisfies the expression (1) at any positions from the center to the outer periphery of the lens. Therefore, the rod lens according to the second aspect does not become cloudy and can exhibit excellent transparency. Accordingly, in the rod lens according to the second aspect, the light intensity is high and the resolution does not deteriorate.

In Tables 1 to 5, the transparency, refractive index, and glass transition temperature of a polymer mixture are shown, the polymer mixture obtained by adding 0.25 parts by mass of 1-hydroxycyclohexyl phenyl ketone (HCPK) as a photocuring catalyst to an uncured material which includes, at various ratios, phenyl methacrylate (PhMA) as the monomer (a), t-butyl methacrylate as the monomer (b), 2,2,3,3-tetrafluoropropyl methacrylate (4FM) as the monomer (c), methyl methacrylate (MMA) as the monomer (m), and polymethyl methacrylate (PMMA) as the polymer (M); and curing the resultant with three 2 KW high-pressure mercury lamps.

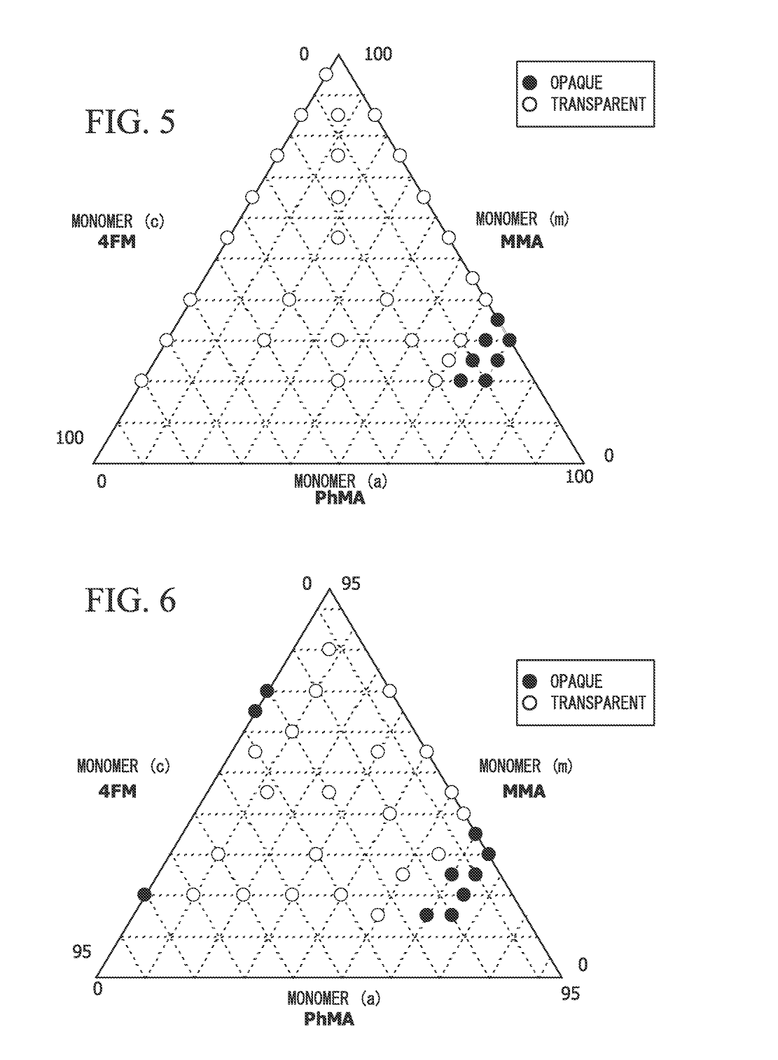

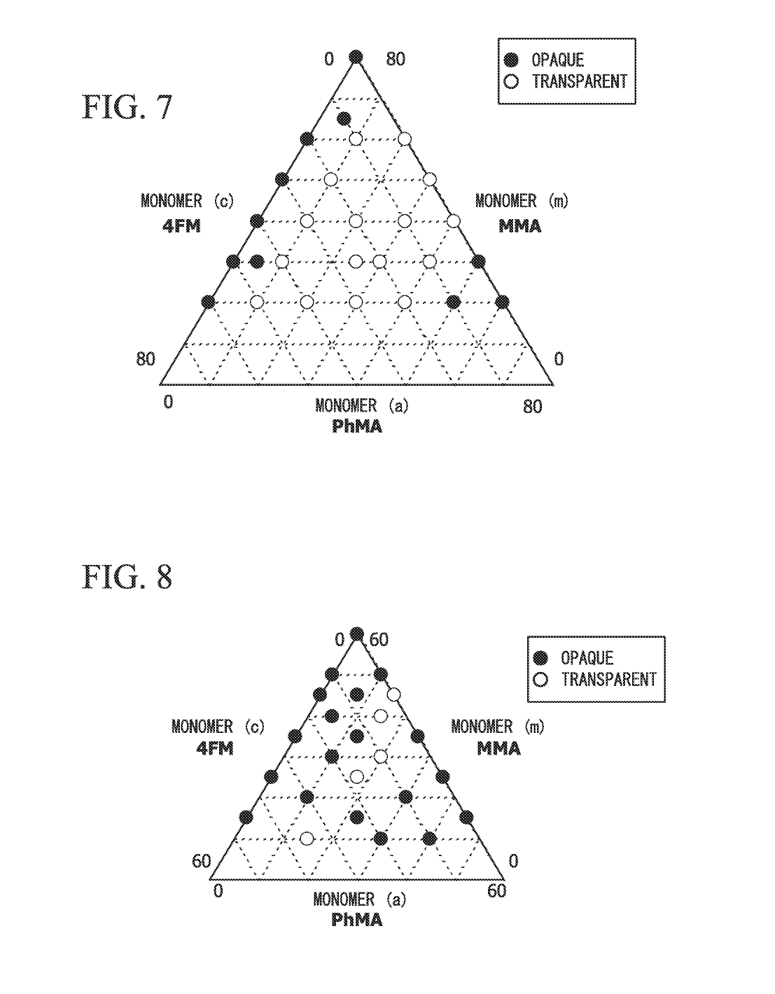

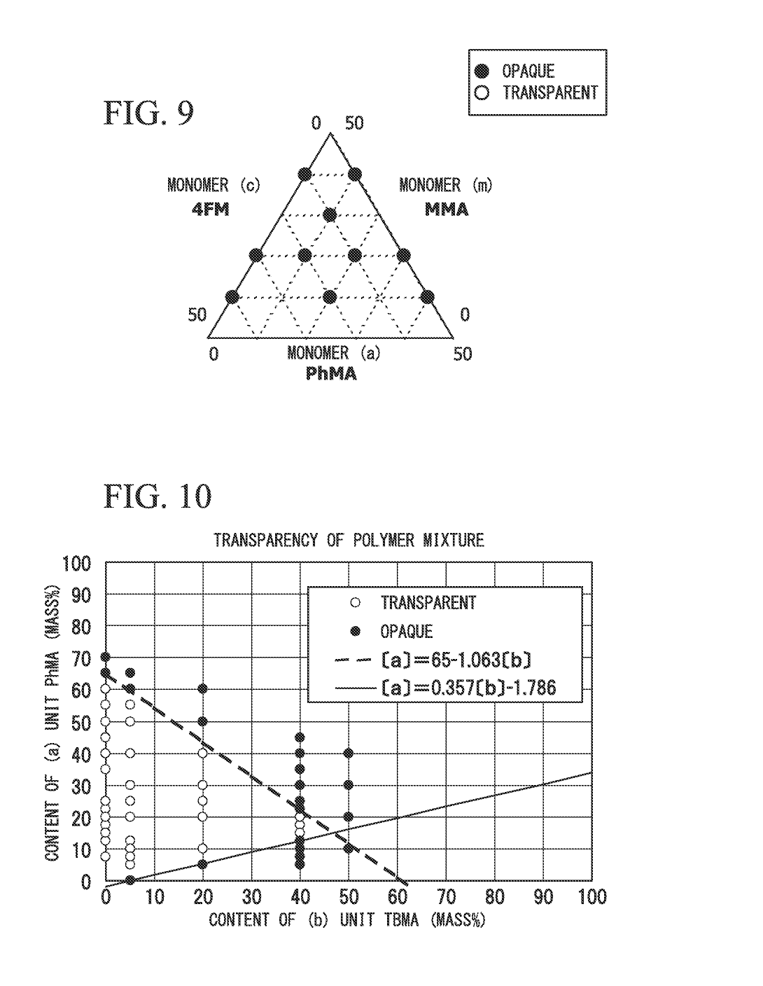

FIGS. 5 to 9 are triangular phase diagrams in which, when the content [b] of each monomer (b) is 0%, 5%, 20%, 40%, or 50%, the results of Tables 1 to 5 for transparency are plotted at the contents [a] (mass %), [c] (mass %), and [m] (mass %) of the compositions of the constitutional units.

FIG. 10 is a graph, illustrating a composition range when a polymer mixture is transparent, in which [a] (mass %) and [b] (mass %) are plotted.

As illustrated in FIG. 10, it can be seen that the polymer mixture is transparent in a range in which the composition of the polymer mixture satisfies the expression (1). In addition, in order to make the polymer mixture transparent, the following expression (1′) is more preferable than the expression (1).

[b]/3≦[a]≦60−[b] (1′)

In addition, in the rod lens according to the second aspect, compositions of the constitutional units of the polymer mixture (II) satisfy the following expression (2) at any position in a range of 0.8r to r from the center to the outer periphery.

[c]<47.143−0.429[b] (2)

(wherein in the expression (2), [b] represents the content (mass %) of the constitutional unit (b); and [c] represents the content (mass %) of the constitutional unit (c))

By increasing the glass transition temperature of the lens, heat resistance is improved. However, in order to impart sufficient heat resistance to the lens, it is necessary that the glass transition temperature of the lens be higher than or equal to 100° C.

Incidentally, in the polymer mixture constituting the rod lens, in order to increase the difference in refractive index between the center and the outer periphery of the lens, a large part of the monomer (c) unit is included in the polymer mixture with a low refractive index which is positioned closer to the outer periphery. Therefore, the glass transition temperature of a polymer which is positioned closer to the outer periphery is likely to be low.

In order to control the glass transition temperature of the lens to be higher than or equal to 100° C., the glass transition temperature of the polymer mixture is not necessarily higher than or equal to 100° C. at any positions from the center to the outer periphery. However, by controlling the glass transition temperature of the polymer mixture, which is positioned in the outer periphery of the lens, to be higher than or equal to 100° C., sufficient heat resistance can be imparted to the lens. This effect is particularly significant when a hot-melt adhesive is used as an adhesive for fixing the lens to a substrate during the manufacturing of a rod lens array. The hot melt adhesive flows at a high temperature and is coated onto the lens and the substrate. Therefore, when the glass transition temperature of the lens outer peripheral portion is low, the refractive index distribution of the lens outer peripheral portion changes and thus, the resolution deteriorates. Accordingly, when the glass transition temperature of the polymer mixture which is positioned in the outer periphery of the lens is higher than or equal to 100° C., sufficient heat resistance can be imparted to the lens.

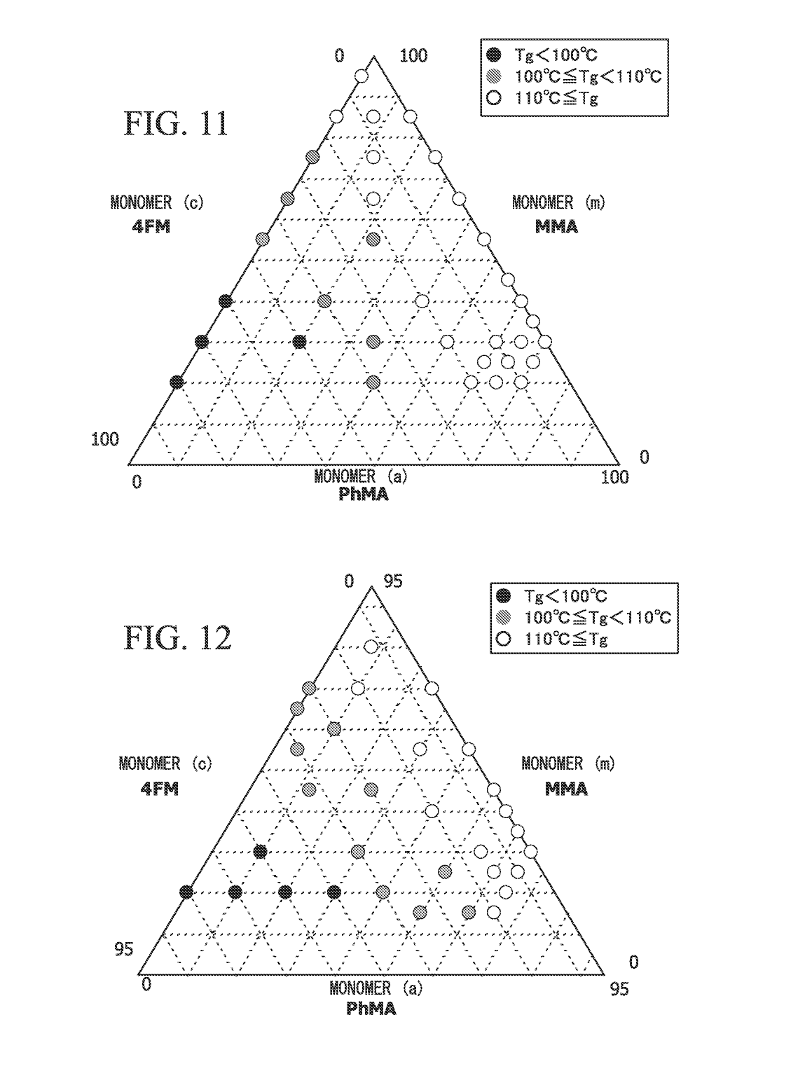

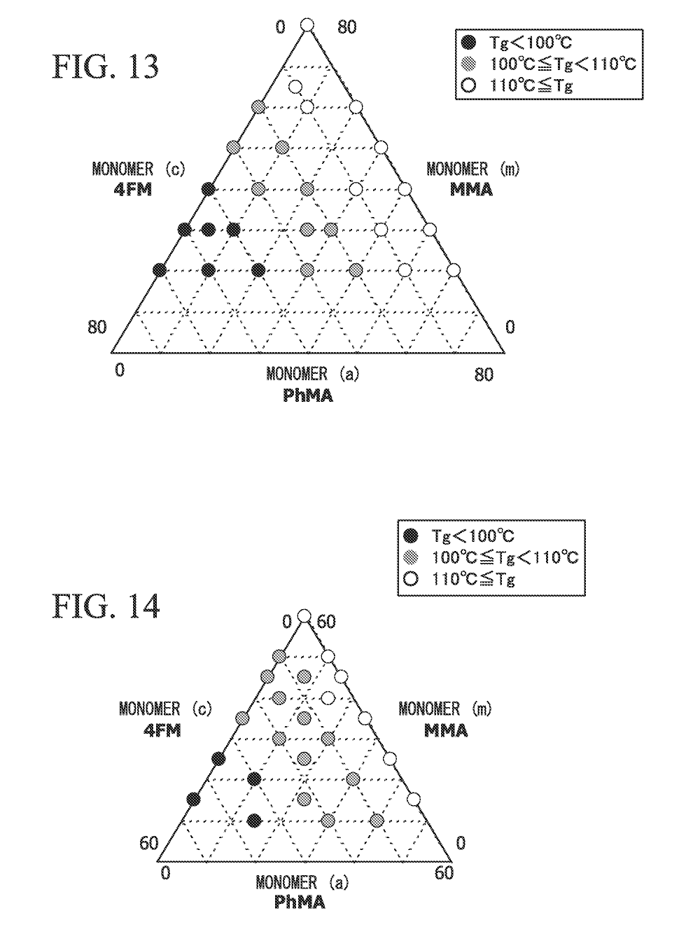

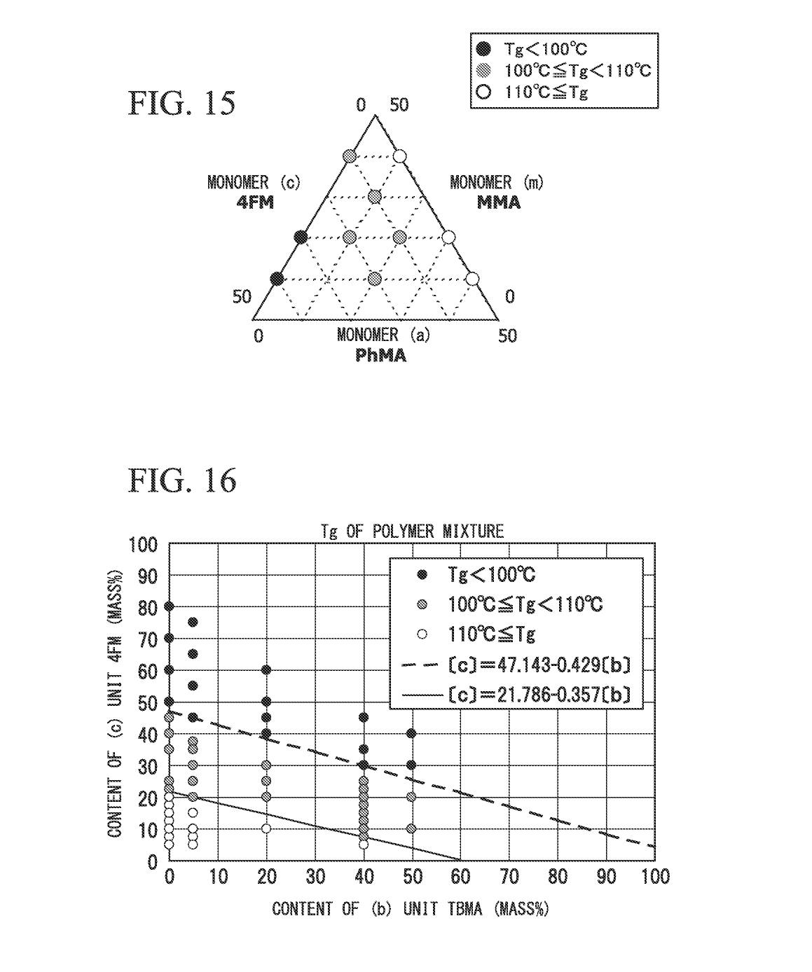

FIGS. 11 to 15 are triangular phase diagrams in which, when the content [b] of each monomer (b) is 0%, 5%, 20%, 40%, or 50%; and Tg of the polymer mixture is higher than or equal to 110° C., is 100° C. to lower than 110° C., or is lower than 100° C., the results of Tables 1 to 5 are plotted at the contents [a] (mass %), [c] (mass %), and [m] (mass %) of the compositions of the constitutional units.

FIG. 16 is a graph, illustrating a composition range when Tg of the polymer mixture is higher than or equal to 110° C., 100° C. to lower than 110° C. or is lower than 100° C., in which [b] (mass %) and [c] (mass %) are plotted.

Based on the above results, Tg of the polymer mixture is controlled to be higher than or equal to 100° C. in a range in which the composition of the polymer mixture satisfies the expression (2).

That is, it is preferable that the polymer mixture, which is positioned in the range (Z) of 0.8r to r from the center to the outer periphery, be constituted with the composition (mass %) satisfying the expression (2), and heat resistance is likely to be imparted to the lens. In addition, the following (2′) is more preferable than the expression (2) from the viewpoint of imparting sufficient heat resistance to the lens.

[c]≦45−0.5[b] (2′)

In addition, by controlling the glass transition temperature of the polymer mixture, which is positioned in the center portion of the lens, to be higher than or equal to 110° C., more sufficient heat resistance can be imparted to the lens, which is particularly preferable.

Based on FIG. 16, Tg of the polymer is controlled to be higher than or equal to 110° C. in a range in which the composition of the polymer mixture satisfies the expression (3).

[c]<21.786−0.357[b] [3]

That is, it is preferable that the polymer mixture, which is positioned in the range (X,Y) of 0 to 0.8r from the center to the outer periphery, be constituted with the composition (mass %) satisfying the expression (3). In addition, the following expression (3′) is more preferable than the expression (3) from the viewpoint of imparting sufficient heat resistance to the lens.

[c]≦20−0.333[b] [3′]

When the constitutional units of the polymer mixture (II) satisfy the expression (2), the glass transition temperature of the polymer mixture (II) is controlled to be higher than or equal to 100° C. Accordingly, sufficient heat resistance can be imparted to the lens; and deterioration in resolution can be suppressed even when the lens is used in a high-temperature environment.

In particular, it is preferable that the polymer mixture, which is positioned in the range (Z) of 0.8r to r from the center to the outer periphery, be constituted with the composition (mass %) at least satisfying the expression (2). Furthermore, it is preferable that the polymer mixture, which is positioned in the range (X,Y) of 0 to 0.8r from the center to the outer periphery, be constituted with the composition (mass %) satisfying the expression (3).

In this way, by appropriately selecting and arranging the composition of the polymer mixture which constitutes the lens, transparency is excellent and the difference in refractive index between the center to the outer periphery of the lens is great. As a result, a lens with a high light intensity can be obtained. Furthermore, since the glass transition temperature is high over the entire lens, a lens in which heat resistance is excellent and the resolution does not deteriorate even after use in a high-temperature environment can be obtained.

Next, a third aspect of the present invention will be described.

In the plastic rod lens according to the third aspect,

the polymer mixture (I) is a polymer mixture (III) which includes, as constitutional units, the (a) unit, the (b) unit, and the (d) unit,

refractive indices and Abbe numbers satisfy the following expression (4) at different arbitrary positions α and β in a range of 0 to r from the center to the outer periphery, and

|{n_{α}×ν_{α}/(n_{α}−1)}−{n_{β}×ν_{β}/(n_{β}−1)}|<5 (4)

(wherein n_{α} and n_{β} represent the refractive indices n_{D} at the positions α and β, respectively; and ν_{α} and ν_{β} represent the Abbe numbers at the positions α and β, respectively) compositions of the constitutional units of the polymer mixture (III) satisfy the following expression (5) at any position in a range of 0 to r from the center to the outer periphery

0.5[b]−10<[a]<72.5−1.75[b] (5)

(wherein, in the expression (5), [a] represents the content (mass %) of the constitutional unit (a); and [b] represents the content (mass %) of the constitutional unit (b))

The polymer mixture (III) includes, as constitutional units, the (a) unit, the (b) unit, and the (d) unit. Therefore, examples of the polymer mixture (III) include:

(1) a mixture of “a polymer including at least <the (a) unit>, <the (b) unit>, and <the (d) unit> as constitutional units” and “another polymer”; and

(2) a mixture of “a polymer including at least the (a) unit as a constitutional unit”, “a polymer including at least the (b) unit as a constitutional unit”, and “a polymer including at least the (d) unit as a constitutional unit”.

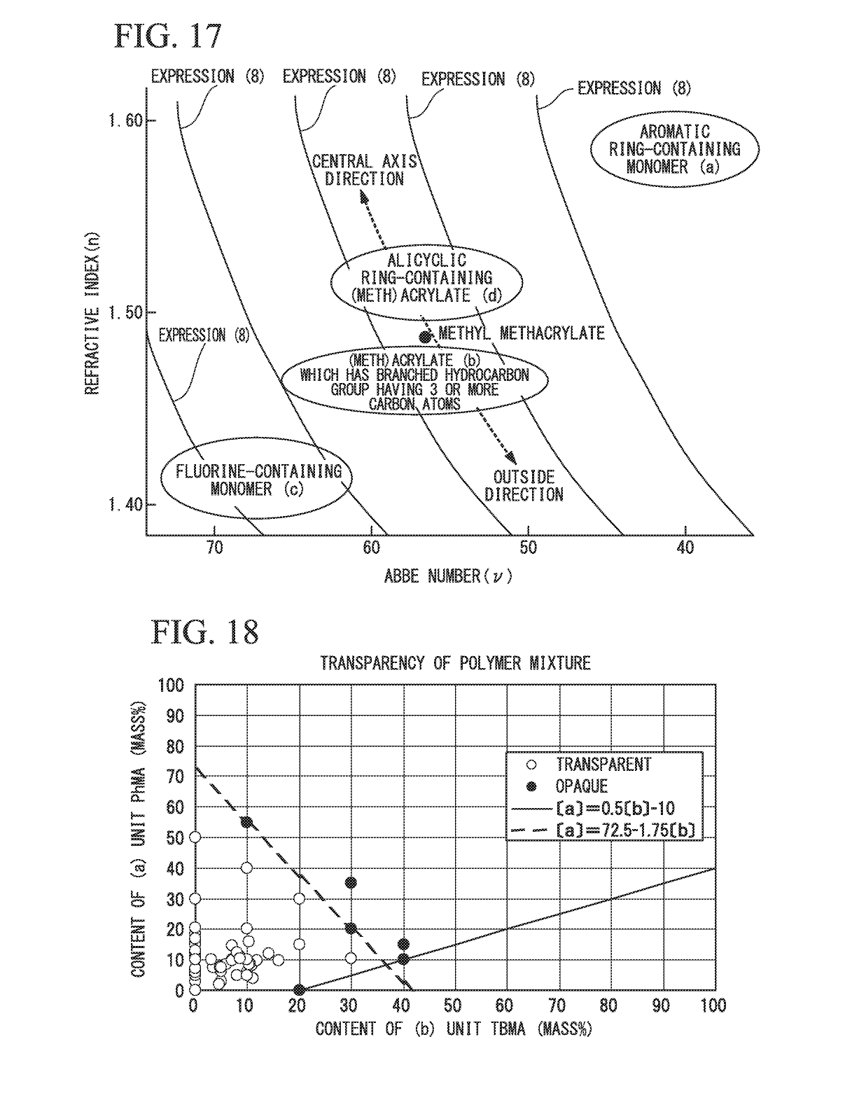

Optionally, in addition to the (a), (b), and (d) units, the polymer mixture (III) may further include the (c) unit, the (m) unit, and another monomer unit as constitutional units. Among these, it is preferable that the polymer mixture (III) include the (m) unit as a constitutional unit from the viewpoint of adjusting transparency, refractive index, and the like. When the monomer (m) is a homopolymer, the refractive index (n) is 1.492, the Abbe number (ν) is 56, and Tg is 114° C. When the above-described monomer (a), monomer (b), monomer (c), monomer (d), and monomer (m) are homopolymers, a relationship between the refractive index and the Abbe number is as illustrated in FIG. 17.

In the rod lens according to the third aspect, refractive indices and Abbe numbers satisfy the following expression (4) at different arbitrary positions α and β in a range of 0 to r from the center to the outer periphery

As described in the reference document (APPLIED OPTICS, Vol. 19, No. 7, P1052 (1980)), when ΔP is 0 in the following expression (7), the chromatic aberration of the rod lens is removed.

$$\frac{Δ P}{P} = - \frac{1}{2} \cdot \frac{\frac{1}{{v}_{0}} ( 1 - \frac{1}{{n}_{0}} ) - \frac{1}{{v}_{i}} ( 1 - \frac{1}{{n}_{i}} )}{\frac{{n}_{0}}{{n}_{i}} - 1} \qquad ( 7 )$$

In the expression (7), n₀ represents the refractive index (central refractive index) in the center of the rod lens; nᵢ represents the refractive index at a position which is distant from the center of the rod lens by the distance i; ν₀ represents the Abbe number at the center of the rod lens; νᵢ represents the Abbe number at the position which is distant from the center of the rod lens by the distance i; P represents the period length of D rays (wavelength: 589.3 nm); and ΔP represents the difference in period length between C rays (wavelength: 656. 3 nm) and F rays (wavelength 486. 1 nm).

Accordingly, in order to reduce the chromatic aberration of the rod lens, it is preferable that the refractive index (n) and the Abbe number (ν) from the center to the outer periphery of the rod lens satisfy the relationship of the following expression (8).

1/ν(1−1/n)=K (8)

(In the expression (8), K represents a constant)

In this case, the expression (8) is plotted in FIG. 17 with an arbitrary value of K.

That is, when a radius of a cross-section, obtained by cutting the rod lens 1 in a direction perpendicular to the central axis as illustrated in FIG. 1, is represented by r, it is preferable that an optical system be designed such that the refractive index and the Abbe number of the polymer mixture are on a line plotted by the expression (8) at any positions in the range of 0 to r from the center O to the outer periphery. By controlling the mixing ratios of the monomer (a), the monomer (b), and the monomer (d) and, optionally, the monomer (c) and the monomer (m) which are used as materials of the polymer, a rod lens satisfying the expression (8) can be obtained.

Satisfying the expression (8) represents that K values are the same at any positions from the center to the outer periphery of the rod lens. In the rod lens according to the third aspect, chromatic aberration can be sufficiently reduced by suppressing a difference |K_{α}−K_{β}| between K values at two arbitrary points α and β in the range of 0 to r from the center to the outer periphery to be less than 5, that is, by satisfying the expression (4).

To that end, it is preferable that a large part of the monomer (d) unit be incorporated into the polymer mixture which is positioned closer to the center; and that large parts of the monomer (a) unit and the monomer (b) unit be incorporated into the polymer mixture which is positioned closer to the outer periphery. In this case, instead of the monomer (b), the monomer (c) can be used in a range in which the glass transition temperature of the lens is higher than 100° C.

Specifically, in the cross section of the rod lens 1 illustrated in FIG. 1, [d] is preferably 10 mass % to 50 mass % and more preferably 10 mass % to 35 mass % in the polymer mixture (III) which is positioned in the range of 0 to 0.5r from the center O to the outer periphery of the lens. In addition, it is preferable that [d] be gradually reduced in the range of 0 to r from the center to the outer periphery of the lens. When [d] is greater than or equal to 10 mass % in the polymer mixture (III) positioned in the above-described range, a difference in Abbe number between the center and the outer periphery is likely to be sufficiently reduced. In addition, when [d] is less than or equal to 50 mass % in the polymer mixture (III) positioned in the above-described range, a difference in refractive index between the center and the outer periphery is likely to be appropriate; and a sufficient focal depth is likely to be obtained.

In addition, in order to obtain a lens having a small chromatic aberration and a high resolution, it is preferable that the monomers be incorporated such that [a] and [b] gradually increase in the range of 0 to r from the center to the outer periphery of the lens. In this case, instead of the monomer (b), the monomer (c) can be used in a range in which the glass transition temperature of the lens is higher than 100° C.

In addition, in the rod lens according to the third aspect, a difference (Δn) between the central refractive index n₀ and the refractive index at the outermost periphery is preferably 0.003 to 0.02. When the difference (Δn) is greater than or equal to 0.003, an aperture angle of the lens is likely to be sufficiently great and a required lens light intensity for high-speed reading is likely to be secured. On the other hand, when the difference (Δn) is less than or equal to 0.02, a sufficient focal depth is likely to be secured. As a result, deterioration in resolution due to out-of focus can be prevented; and a sufficient working distance is likely to be secured, thereby making an optical design easy.

Furthermore, the refractive index distribution constant g of the rod lens according to the third aspect is not particularly limited. However, in light having a wavelength of 525 nm, the refractive index distribution constant g is preferably in a range of 0.10 mm⁻¹ to 1.00 mm⁻¹ and more preferably in a range of 0.25 mm⁻¹ to 0.70 mm⁻¹, from the viewpoint of reducing the size of an optical system; and securing the working distance and handleability in an optical system. When the refractive index distribution constant g is greater than or equal to 0.10 mm⁻¹, the working distance of an optical system is likely to be shortened, thereby promoting a reduction in size. On the other hand, when the refractive index distribution constant g is less than or equal to 1.00 mm⁻¹, the working distance is appropriate and an optical system is likely to be easily designed.

In addition, in the rod lens according to the third aspect, compositions of the constitutional units of the polymer mixture (III) satisfy the expression (5) at any position in a range of 0 to r from the center to the outer periphery.

0.5[b]−10[a]<72.5−1.75[b] (5)

Generally, it is known that a mixture of plural kinds of polymers becomes cloudy because the polymers are not compatible to each other; and phase separation occurs. In particular, when monomers with a high refractive index are used, this tendency becomes significant. When the polymer mixture becomes cloudy, the intensity of transmitted light is reduced and thus, the lens light intensity is reduced. Furthermore, since light in the lens is diffused, the resolution significantly deteriorates.

However, in the rod lens according to the present invention, the composition of the polymer mixture constituting the rod lens satisfies the expression (5) at any positions from the center to the outer periphery of the lens. Therefore, since the rod lens does not become cloudy and can exhibit excellent transparency, a rod lens having a high light intensity and no deterioration in resolution can be obtained.

In Tables 6 and 7, the transparency, refractive index, Abbe number, and glass transition temperature of a polymer mixture are shown, the polymer mixture obtained by adding 0.25 parts by mass of 1-hydroxycyclohexyl phenyl ketone (HCPK) as a photocuring catalyst to an uncured material which includes, at various ratios, phenyl methacrylate (PhMA) and benzyl methacrylate (BzMA) as the monomer (a), t-butyl methacrylate (TBMA) as the monomer (b), 2,2,3,3-tetrafluoropropyl methacrylate (4FM) and 2,2,3,3,4,4,5,5-octafluoropentyl methacrylate (8FM) as the monomer (c), tricyclo[5.2.1.0^{2,6}]decanyl methacrylate (TCDMA) as the monomer (d), methyl methacrylate (MMA) as the monomer (m), and polymethyl methacrylate (PMMA) as the polymer (M); and curing the resultant with the irradiation of ultraviolet rays emitted from three 2 KW high-pressure mercury lamps.

FIG. 6 is a graph, illustrating a composition range when a polymer mixture is transparent, in which [a] (mass %) and [b] (mass %) are plotted.

It can be seen that the constitutional units of the polymer mixture are mixed with each other without phase separation in a range in which the composition of the polymer mixture satisfies the expression (5); and thus, the polymer mixture is transparent. In addition, in order to make the polymer mixture transparent, the following expression (5′) is more preferable than the expression (5).

0.35[b]≦[a]≦69−1.95[b] (5′)

In addition, in the rod lens according to the third aspect, as compositions of constitutional units of the polymer mixture in a range (Y, Z) of 0.5r to r from the center to the outer periphery, [a] is preferably 5 mass % to 72.5 mass % and [b] is preferably 2 mass % to 36.7 mass %.

By increasing the glass transition temperature of the rod lens, heat resistance can be improved. However, in order to impart sufficient heat resistance to the lens, it is necessary that the glass transition temperature of the lens be higher than or equal to 100° C.

However, in the polymer mixture constituting the rod lens, in order to increase a difference in refractive index between the center and the outer periphery of the lens, a large part of the monomer (c) unit is included in the polymer mixture with a low refractive index which is positioned closer to the outer periphery. Therefore, the glass transition temperature of the polymer which is positioned closer to the outer periphery of the lens is likely to be low.

In order to control the glass transition temperature of the lens to be higher than or equal to 100° C., the glass transition temperature of the polymer mixture is not necessarily higher than or equal to 100° C. at any positions from the center to the outer periphery. However, by controlling the glass transition temperature of the polymer, which is positioned in the outer periphery of the lens, to be around 100° C., sufficient heat resistance can be imparted to the lens. This effect is particularly significant when a hot-melt adhesive is used as an adhesive for fixing the lens to a substrate during the manufacturing of a rod lens array. The hot melt adhesive flows at a high temperature and is coated onto the lens and the substrate. Therefore, when the glass transition temperature of the lens outer peripheral portion is low, the refractive index distribution of the lens outer peripheral portion changes and thus, the resolution deteriorates. Accordingly, when the glass transition temperature of the polymer which is positioned in the outer periphery of the lens is around 100° C., sufficient heat resistance can be imparted to the lens.

Specifically, in the cross section of a rod lens 1 illustrated in FIG. 1, [a] is preferably 5 mass % to 72.5 mass % and more preferably 10 mass % to 30 mass %; and [b] is preferably 2 mass % to 36.7 mass % and more preferably 5 mass % to 30 mass % in the polymer mixture (III) which is positioned in the range (Y, Z) of 0.5r to r from the center to the outer periphery.

When [a] is greater than or equal to 5 mass % and [b] is greater than or equal to 2 mass % in the polymer mixture (III) positioned in the above-described range, the glass transition temperature of the lens outer peripheral portion approaches 100° C. and the glass transition temperature of the entire lens is higher than or equal to 100° C. Therefore, sufficient heat resistance is likely to be imparted to the lens. In addition, since the K value of the lens outer peripheral portion obtained from the expression (8) sufficiently approaches the K value of the lens center portion, a lens with a small chromatic aberration is likely to be obtained. In addition, when [a] is less than or equal to 72.5 mass % and [b] is less than or equal to 36.7 mass % in the polymer mixture (III) positioned in the above-described range, the (a) unit and the (b) unit are likely to be easily mixed with each other; and the polymer mixture is likely to be inhibited from becoming cloudy.

In this way, by appropriately selecting and arranging the composition of the polymer mixture which constitutes the lens, a plastic rod lens can be obtained in which transparency is excellent, chromatic aberration is small, color characteristic are excellent, heat resistance is excellent, and a high resolution can be maintained even after use in a high-temperature environment.

In the rod lenses according to the first, second, and third aspects of the present invention, it is preferable that an absorbing layer including at least an absorbent for absorbing at least a part of light, which is transmitted through the rod lenses, be formed in a range of 0.95r to r (outer peripheral portion) from the center to the outer periphery.

Generally, in a rod lens, an irregular portion of a refractive index distribution which is shifted from an ideal distribution is likely to be formed in a direction away from the center. In this case, if a light absorbing layer is formed in the outer peripheral portion of the rod lens, deterioration in optical characteristics caused by the irregular portion of the refractive index distribution is likely to be suppressed.

It is preferable that the thickness of the light absorbing layer be 5 μm to 100 μm. When the thickness of the light absorbing layer is in this range, flare light or crosstalk light is likely to be sufficiently removed and a sufficient intensity of transmitted light is likely to be secured.

As the light absorbent, one for absorbing at least a part of light in a wavelength range of 400 nm to 900 nm is preferably used because a light source which emits light in a wavelength range of 400 nm to 900 nm is generally used, for example, as a light source for LED printers.

Such a light absorbent is not particularly limited, and examples thereof include “Kayasorb CY-10” manufactured by Nippon Kayaku Co., Ltd “VALIFAST BLUE 2606” manufactured by Orient Chemical Industries Co., Ltd., and the like which absorb light in a wavelength range of 600 nm to the near-infrared range; “Diaresin Blue 4G” manufactured by Mitsubishi Chemical Corporation and the like which absorb light in a wavelength range of 600 nm to 700 nm; “Kayaset Blue ACR” manufactured by Nippon Kayaku Co., Ltd. and the like which absorb light in a wavelength range of 550 nm to 650 nm; “MS Magenta HM-1450” manufactured by Mitsui Toatsu Dye Ltd. and the like which absorb light in a wavelength range of 500 nm to 600 nm; and “MS Yellow HD-180” manufactured by Mitsui Toatsu Dye Ltd. and the like which absorb light in a wavelength range of 400 nm to 500 nm. In addition, examples of a light absorbent which absorbs all the light rays in a wavelength range of 400 nm to 900 nm include black dyes.

These light absorbents may be used alone or in a combination of two or more kinds.

### [Method of Manufacturing Plastic Rod Lens]

Next, a method of manufacturing the plastic rod lens according to the present invention will be described.

Examples of a method of manufacturing a rod lens in which a refractive index is reduced from the center to the outer periphery include an addition reaction method, a copolymerization method, a gel polymerization method, a monomer volatilization method, and a mutual diffusion method. Any of these methods may be used, but an interdiffusion method is preferable from the viewpoints of precision and productivity.

Hereinbelow, the interdiffusion method will be described.

First, an uncured laminate (hereinbelow, referred to as “filament”) is formed in which N uncured materials (refractive indices after curing satisfy n₁>n₂> . . . >n_{N} (N≧3)) are concentrically laminated using a multi-component spinning nozzle in an arrangement where the refractive indices after curing are sequentially reduced from the center to the outer periphery.

Next, in order to make a refractive index distribution between respective layers of the filament continuous, the filament is cured during or after an interdiffusion treatment in which materials are diffused between adjacent layers, thereby obtaining a rod lens base fiber (fiber-spinning process).

The interdiffusion treatment described herein is the treatment in which several seconds to several minutes of thermal history is given to the filament in a nitrogen atmosphere at 10° C. to 60° C., preferably, at 20° C. to 50° C.

Next, the rod lens base fibers obtained in the fiber-spinning process are optionally heated and drawn, are relaxed, and are appropriately cut into a predetermined size, thereby obtaining the rod lens according to the present invention.

As the uncured materials, for example, compositions including a radically polymerizable monomer can be used. As the radically polymerizable monomers, the above-described monomer (a), monomer (b), monomer (c), monomer (d), and monomer (m), and another monomer can be used. In addition, in order to promote spinning by imparting appropriate viscosity to the uncured materials, it is preferable that the uncured materials include a polymer (soluble polymer) soluble in the monomers.

Examples of the soluble polymer include polymethyl methacrylate (n=1.49, Tg=114° C.) and polymethyl methacrylate copolymers (n=1.47 to 1.50). Among these, polymethyl methacrylate (PMMA) is preferable from the viewpoints of excellent transparency and high refractive index. The numerical values in the parentheses are physical property values.

In order to cure the filament formed from the uncured materials, it is only necessary that a heat-curing catalyst and/or a photocuring catalyst be added to the uncured materials to perform a heat curing treatment and/or a photocuring treatment.

The heat curing treatment can be performed by heating the uncured materials including the heat-curing catalyst for a predetermined time in a curing treatment portion such as a heating furnace controlled to a constant temperature.

The photocuring treatment can be performed by irradiating the uncured materials including the photocuring catalyst with ultraviolet rays emitted from the surroundings. Examples of a light source used for the photocuring treatment include carbon arc lamps, ultrahigh pressure mercury lamps, high-pressure mercury lamps, middle-pressure mercury lamps, low-pressure mercury lamps, chemical lamps, xenon lamps, light emitting diodes (LED), and laser light sources which emit light in a wavelength of 150 nm to 600 nm.

As the heat-curing catalyst, for example, peroxide catalysts or azo catalysts can be used.

Examples of the photocuring catalyst include benzophenone, benzoin alkyl ether, 4′-isopropyl-2-hydroxy-2-methylpropiophenone, 1-hydroxycyclohexylphenylketone, benzyl methyl ketal, 2,2-diethoxyacetophenone, chlorothioxanthone, thioxanthone-based compounds, benzophenone-based compounds, ethyl 4-dimethylaminobenzoate, isoamyl 4-dimethylaminobenzoate, N-methyldiethanolamine, and triethylamine.

The content of the heat-curing catalyst or the photocuring catalyst is not particularly limited, but is preferably 0.01 parts by mass to 2.00 parts by mass with respect to 100 parts by mass of the uncured materials.

In addition, in order to stably manufacture the filament, it is preferable that 10 ppm to 1000 ppm of polymerization inhibitor for inhibiting polymerization until the curing treatment be added to the uncured materials.

Examples of the polymerization inhibitor include quinone compounds such as hydroquinone and hydroquinone monomethyl ether, amine-based compounds such as phenothiazine, and N-oxyl-based compounds such as 4-hydroxy-2,2,6,6-tetramethylpiperidine-N-oxyl.

The above-described fiber-spinning process can be performed using, for example, a device of manufacturing a plastic rod lens base fiber illustrated in FIG. 2.

This device 10 of manufacturing a plastic rod lens base fiber includes a concentric multi-component spinning nozzle 11; an receiving body 12 that receives a filament E extruded from the concentric multi-component spinning nozzle 11; an inert gas introducing pipe 13 that is connected to the receiving body 12 on a side of the concentric multi-component spinning nozzle 11; an inert gas discharge pipe 14 that is connected to the receiving body 12 on a side of an outlet 12a; a first light irradiation unit 15 that is provided outside the center of the receiving body in a longitudinal direction thereof; a second light irradiation unit 16 that is provided outside the receiving body 12 on a side of the inert gas discharge pipe 14; and a pull roller 17 that is arranged downstream of the receiving body 12.

In the receiving body 12, a portion from the concentric multi-component spinning nozzle 11 immediately before a portion, which is irradiated with light from the first light irradiation unit 15, is referred to as an interdiffusion portion 12b; the portion, which is irradiated with light from the first light irradiation unit 15, is referred to as an first curing portion 12c; and a portion, which is irradiated with light from the second light irradiation unit 16, is referred to as a second curing portion 12d.

When a rod lens base fiber is manufactured using the manufacturing device 10, inert gas (for example, nitrogen gas) is introduced from the inert gas introducing pipe 13 into the receiving body 12, and the inert gas in the receiving body 12 is discharged from the inert gas discharge pipe 14.

In such a state in which inert gas flows, the uncured filament E is extruded from the concentric multi-component spinning nozzle 11; and the filament is caused to pass through the receiving body 12. At this time, in the interdiffusion portion 12b, interdiffusion occurs between the respective layers constituting the filament E. In the first curing portion 12c, the filament E is irradiated with light by the first light irradiation unit 15 and curing advances while interdiffusion occurs between the respective layers. In the second curing portion 12d, the filament E is irradiated with light by the second light irradiation unit 16 and curing further advances.

Then, the filament E is pulled by the pull roller 17 to obtain a rod lens base fiber F from the receiving body 12.

The rod lens base fiber F obtained in the fiber-spinning process, optionally, may be continuously conveyed for the heating and drawing treatment; may be temporarily wound around a bobbin and then conveyed for the heating and drawing treatment; or may be cut into a desired length.

The heating and drawing treatment may be performed with a batch method or may be continuously performed. The heating and drawing treatment and the relaxation treatment may be continuously or discontinuously performed.

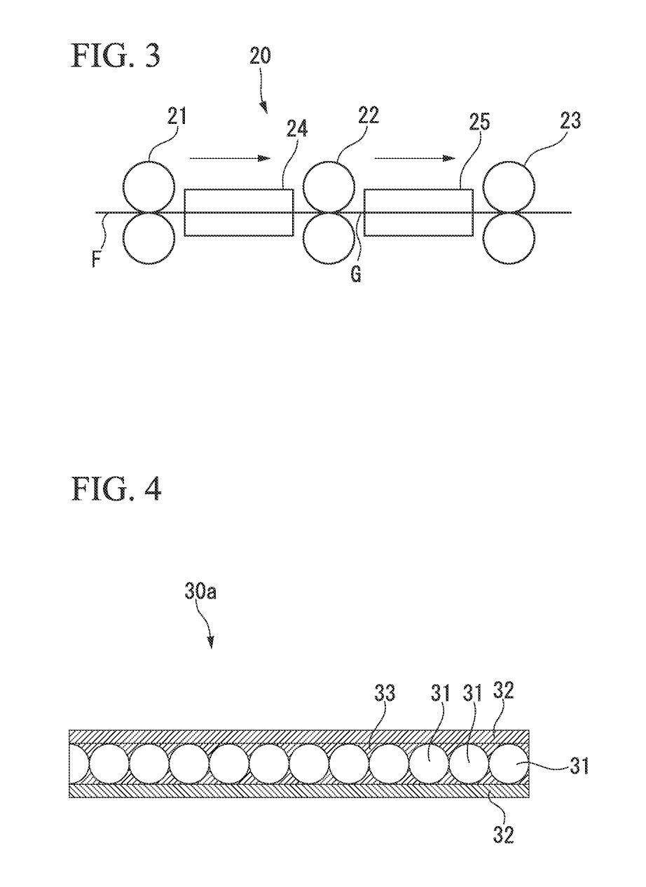

The heating and drawing treatment and the relaxation treatment can be performed using, for example, a drawing and relaxing device 20 illustrated in FIG. 3.

This drawing and relaxing device 20 includes a first nip roller 21, a second nip roller 22, a third nip roller 23, a first heating furnace 24 that is arranged between the first nip roller 21 and the second nip roller 22, and a second heating furnace 25 that is arranged between the second nip roller 22 and the third nip roller 23.

The heating and drawing treatment can be performed using the above-described drawing and relaxing device 20 with a method in which the rod lens base fiber F obtained by curing is supplied to the first heating furnace 24 by the first nip roller 21, the plastic rod lens base fiber F which has passed through the first heating furnace 24 is pulled by the second nip roller 22 at a higher rate than that of the first nip roller 21 and is drawn.

In the heating and drawing treatment, the temperature of an atmosphere in the heating furnace 24 is appropriately set according to a material of a rod lens, but is preferably higher than or equal to (the glass transition temperature (Tg) of the rod lens+20° C.). In addition, a draw ratio is appropriately determined according to a desired rod lens diameter and can be adjusted by a peripheral speed ratio of the first nip roller 21 and the second nip roller 22.

The relaxation treatment can be performed using the above-described drawing and relaxing device 20, for example, with a method in which a drawn rod lens base fiber G is supplied to the second heating furnace 25 by the second nip roller 22; and the plastic rod lens base fiber G which has passed through the second heating furnace 25 is pulled by the third nip roller 23 at a lower rate than that of the second nip roller 22 and is relaxed.

In the relaxation treatment, the temperature of an atmosphere in the heating furnace 25 is appropriately set according to a material of a rod lens, but is preferably higher than or equal to Tg of the rod lens. In addition, a relaxation ratio (length after relaxation treatment/length before relaxation treatment) is appropriately determined according to a desired rod lens diameter, but is preferably about 99/100 to 1/2. When the relaxation treatment is performed at such a relaxation ratio, the contraction of the rod lens can be suppressed. When the relaxation ratio is too low, unevenness in lens diameter is great, which is not preferable. The relaxation ratio can be adjusted by a peripheral speed ratio of the second nip roller 22 and the third nip roller 23.

According to the above-described method, plural polymers overlap in a concentric shape to form a polymer mixture; and a rod lens having a refractive index distribution in which a refractive index is continuously reduced from the center to the outer periphery can be obtained. This polymer mixture is cured in a state where monomers constituting the polymers are diffused between the respective layers.

The rod lens is obtained by performing curing in the state where the uncured materials are diffused between the respective layers. Therefore, the central refractive index n₀ of the rod lens is lower than or equal to the refractive index after curing of an uncured material as a rod lens-forming solution which is positioned in the center of the multi-component spinning nozzle. In addition, the refractive index at the outermost peripheral portion of the rod lens is higher than or equal to the refractive index after curing of an uncured material as a rod lens-forming solution which is positioned in the outermost periphery of the multi-component spinning nozzle.

Therefore, a difference between the central refractive index of the rod lens and the refractive index of the outer peripheral portion of the rod lens is likely to be less than a difference between the refractive index of a polymer mixture which is obtained by curing an uncured material alone positioned in the center of the multi-component spinning nozzle and the refractive index of a polymer mixture which is obtained by curing an uncured material alone positioned in the outer peripheral portion of the multi-component spinning nozzle.

For the above-described reason, according to the first aspect, in order to control the difference in refractive index between the center and the outer peripheral portion of the rod lens to be 0.003 to 0.06, it is preferable that the difference between the refractive index of a polymer mixture which is obtained by curing an uncured material alone positioned in the center of the multi-component spinning nozzle and the refractive index of a polymer mixture which is obtained by curing an uncured material alone positioned in the outer peripheral portion of the multi-component spinning nozzle, be 0.008 to 0.065.

In addition, according to the second aspect, in order to control the difference in refractive index between the center and the outer peripheral portion of the rod lens to be 0.02 to 0.06, it is preferable that the difference between the refractive index of a polymer mixture which is obtained by curing an uncured material alone positioned in the center of the multi-component spinning nozzle and the refractive index of a polymer mixture which is obtained by curing an uncured material alone positioned in the outer peripheral portion of the multi-component spinning nozzle, be 0.025 to 0.065.

In addition, according to the third aspect, in order to control the difference in refractive index between the center and the outer peripheral portion of the rod lens to be 0.003 to 0.02, it is preferable that the difference between the refractive index of a polymer mixture which is obtained by curing an uncured material alone positioned in the center of the multi-component spinning nozzle and the refractive index of a polymer mixture which is obtained by curing an uncured material alone positioned in the outer peripheral portion of the multi-component spinning nozzle, be 0.008 to 0.025.

[Plastic Rod Lens Array]

Next, a plastic rod lens array (hereinbelow, simply referred to as “rod lens array”) will be described

A rod lens array according to the present invention includes at least one rod lens line in which the above-described plural rod lenses according to the present invention are arranged and fixed between two substrates such that central axes of the rod lenses are substantially parallel to each other.

As an example of the rod lens array, one illustrated in FIG. 4 in which two or more rod lenses 31, 31, and . . . are arranged and fixed in a line between two substrates 32 and 32 may be used.

Adjacent rod lenses 31 and 31 may be arranged in close contact with each other or at a given interval.

In addition, in a lens array in which the same kind of rod lenses are laminated in two or more stages, it is preferable that the rod lenses be arranged in a trefoil shape such that intervals between the rod lenses are minimum.

The substrates 32 constituting the rod lens array 30 may have a plate shape or may have a configuration in which, for example, U-shaped or V-shaped grooves having the rod lenses 31 arranged and accommodated at regular intervals are formed.

A material of the substrates 32 is not particularly limited, but is preferably a material which is easily processed in a process of manufacturing a rod lens array. Specifically, various thermoplastic resins, various thermosetting resins, and the like are preferable; and acrylic resins, ABS resins, polyimide resins, liquid crystal polymers, epoxy resins, and the like are particularly preferable. In addition, as a base material or reinforcing material of the substrates 32, fiber or paper may be used, or a mold releasing agent, a dye, a pigment, a antistatic agent, and the like may be added to the substrates.

An adhesive 33 is used for fixing the rod lenses 31 between the substrates 32. The adhesive 33 is not particularly limited as long as it has an adhesive force to the extent that the rod lens 31 and the substrate 32; or the rod lenses 31 and 31 can be bonded to each other. For example, adhesives which can be coated in a thin film shape, spray adhesives, and hot melt adhesives can be used.

In addition, as a method of applying the adhesive to the substrates 32 and the rod lenses 31, well-known coating methods such as a screen printing method and a spray coating method can be used according to the kind of the additive.

The rod lens array 30 may include a surface protective layer for preventing the attachment or scratch of dust on a lens end surface. As this surface protective layer, an existing UV curable hard coating agent may be used; or a cover glass may be provided on a lens end surface.

When the rod lens according to the second aspect is used in the rod lens array according to the present invention, the light intensity of the lens is high and heat resistance is excellent. Therefore, for example, in LED printers, even when the lens is used in a high-temperature environment made by an increase in printing speed and a reduction in the size of the apparatus, deterioration in optical characteristics such as resolution is suppressed and thus the rod lens can be preferably used.

In addition, when the rod lens according to the third aspect is used in the rod lens array according to the present invention, chromatic aberration is small and heat resistance is excellent. Therefore, for example, in copying machines, even when the lens is used in a high-temperature environment made by an increase in reading speed and a reduction in the size of the apparatus, deterioration in optical characteristics such as resolution is suppressed and thus the rod lens can be preferably used.

### [LED Printer Head]

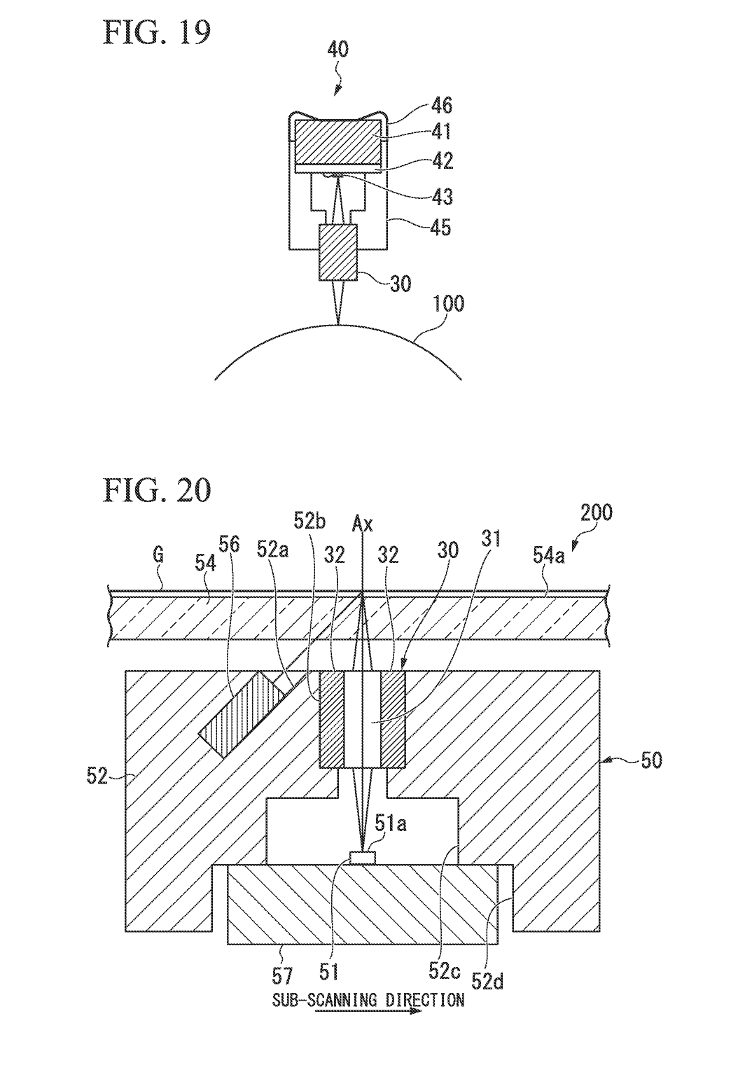

Next, an LED printer head according to the present invention will be described using FIG. 19.

An LED printer head 40 according to the present invention is obtained by combining the above-described rod lens array 30 with an LED array 43 in which plural light emitting diodes (LED) as light emitting elements are arranged. This LED printer head 40 include a housing 41 as a support; a printer substrate 42 on which a driving device of the light emitting element array is mounted; the LED array 43 that emits exposure light; the rod lens array 30 that exposes light emitted from the LED array 43 to a surface of a photoconductor drum 100 to form an image thereon; a rod lens array holder 45 that supports the rod lens array 30 and shields the LED array 43 from the outside; and a plate spring 46 that biases the housing 41 toward the rod lens array 30.

The housing 41 is formed with a block or a sheet material of aluminum, SUS, or the like and supports the printer substrate 42 and the LED array 43. In addition, the rod lens array holder 45 supports the housing 41 and the rod lens array 30 and is constituted such that a light emitting point of the LED array 43 matches with a focal point of the rod lens array 30. Furthermore, the rod lens array holder 45 is arranged such that the LED array 43 is sealed. Therefore, dust from the outside is not attached on the LED array 43. On the other hand, the plate spring 46 biases the housing 41 toward the rod lens array 30 such that a positional relationship between the LED array 43 and the rod lens array 30 is maintained.

The LED printer head 40 constituted as above can move in an optical axis direction of the SELFOC (registered trademark) lens array 24 through an adjusting screw (not illustrated) and is adjusted such that an image position (focal point) of the rod lens array 30 is positioned on the surface of the photoconductor drum 100.

In the LED array 43, plural LED chips are precisely arranged on the substrate 42 in a line in a direction parallel to an axis direction of the photoconductor drum 100. Likewise, in the rod lens array 30, the rod lenses 31 are precisely arranged in a line in the direction parallel to the axis direction of the photoconductor drum 100. Light emitted from the LED array 43 is exposed to the surface of the photoconductor drum 100 to form an electrostatic latent image thereon.

### [Color Image Sensor Head]

Next, a color image sensor head according to the present invention will be described using FIG. 20.

A color image sensor head 50 according to the present invention is obtained by combining the above-described rod lens array 30 according to the present invention with a line image sensor (photoelectric conversion element) 51. This color image sensor head 50 includes a linear light source 56 that irradiates a document G, placed on a document placement surface 54a of a document tray 54, with light; the rod lens array 30 that collects light reflected from the document G; the line image sensor 51 that receives the light collected by the rod lens array 30; and a case 52 that accommodates the linear light source 56, the rod lens array 30, and the line image sensor 51.

The case 52 is formed in a substantially rectangular shape. A first concave portion 52a and a second concave portion 52b are formed on an upper surface of the case 52; and a third concave portion 52c is formed on a lower surface of the case 52. The case 52 is formed by the injection molding of a resin. When the case 52 is formed by injection molding, the case can be easily formed at a low cost. The linear light source 56 is obliquely fixed in the first concave portion 52a. The linear light source 56 is fixed such that an optical axis of irradiated light passes through an intersection between an optical axis Ax of the rod lens array 30 and the document placement surface 54a; or the vicinity of the intersection.

The rod lens array 30 is fixed in the second concave portion 52b. A substrate 57 including the line image sensor 51 is attached in the third concave portion 52c. The substrate 57 is fixed such that an upper surface thereof comes into contact with a step portion 52d provided in the third concave portion 52c.

The rod lens array 30 is mounted on an image reading apparatus 200 such that a lens arrangement direction thereof matches with a main scanning direction. The rod lens array 30 receives linear light which is reflected from the document G positioned above the rod lens array 30 and forms an erecting equal-magnification image on an image surface positioned below the rod lens array 30, that is, on a light receiving surface 51a of the line image sensor 51. Using a driving mechanism, the image reading apparatus 200 can cause the color image sensor head 50 to scan the document G in a sub-scanning direction and thus can read the document G.

### EXAMPLES

Hereinbelow, the present invention will be described in detail referring to Examples. However, the present invention is not limited thereto.

### <Evaluation for Transparency>

A film of each polymer of samples No. 1 to 207 was evaluated for transparency by visual inspection.

### <Measurement of Refractive Index, Abbe Number, and Refractive Index Distribution>

The measurement was performed using an INTERFOCO interference microscope manufactured by Carl Zeiss.

### <Measurement of Glass Transition Temperature (Tg)>

The glass transition temperature (Tg) was measured under the following conditions using a differential thermal analyzer (Model No. DSC6220C) manufactured by SII Nano Technology Inc.

Under nitrogen gas stream (flow rate: 100 mL/min)

Measurement temperature range: start temperature of 30° C., limit temperature of 200° C.

Temperature rise rate: 10° C./min

A pretreatment of an evaluation specimen was performed as follows.

A specimen of a film or a rod lens of each polymer of samples No. 1 to 207 was held in the molten state at 150° C. for 5 minutes, and was rapidly cooled with dry ice for 1 minute. After removing a residual stress, the resultant was left to stand in a desiccator for 15 minutes or longer to remove frost attached on the sample.

The glass transition temperature (Tg) was obtained with a well-known method. That is, from a DSC curve obtained by the measurement, an intersection between an extension line of a base line in a glass region; and a tangent line at an inflection point of the DSC curve appearing in the vicinity of a glass transition region, was obtained as the glass transition temperature (Tg).

### <Measurement of Conjugation Length TC and Resolution (Average MTF)>

The measurement was performed with a line chart having a spatial frequency of 12 line pair/mm (Lp/mm).

Specifically, light (wavelength 470 nm, 525 nm, or 630 nm), emitted from a light source was incident through a line chart on a rod lens array in which both end surfaces perpendicular to an optical axis were polished. Then, a grid image was read by a CCD line sensor provided on an image surface. The maximum value (iₘₐₓ) and the minimum value (iₘᵢₙ) in the measured light intensity were measured to obtain an MTF (modulation transfer function) according to the following expression (9).

MTF(%)={(iₘₐₓ−iₘᵢₙ)/(iₘₐₓ+iₘᵢₙ)}×100 (9)

At this time, a distance between an incident end of the rod lens array and the line chart was the same as a distance between an exit end of the rod lens array and the CCD line sensor. The line chart and the CCD line sensor moved symmetrically to the rod lens array to measure the MTF. At this time, a distance between the line chart and the CCD line sensor at the maximum value of MTF is the conjugation length TC.

Next, while maintaining the distance between the line chart and the CCD line sensor at the conjugation length, the entire rod lens array was scanned to measure MTF values at 50 points. The average (average MTF) of the MTF values was obtained as an index of resolution. The greater the average MTF value, the higher the resolution.

The spatial frequency described herein indicates the number of line pairs provided at a width of 1 mm in which one line pair is composed of a white line and a black line.

### <Measurement of Light Intensity>

The light intensity was measured using an opal diffuser instead of the line chart used for the measurement of resolution.

Specifically, light (wavelength: 525 nm) emitted from a light source was incident on a rod lens array through a diffuser. The light intensity output was measured using a CCD line sensor provided on an image surface. The maximum value (iₘₐₓ) in the measured light intensity was recorded. At this time, a distance between an incident end of the rod lens array and the diffuser was the same as a distance between an exit end of the rod lens array and the CCD line sensor; and a distance between the diffuser and the CCD line sensor is the conjugation length.

Next, while maintaining the distance between the line chart and the CCD line sensor at the conjugation length, the entire rod lens array was scanned to measure light intensity output values at 50 points. The average (average light intensity) of the light intensity output values was obtained. When the average light intensity of the SELFOC (registered trademark) lens array SLA12D (manufactured by Nippon Sheet Glass Co., Ltd.) as a generally used rod lens was 100%, the light intensity percentage (%) of a target lens was obtained as an index of the light intensity. As the light intensity value is higher, printing can be performed at a higher speed.

### <Heat Resistance Test>

A rod lens array was disposed in a thermohygrostat in which the temperature and the humidity were set to 70° C. and 90% RH, respectively. The average MTF values before and after the test were obtained at a wavelength of 470 nm, 525 nm, or 630 nm.

### [Preparation Examples of Polymer Mixtures (Samples No. 1 to 207)]

0.25 parts by mass of 1-hydroxycyclohexyl phenyl ketone (HCPK) as a photocuring catalyst was mixed with 100 parts by mass of each mixture of monomers and polymers shown in Tables 1 to 7. The mixture was held between two slide glasses and was irradiated 8 times with ultraviolet light having an intensity of 5000 ml/cm² by three 2 KW high-pressure mercury lamps for curing. As a result, film polymer mixture samples No. 1 to 207 (mixtures of PMMA and other polymers) having a thickness of 0.3 mm were obtained.

Samples No. 1 to 131 were evaluated for the transparency, refractive index, and glass transition temperature of the polymer mixtures, and the results thereof are shown in Tables 1 to 5. Among the results, the results for the transparency are illustrated in FIGS. 5 to 9 with the triangular phase diagrams and are illustrated in FIG. 10 in which the content of the aromatic ring-containing monomer (a) and the content of the (meth)acrylate (b) unit which has a branched hydrocarbon group having 3 or more carbon atoms are plotted. In addition, among the results, the results for the glass transition temperature are illustrated in FIGS. 11 to 15 with the triangular phase diagrams and are illustrated in FIG. 16 in which the content of the (meth)acrylate (b) unit which has a branched hydrocarbon group having 3 or more carbon atoms and the content of the fluorine-containing monomer (c) unit are plotted.

TABLE 1

| | Composition (Part(s) by Mass) | | | | | | Polymer Properties | | |
|---|---|---|---|---|---|---|---|---|---|
| Sample No. | PhMA | 4FM | MMA | PMMA | TBMA | TOTAL | Transparency | Refractive Index | Tg (° C.) |
| 1 | | 45 | 10 | 45 | 0 | 100 | Transparent | 1.463 | 100.5 |
| 2 | 45 | | 10 | 45 | 0 | 100 | Transparent | 1.522 | 117.6 |
| 3 | 22.5 | 22.5 | 10 | 45 | 0 | 100 | Transparent | 1.494 | 107.2 |
| 4 | | 35 | 20 | 45 | 0 | 100 | Transparent | 1.470 | 101.0 |
| 5 | 35 | | 20 | 45 | 0 | 100 | Transparent | 1.515 | 116.8 |
| 6 | 17.5 | 17.5 | 20 | 45 | 0 | 100 | Transparent | 1.493 | 110.6 |
| 7 | 20 | 40 | 0 | 40 | 0 | 100 | Transparent | 1.481 | 100.7 |
| 8 | 40 | 20 | 0 | 40 | 0 | 100 | Transparent | 1.507 | 110.5 |
| 9 | | 70 | 0 | 30 | 0 | 100 | Transparent | 1.445 | 88.8 |
| 10 | | 60 | 0 | 40 | 0 | 100 | Transparent | 1.453 | 92.2 |
| 11 | 60 | | 0 | 40 | 0 | 100 | Transparent | 1.532 | 118.8 |
| 12 | 35 | 35 | 0 | 30 | 0 | 100 | Transparent | 1.495 | 103.6 |
| 13 | 20 | 50 | 0 | 30 | 0 | 100 | Transparent | 1.474 | 97.1 |
| 14 | 50 | 20 | 0 | 30 | 0 | 100 | Transparent | 1.514 | 110.3 |
| 15 | | 80 | 0 | 20 | 0 | 100 | Transparent | 1.438 | 85.5 |
| 16 | 40 | 40 | 0 | 20 | 0 | 100 | Transparent | 1.495 | 102.1 |
| 17 | 60 | 20 | 0 | 20 | 0 | 100 | Transparent | 1.521 | 111.0 |
| 18 | 60 | 10 | 0 | 30 | 0 | 100 | Transparent | 1.527 | 114.9 |
| 19 | 60 | | 10 | 30 | 0 | 100 | Transparent | 1.532 | 118.8 |
| 20 | 60 | | 20 | 20 | 0 | 100 | Transparent | 1.532 | 118.8 |
| 21 | 60 | 15 | 0 | 25 | 0 | 100 | Transparent | 1.524 | 112.9 |
| 22 | | 25 | 30 | 45 | 0 | 100 | Transparent | 1.477 | 104.6 |
| 23 | 25 | | 30 | 45 | 0 | 100 | Transparent | 1.509 | 116.0 |
| 24 | 12.5 | 12.5 | 30 | 45 | 0 | 100 | Transparent | 1.493 | 110.2 |
| 25 | | 15 | 40 | 45 | 0 | 100 | Transparent | 1.483 | 110.2 |
| 26 | 15 | | 40 | 45 | 0 | 100 | Transparent | 1.502 | 115.2 |
| 27 | 7.5 | 7.5 | 40 | 45 | 0 | 100 | Transparent | 1.493 | 111.7 |
| 28 | | 5 | 50 | 45 | 0 | 100 | Transparent | 1.489 | 112.1 |
| 29 | 55 | | 5 | 40 | 0 | 100 | Transparent | 1.529 | 118.4 |
| 30 | 70 | | 0 | 30 | 0 | 100 | Cloudy | 1.539 | 119.6 |
| 31 | 65 | | 0 | 35 | 0 | 100 | Cloudy | 1.536 | 119.2 |
| 32 | 65 | 5 | 0 | 30 | 0 | 100 | Cloudy | 1.533 | 117.2 |
| 33 | 70 | 10 | 0 | 20 | 0 | 100 | Cloudy | 1.534 | 115.6 |
| 34 | 70 | 5 | 0 | 25 | 0 | 100 | Cloudy | 1.537 | 117.6 |
| 35 | 65 | 15 | 0 | 20 | 0 | 100 | Cloudy | 1.528 | 113.3 |
| 36 | 65 | 10 | 0 | 25 | 0 | 100 | Cloudy | 1.530 | 115.3 |
| 37 | 65 | | 5 | 30 | 0 | 100 | Cloudy | 1.536 | 119.2 |
| 38 | 65 | 5 | 10 | 20 | 0 | 100 | Cloudy | 1.533 | 117.2 |

TABLE 2

| | Composition (Part(s) by Mass) | | | | | | Polymer Properties | | |
|---|---|---|---|---|---|---|---|---|---|
| Sample No. | PhMA | 4FM | MMA | PMMA | TBMA | TOTAL | Transparency | Refractive Index | Tg (° C.) |
| 39 | 55 | | 5 | 35 | 5 | 100 | Transparent | 1.527 | 118.0 |
| 40 | 55 | 10 | 0 | 30 | 5 | 100 | Transparent | 1.522 | 114.1 |
| 41 | 50 | 20 | 0 | 25 | 5 | 100 | Transparent | 1.513 | 109.9 |
| 42 | 50 | 30 | 0 | 15 | 5 | 100 | Transparent | 1.507 | 106.2 |
| 43 | 50 | | 5 | 40 | 5 | 100 | Transparent | 1.524 | 117.6 |
| 44 | 40 | | 10 | 45 | 5 | 100 | Transparent | 1.517 | 116.8 |
| 45 | 10 | 65 | 0 | 20 | 5 | 100 | Transparent | 1.455 | 90.9 |
| 46 | 20 | 55 | 0 | 20 | 5 | 100 | Transparent | 1.469 | 95.0 |
| 47 | 30 | 45 | 0 | 20 | 5 | 100 | Transparent | 1.483 | 99.3 |
| 48 | 40 | 35 | 0 | 20 | 5 | 100 | Transparent | 1.497 | 103.6 |
| 49 | 30 | 35 | 0 | 30 | 5 | 100 | Transparent | 1.490 | 102.9 |
| 50 | 10 | 55 | 0 | 30 | 5 | 100 | Transparent | 1.462 | 94.3 |
| 51 | 25 | 25 | 10 | 35 | 5 | 100 | Transparent | 1.492 | 106.1 |
| 52 | 30 | 10 | 15 | 40 | 5 | 100 | Transparent | 1.505 | 112.2 |
| 53 | 40 | 15 | 0 | 40 | 5 | 100 | Transparent | 1.509 | 111.0 |
| 54 | 5 | 35 | 15 | 40 | 5 | 100 | Transparent | 1.472 | 101.0 |
| 55 | 12.5 | 37.5 | 0 | 45 | 5 | 100 | Transparent | 1.476 | 100.7 |
| 56 | 10 | 25 | 15 | 45 | 5 | 100 | Transparent | 1.482 | 105.0 |
| 57 | 10 | 15 | 25 | 45 | 5 | 100 | Transparent | 1.488 | 110.5 |
| 58 | 25 | | 20 | 50 | 5 | 100 | Transparent | 1.507 | 115.6 |
| 59 | 7.5 | 7.5 | 30 | 50 | 5 | 100 | Transparent | 1.491 | 111.4 |
| 60 | 65 | 5 | 0 | 25 | 5 | 100 | Cloudy | 1.531 | 116.8 |
| 61 | 65 | | 0 | 30 | 5 | 100 | Cloudy | 1.534 | 118.8 |
| 62 | 60 | | 0 | 35 | 5 | 100 | Cloudy | 1.531 | 118.4 |
| 63 | 65 | | 0 | 30 | 5 | 100 | Cloudy | 1.534 | 118.8 |
| 64 | 60 | 10 | 0 | 25 | 5 | 100 | Cloudy | 1.525 | 114.5 |
| 65 | 65 | 10 | 0 | 20 | 5 | 100 | Cloudy | 1.529 | 114.9 |
| 66 | 60 | 20 | 0 | 15 | 5 | 100 | Cloudy | 1.520 | 109.0 |
| 67 | 65 | 15 | 0 | 15 | 5 | 100 | Cloudy | 1.526 | 113.0 |
| 68 | | 75 | 0 | 20 | 5 | 100 | Cloudy | 1.441 | 86.8 |
| 69 | 0 | 25 | 25 | 45 | 5 | 100 | Cloudy | 1.475 | 104.3 |
| 70 | | 30 | 15 | 50 | 5 | 100 | Cloudy | 1.472 | 102.5 |

TABLE 3

| | Composition (Part(s) by Mass) | | | | | | Polymer Properties | | |
|---|---|---|---|---|---|---|---|---|---|
| Sample No. | PhMA | 4FM | MMA | PMMA | TBMA | TOTAL | Transparency | Refractive Index | Tg (° C.) |
| 71 | 30 | | 5 | 45 | 20 | 100 | Transparent | 1.506 | 114.9 |
| 72 | 40 | | 0 | 40 | 20 | 100 | Transparent | 1.513 | 115.7 |
| 73 | 20 | 20 | 0 | 40 | 20 | 100 | Transparent | 1.488 | 106.6 |
| 74 | 25 | 25 | 0 | 30 | 20 | 100 | Transparent | 1.488 | 105.1 |
| 75 | 30 | 30 | 0 | 20 | 20 | 100 | Transparent | 1.489 | 103.7 |
| 76 | 20 | | 10 | 50 | 20 | 100 | Transparent | 1.500 | 114.1 |
| 77 | 10 | 10 | 10 | 50 | 20 | 100 | Transparent | 1.488 | 110.9 |
| 78 | 30 | 10 | 0 | 40 | 20 | 100 | Transparent | 1.501 | 111.1 |
| 79 | 30 | 20 | 0 | 30 | 20 | 100 | Transparent | 1.495 | 107.3 |
| 80 | 40 | 10 | 0 | 30 | 20 | 100 | Transparent | 1.507 | 111.9 |
| 81 | 40 | 20 | 0 | 20 | 20 | 100 | Transparent | 1.501 | 108.1 |
| 82 | 10 | 20 | 5 | 45 | 20 | 100 | Transparent | 1.482 | 105.8 |
| 83 | 10 | 30 | 0 | 40 | 20 | 100 | Transparent | 1.475 | 102.2 |
| 84 | 10 | 40 | 0 | 30 | 20 | 100 | Transparent | 1.469 | 98.6 |
| 85 | 20 | 40 | 0 | 20 | 20 | 100 | Transparent | 1.476 | 99.3 |
| 86 | 10 | 50 | 0 | 20 | 20 | 100 | Transparent | 1.462 | 95.1 |
| 87 | 5 | 10 | 20 | 45 | 20 | 100 | Cloudy | 1.484 | 110.2 |
| 88 | 5 | 45 | 0 | 30 | 20 | 100 | Cloudy | 1.462 | 96.5 |
| 89 | | 30 | 5 | 45 | 20 | 100 | Cloudy | 1.469 | 101.5 |
| 90 | | | 30 | 50 | 20 | 100 | Cloudy | 1.487 | 112.6 |
| 91 | | 40 | 0 | 40 | 20 | 100 | Cloudy | 1.462 | 97.9 |
| 92 | 50 | | 0 | 30 | 20 | 100 | Cloudy | 1.519 | 116.5 |
| 93 | | 50 | 0 | 30 | 20 | 100 | Cloudy | 1.456 | 94.4 |
| 94 | 60 | | 0 | 20 | 20 | 100 | Cloudy | 1.526 | 117.3 |
| 95 | | 60 | 0 | 20 | 20 | 100 | Cloudy | 1.449 | 90.9 |
| 96 | | 20 | 10 | 50 | 20 | 100 | Cloudy | 1.475 | 105.1 |
| 97 | 50 | 10 | 0 | 20 | 20 | 100 | Cloudy | 1.514 | 112.6 |

TABLE 4

| | Composition (Part(s) by Mass) | | | | | | Polymer Properties | | |
|---|---|---|---|---|---|---|---|---|---|
| Sample No. | PhMA | 4FM | MMA | PMMA | TBMA | TOTAL | Transparency | Refractive Index | Tg (° C.) |
| 98 | 15 | | 0 | 45 | 40 | 100 | Transparent | 1.492 | 112.3 |
| 99 | 17.5 | 17.5 | 0 | 25 | 40 | 100 | Transparent | 1.483 | 106.0 |
| 100 | 20 | 10 | 0 | 30 | 40 | 100 | Transparent | 1.489 | 108.9 |
| 101 | 15 | 5 | 0 | 40 | 40 | 100 | Transparent | 1.489 | 110.4 |
| 102 | 15 | 35 | 0 | 10 | 40 | 100 | Transparent | 1.471 | 99.4 |
| 103 | | 15 | 0 | 45 | 40 | 100 | Cloudy | 1.474 | 105.6 |
| 104 | | | 15 | 45 | 40 | 100 | Cloudy | 1.482 | 111.2 |
| 105 | 25 | | 0 | 35 | 40 | 100 | Cloudy | 1.498 | 113.1 |
| 106 | | 25 | 0 | 35 | 40 | 100 | Cloudy | 1.468 | 101.9 |
| 107 | 12.5 | 12.5 | 0 | 35 | 40 | 100 | Cloudy | 1.483 | 107.4 |
| 108 | 35 | | 0 | 25 | 40 | 100 | Cloudy | 1.504 | 113.9 |
| 109 | | 35 | 0 | 25 | 40 | 100 | Cloudy | 1.461 | 98.3 |
| 110 | 45 | | 0 | 15 | 40 | 100 | Cloudy | 1.510 | 114.7 |
| 111 | | 45 | 0 | 15 | 40 | 100 | Cloudy | 1.455 | 94.8 |
| 112 | 22.5 | 22.5 | 0 | 15 | 40 | 100 | Cloudy | 1.483 | 104.5 |
| 113 | 10 | 20 | 0 | 30 | 40 | 100 | Cloudy | 1.477 | 104.5 |
| 114 | 30 | 10 | 0 | 20 | 40 | 100 | Cloudy | 1.495 | 109.7 |
| 115 | 40 | 10 | 0 | 10 | 40 | 100 | Cloudy | 1.502 | 109.8 |
| 116 | 30 | 20 | 0 | 10 | 40 | 100 | Cloudy | 1.490 | 106.0 |
| 117 | 10 | 30 | 0 | 20 | 40 | 100 | Cloudy | 1.471 | 99.8 |
| 118 | | 10 | 5 | 45 | 40 | 100 | Cloudy | 1.477 | 107.4 |
| 119 | 10 | | 5 | 45 | 40 | 100 | Cloudy | 1.488 | 111.9 |
| 120 | 5 | 15 | 0 | 40 | 40 | 100 | Cloudy | 1.477 | 105.9 |
| 121 | 7.5 | 7.5 | 0 | 45 | 40 | 100 | Cloudy | 1.483 | 108.9 |

TABLE 5

| | Composition (Part(s) by Mass) | | | | | | Polymer Properties | | |
|---|---|---|---|---|---|---|---|---|---|
| Sample No. | PhMA | 4FM | MMA | PMMA | TBMA | TOTAL | Transparency | Refractive Index | Tg (° C.) |
| 122 | 10 | 10 | 0 | 30 | 50 | 100 | Cloudy | 1.481 | 107.5 |
| 123 | 20 | 10 | 0 | 20 | 50 | 100 | Cloudy | 1.487 | 108.2 |
| 124 | 10 | 20 | 0 | 20 | 50 | 100 | Cloudy | 1.475 | 103.8 |
| 125 | 20 | 20 | 0 | 10 | 50 | 100 | Cloudy | 1.481 | 104.5 |
| 126 | | 10 | 10 | 30 | 50 | 100 | Cloudy | 1.474 | 106.7 |
| 127 | 10 | | 10 | 30 | 50 | 100 | Cloudy | 1.486 | 111.2 |
| 128 | | 30 | 0 | 20 | 50 | 100 | Cloudy | 1.462 | 99.5 |
| 129 | 30 | | 0 | 20 | 50 | 100 | Cloudy | 1.498 | 112.8 |
| 130 | | 40 | 0 | 10 | 50 | 100 | Cloudy | 1.456 | 95.9 |
| 131 | 40 | | 0 | 10 | 50 | 100 | Cloudy | 1.504 | 113.6 |

Samples No. 132 to 207 were evaluated for the transparency, refractive index, glass transition temperature, and Abbe number of the polymer mixtures, and the results thereof are shown in Tables 6 and 7. Among the results, the results for the transparency are illustrated in FIG. 18 in which the content of the aromatic ring-containing monomer (a) and the content of the (meth)acrylate (b) unit which has a branched hydrocarbon group having 3 or more carbon atoms are plotted.

TABLE 6

| | | | | | | | | | | Polymer Properties | | | | |
|---|---|---|---|---|---|---|---|---|---|---|---|---|---|---|
| Sample | Composition (Part(s) by Mass) | | | | | | | | | | Refractive | Abbe | K = n_{D} − | Tg |
| No. | PhMA | BzMA | 4FM | 8FM | MMA | PMMA | TCDMA | TBMA | TOTAL | Transparency | Index | Number | V/(n_{D} − 1) | (° C.) |
| 132 | 0 | | | | 24 | 46 | 30 | 0 | 100 | Transparent | 1.502 | 55.7 | 166.5 | 114.1 |
| 133 | 3 | | | | 30.6 | 45 | 16.4 | 5 | 100 | Transparent | 1.498 | 54.8 | 164.8 | 109.4 |
| 134 | 5.8 | | | | 36.2 | 48 | | 10 | 100 | Transparent | 1.493 | 54.1 | 163.7 | 103.7 |
| 135 | 12.1 | | | 15 | 13.9 | 44.8 | | 14.2 | 100 | Transparent | 1.485 | 52.8 | 161.5 | 99 |
| 136 | 15.9 | | | 30 | 3.4 | 40.3 | | 10.4 | 100 | Transparent | 1.477 | 52.2 | 161.6 | 96 |
| 137 | 5 | | | | 22 | 43 | 30 | 0 | 100 | Transparent | 1.506 | 54.2 | 161.3 | 114.6 |
| 138 | 6.3 | | | | 19.2 | 43 | 26.5 | 5 | 100 | Transparent | 1.504 | 53.8 | 160.5 | 113.1 |
| 139 | 8 | | | | 17.2 | 43 | 21 | 10.8 | 100 | Transparent | 1.502 | 53.3 | 159.5 | 110.9 |
| 140 | 9.9 | | | | 24.7 | 47 | 6.6 | 11.8 | 100 | Transparent | 1.498 | 52.8 | 158.9 | 106.1 |
| 141 | 14.5 | | | 15 | 18.5 | 45 | | 7 | 100 | Transparent | 1.439 | 52.1 | 158.6 | 99.6 |
| 142 | 7.5 | | | | 15 | 44 | 30 | 3.5 | 100 | Transparent | 1.506 | 53.4 | 158.9 | 114.5 |
| 143 | 3 | | | | 17 | 44 | 25.5 | 5.5 | 100 | Transparent | 1.505 | 53.3 | 158.9 | 112.8 |
| 144 | 8.8 | | | | 17.7 | 44.5 | 19.5 | 10.5 | 100 | Transparent | 1.501 | 53.1 | 158.9 | 110.1 |
| 145 | 9.7 | | | | 17 | 45.8 | 11.5 | 16 | 100 | Transparent | 1.498 | 52.8 | 158.8 | 107.4 |
| 146 | 15 | | 13 | | 5 | 45 | 2 | 20 | 100 | Transparent | 1.49 | 52.2 | 158.7 | 99.5 |
| 147 | 7.5 | | | | 16 | 43 | 30 | 3.5 | 100 | Transparent | 1.506 | 53.4 | 158.9 | 114.5 |
| 148 | 3 | | | | 17 | 44 | 25.5 | 5.5 | 100 | Transparent | 1.505 | 53.3 | 158.9 | 112.8 |
| 149 | 3.3 | | | | 17.7 | 44.5 | 19.5 | 10.5 | 100 | Transparent | 1.501 | 53.1 | 158.9 | 110.1 |
| 150 | 11 | | 5.5 | | 16.5 | 46 | 12.5 | 8.5 | 100 | Transparent | 1.498 | 52.8 | 158.9 | 106.3 |
| 151 | 15 | | 20 | | 11.5 | 44.5 | 9 | 0 | 100 | Transparent | 1.493 | 52.7 | 159.5 | 100.5 |
| 152 | 10.5 | | | | 7.5 | 45.5 | 6.5 | 30 | 100 | Transparent | 1.493 | 52.5 | 159 | 104.8 |
| 153 | 6.5 | | | | 18.5 | 43 | 32 | 0 | 100 | Transparent | 1.507 | 53.7 | 159.6 | 115.4 |
| 154 | 6 | | | | 18 | 46 | 30 | 0 | 100 | Transparent | 1.506 | 53.9 | 160.3 | 114.6 |
| 155 | 5.5 | | | | 20.5 | 44 | 30 | 0 | 100 | Transparent | 1.506 | 54 | 160.8 | 114.6 |
| 156 | 5.5 | | | | 20 | 45 | 29.5 | 0 | 100 | Transparent | 1.506 | 54 | 160.8 | 114.4 |
| 157 | 7.8 | | | | 14.7 | 44.5 | 28 | 5 | 100 | Transparent | 1.505 | 53.3 | 158.8 | 113.7 |
| 158 | 7.5 | | | | 18 | 44 | 25.8 | 4.7 | 100 | Transparent | 1.505 | 53.4 | 159.3 | 113 |
| 159 | 8.3 | | | | 19.2 | 44.5 | 22 | 6 | 100 | Transparent | 1.503 | 53.2 | 158.9 | 111.6 |
| 160 | 15 | | 3 | | 16 | 46 | 20 | 0 | 100 | Transparent | 1.507 | 51.6 | 153.3 | 110.7 |
| 161 | 8.5 | | | | 17 | 44.5 | 19.7 | 10.3 | 100 | Transparent | 1.502 | 53.1 | 159.1 | 110.5 |
| 162 | 7.5 | | | | 26 | 45 | 16.5 | 5 | 100 | Transparent | 1.501 | 53.5 | 160.2 | 109.8 |
| 163 | 15.7 | | 5.1 | | 14.3 | 46 | 18.9 | 0 | 100 | Transparent | 1.506 | 51.5 | 153.4 | 109.6 |
| 164 | 2 | | | | 32 | 45 | 16.4 | 4.6 | 100 | Transparent | 1.498 | 55.1 | 165.9 | 109.3 |
| 165 | 10.2 | | 4.5 | | 16.3 | 45 | 17 | 7 | 100 | Transparent | 1.5 | 53 | 158.9 | 108.2 |
| 166 | 16.5 | | 6.5 | | 17 | 45 | 15 | 0 | 100 | Transparent | 1.504 | 51.4 | 153.3 | 107.8 |
| 167 | 3 | 5 | | | 30.6 | 45 | 16.4 | 0 | 100 | Transparent | 1.503 | 53.6 | 160.1 | 106.4 |
| 168 | 12 | | 11.5 | | 14 | 45 | 17.5 | 0 | 100 | Transparent | 1.499 | 53 | 159.1 | 106.3 |
| 169 | 12 | | 5.5 | | 16.5 | 46 | 12.5 | 8.5 | 100 | Transparent | 1.498 | 52.8 | 158.9 | 106.3 |

TABLE 7

| | | | | | | | | | | Polymer Properties | | | | |
|---|---|---|---|---|---|---|---|---|---|---|---|---|---|---|
| Sample | Composition (Part(s) by Mass) | | | | | | | | | | Refractive | Abbe | K = n_{D} − | Tg |
| No. | PhMA | BzMA | 4FM | 8FM | MMA | PMMA | TCDMA | TBMA | TOTAL | Transparency | Index | Number | V/(n_{D} − 1) | (° C.) |
| 170 | 9.7 | | | 3.8 | 16.5 | 45 | 18 | 7 | 100 | Transparent | 1.5 | 53 | 158.9 | 106.2 |
| 171 | 11 | | 11.3 | | 17 | 46 | 14.7 | 0 | 100 | Transparent | 1.498 | 53.3 | 160.3 | 105.4 |
| 172 | 12.7 | | 16 | | 9.8 | 42 | 19.5 | 0 | 100 | Transparent | 1.498 | 53.1 | 159.6 | 105.3 |
| 173 | 5 | | | 5 | 28.6 | 45 | 16.4 | 0 | 100 | Transparent | 1.498 | 54.5 | 164 | 104.6 |
| 174 | 10 | | | | 39 | 48 | | 3 | 100 | Transparent | 1.498 | 52.9 | 159 | 104.6 |
| 175 | 18.5 | | 11 | | 14 | 47.5 | 9 | 0 | 100 | Transparent | 1.501 | 51.1 | 153.2 | 104.2 |
| 176 | 10 | | | | 32 | 48 | | 10 | 100 | Transparent | 1.496 | 52.8 | 159.3 | 104.1 |
| 177 | 12.5 | | 9.5 | | 15 | 45 | 10 | 8 | 100 | Transparent | 1.496 | 52.7 | 158.9 | 104 |
| 178 | 5 | | | | 39 | 48 | 0 | 8 | 100 | Transparent | 1.493 | 54.3 | 164.5 | 103.8 |
| 179 | 10.4 | | | 4.8 | 17 | 45.5 | 13.8 | 8.5 | 100 | Transparent | 1.498 | 52.8 | 158.9 | 103.8 |
| 180 | 0 | 5 | | 5 | 28.6 | 45 | 16.4 | 0 | 100 | Transparent | 1.498 | 54.7 | 164.7 | 101 |
| 181 | 20.5 | | 16.5 | | 13 | 46 | 4 | 0 | 100 | Transparent | 1.497 | 50.9 | 153.3 | 100.6 |
| 182 | 15 | | 20 | | 12 | 44 | 9 | 0 | 100 | Transparent | 1.493 | 52.7 | 159.5 | 100.5 |
| 183 | 12.5 | | | 15.3 | 16.2 | 45 | 11 | 0 | 100 | Transparent | 1.493 | 52.7 | 159.5 | 93 |
| 184 | 0 | 6.8 | | 10 | 35.2 | 48 | | 0 | 100 | Transparent | 1.489 | 54.6 | 166.2 | 89.8 |
| 185 | 13.1 | | | 29.2 | 12.9 | 44.8 | | 0 | 100 | Transparent | 1.479 | 53.2 | 164.2 | 76.7 |
| 186 | 0 | 13.1 | | 29.2 | 12.9 | 44.8 | | 0 | 100 | Transparent | 1.479 | 53.8 | 166.2 | 68.7 |
| 187 | 16.9 | | | 40.4 | 2.4 | 40.3 | | 0 | 100 | Transparent | 1.472 | 52.4 | 163.4 | 67.2 |
| 188 | 0 | 5 | | 6 | 29 | 45 | 15 | 0 | 100 | Transparent | 1.497 | 54.7 | 164.8 | 99.5 |
| 189 | 0 | 6 | | 8 | 37 | 49 | | 0 | 100 | Transparent | 1.49 | 54.8 | 166.6 | 92.2 |
| 190 | 0 | 10 | | 20 | 23 | 47 | | 0 | 100 | Transparent | 1.484 | 54.2 | 166.2 | 88.6 |
| 191 | 0 | 17 | | 41 | 3 | 39 | | 0 | 100 | Transparent | 1.472 | 53.2 | 165.9 | 67 |
| 192 | 4 | | 20 | | 10 | 43 | 12 | 11 | 100 | Transparent | 1.484 | 56.1 | 171.9 | 105.8 |
| 193 | 5 | | 25 | | 7 | 43 | 10 | 10 | 100 | Transparent | 1.481 | 56.2 | 173 | 102.5 |
| 194 | 6 | | 30 | | 17 | 42 | 5 | 0 | 100 | Transparent | 1.479 | 56.5 | 174.3 | 94.8 |
| 195 | 7 | | 35 | | 11 | 44 | 3 | 0 | 100 | Transparent | 1.476 | 56.6 | 175.5 | 92.4 |
| 196 | 10 | | 45 | | 5 | 40 | | 0 | 100 | Transparent | 1.47 | 56.5 | 176.5 | 88.1 |
| 197 | 50 | | | | | 40 | 10 | 0 | 100 | Transparent | 1.529 | 43.6 | 126.1 | 111.3 |
| 198 | 30 | | | | 10 | 40 | 20 | 0 | 100 | Transparent | 1.519 | 47.7 | 139.8 | 113.1 |
| 199 | 40 | | | | | 40 | 10 | 10 | 100 | Transparent | 1.519 | 45.6 | 133.5 | 109.8 |
| 200 | 20 | | | | 10 | 40 | 20 | 10 | 100 | Transparent | 1.509 | 50.1 | 148.5 | 111.6 |
| 201 | 30 | | | | | 40 | 10 | 20 | 100 | Transparent | 1.51 | 47.8 | 141.5 | 108.3 |
| 202 | 20 | | | | 5 | 35 | 10 | 30 | 100 | Cloudy | 1.501 | 50.1 | 150.1 | 106.7 |
| 203 | 15 | | | | | 25 | 20 | 40 | 100 | Cloudy | 1.498 | 51.3 | 154.2 | 109 |
| 204 | 55 | | | | | 25 | 10 | 10 | 100 | Cloudy | 1.529 | 42.8 | 123.7 | 111 |
| 205 | 0 | | | | 15 | 45 | 20 | 20 | 100 | Cloudy | 1.494 | 55.6 | 168.1 | 109.2 |
| 206 | 35 | | | | | 25 | 10 | 30 | 100 | Cloudy | 1.51 | 46.7 | 138.3 | 107.9 |
| 207 | 10 | | | | | 30 | 20 | 40 | 100 | Cloudy | 1.495 | 52.6 | 158.8 | 108.6 |

### Example 1

45 parts by mass of polymethyl methacrylate (PMMA), 20 parts by mass of methyl methacrylate (MMA), 35 parts by mass of phenyl methacrylate (PhMA), 0.25 parts by mass of 1-hydroxycyclohexyl phenyl ketone (HCPK), and 0.1 parts by mass of hydroquinone (HQ) were heated and kneaded at 70° C. to obtain a first layer-forming solution (uncured material). This composition is the same as that of sample No. 5.

45 parts by mass of PMMA, 40 parts by mass of MMA, 15 parts by mass of PhMA, 0.25 parts by mass of HCPK, and 0.1 parts by mass of HQ were heated and kneaded at 70° C. to obtain a second layer-forming solution (uncured material). This composition is the same as that of sample No. 26.

45 parts by mass of PMMA, 40 parts by mass of MMA, 7.5 parts by mass of PhMA, 7.5 parts by mass of 2,2,3,3-tetrafluoropropyl methacrylate (4FM), 0.25 parts by mass of HCPK, and 0.1 parts by mass of HQ were heated and kneaded at 70° C. to obtain a third layer-forming solution (uncured material). This composition is the same as that of sample No. 27.

50 parts by mass of PMMA, 10 parts by mass of MMA, 10 parts by mass of PhMA, 20 parts by mass of t-butyl methacrylate (TBMA), 10 parts by mass of 4FM, 0.25 parts by mass of HCPK, and 0.1 parts by mass of HQ were heated and kneaded at 70° C. to obtain a fourth layer-forming solution (uncured material). This composition is the same as that of sample No. 77.

25 parts by mass of PMMA, 17.5 parts by mass of PhMA, 40 parts by mass of TBMA, 17.5 parts by mass of 4FM, 0.25 parts by mass of HCPK, and 0.1 parts by mass of HQ were heated and kneaded at 70° C. to obtain a fifth layer-forming solution (uncured material). This composition is the same as that of sample No. 99.

HCPK is a photocuring agent, and HQ is a polymerization inhibitor.

The composition of the forming solution of each layer is shown in Table 8.

In order to suppress crosstalk light or flare light, to the fourth layer-forming solution and the fifth layer-forming solution before heating and kneading, 0.57 parts by mass of dye Blue ACR (manufactured by Nippon Kayaku Co., Ltd.), 0.14 parts by mass of dye MS yellow HD-180 (manufactured by Mitsui Toatsu Dye Ltd.), 0.14 parts by mass of MS Magenta HM-1450 (manufactured by Mitsui Toatsu Dye Ltd.), 0.02 parts by mass of dye Diaresin blue 4G (manufactured by Mitsubishi Chemical Corporation), and 0.02 parts by mass of Kayasorb CY-10 (manufactured by Nippon Kayaku Co., Ltd.) with respect to 100 parts by mass of the forming solutions were added.

Such 5 kinds of forming solutions were arranged such that the refractive index after curing is sequentially reduced from the center to the outer periphery and were simultaneously extruded from a concentric 5-layer multi-component spinning nozzle to obtain a filament. The temperature of the multi-component spinning nozzle was 50° C.

The discharge ratio of each layer was first layer/second layer/third layer/fourth layer/fifth layer=24.0/31.1/40.2/2.2/2.5 in terms of the ratio of the thickness (radius in the first layer) of each layer in a radial direction of the rod lens

In this case, the first layer was the innermost layer, and the fifth layer was the outermost layer.

Next, a rod lens base fiber was manufactured from the obtained forming solutions using the device 10 of manufacturing a plastic rod lens base fiber illustrated in FIG. 2.

Specifically, nitrogen gas was introduced from the inert gas introducing pipe 13 into the receiving body 12, and the inert gas in the receiving body 12 was discharged from the inert gas discharge pipe 14.

In addition, a filament A extruded from the concentric multi-component spinning nozzle 11 was pulled (390 cm/min) by the pull roller (nip roller) 17 and was caused to pass through the interdiffusion portion 12b having a length of 30 cm, thereby causing interdiffusion to occur between the respective layers.

Next, the filament A was caused to pass through the center of the first curing portion (light irradiation unit) 12c in which eighteen 40 W chemical lamps having a length of 120 cm were disposed around a central axis at regular intervals, to cure the filament A while interdiffusion was caused to occur between the respective layers. Next, the filament A was caused to pass through the center of the second curing portion (light irradiation unit) 12d in which three 2 KW high-pressure mercury lamps were disposed around a central axis at regular intervals, to further cure the filament A. The flow rate of nitrogen in the interdiffusion portion 12b was 72 L/min.

The radius of the rod lens base fiber obtained as above was 0.215 mm.

Next, the obtained rod lens base fiber was cut into a length of 166 mm to obtain a rod lens.

In the rod lens obtained as above, the radius r was 0.215 mm and Tg was 110° C. In addition, the central refractive index n₀ of the rod lens was 1.513 at a wavelength of 525 nm, the refractive index distribution approximates the expression (6) in a range of 0.2r to 0.8r from the center to the outer periphery, the refractive index distribution constant g at a wavelength of 525 nm was 0.85 mm⁻¹, and the difference in refractive index between the center and the outer periphery of the lens was 0.025. The rod lens was transparent, and a dye layer was formed in the outer periphery of the rod lens.

Using many of the obtained rod lenses, a rod lens array having two rod lens lines (lens length: 4.5 mm) at an alignment pitch of 0.445 mm (a gap of 15 μm between adjacent lenses) was prepared.

In the prepared rod lens array, when the light intensity and the average MTF before and after the heat resistance test were measured at a wavelength of 525 nm, the light intensity was high, there was almost no deterioration in the resolution after the heat resistance test, and the heat resistance was extremely excellent. The results thereof are shown in Table 10.

In addition, an LED printer head was prepared using the prepared rod lens array. When printing was performed by the LED printer head, a clear image was obtained and there was no change in the printed image even after the heat resistance test.

### Example 2

45 parts by mass of PMMA, 10 parts by mass of MMA, 45 parts by mass of PhMA, 0.25 parts by mass of HCPK, and 0.1 parts by mass of HQ were heated and kneaded at 70° C. to obtain a first layer-forming solution (uncured material). This composition is the same as that of sample No. 2.

45 parts by mass of PMMA, 30 parts by mass of MMA, 25 parts by mass of PhMA, 0.25 parts by mass of HCPK, and 0.1 parts by mass of HQ were heated and kneaded at 70° C. to obtain a second layer-forming solution (uncured material). This composition is the same as that of sample No. 23.

45 parts by mass of PMMA, 40 parts by mass of MMA, 7.5 parts by mass of PhMA, 7.5 parts by mass of 4FM, 0.25 parts by mass of HCPK, and 0.1 parts by mass of HQ were heated and kneaded at 70° C. to obtain a third layer-forming solution (uncured material). This composition is the same as that of sample No. 27.

45 parts by mass of PMMA, 25 parts by mass of MMA, 10 parts by mass of PhMA, 5 parts by mass of TBMA, 15 parts by mass of 4FM, 0.25 parts by mass of HCPK, and 0.1 parts by mass of HQ were heated and kneaded at 70° C. to obtain a fourth layer-forming solution (uncured material). This composition is the same as that of sample No. 57.

40 parts by mass of PMMA, 10 parts by mass of PhMA, 20 parts by mass of TBMA, 30 parts by mass of 4FM, 0.25 parts by mass of HCPK, and 0.1 parts by mass of HQ were heated and kneaded at 70° C. to obtain a fifth layer-forming solution (uncured material). This composition is the same as that of sample No. 83.

The composition of the forming solution of each layer is shown in Table 8.

The same kinds and amounts of dyes as those of Example 1 were added to the fourth layer-forming solution and the fifth layer-forming solution.

A rod lens base fiber was manufactured with the same method as that of Example 1, except that the forming solution of each layer prepared with the above-described composition was used; and the pulling speed was changed to 288 cm/min. This rod lens base fiber was cut into a length of 166 mm to obtain a rod lens having a radius of 0.250 mm.

In the rod lens obtained as above, the radius r was 0.250 mm and Tg was 108° C. In addition, the central refractive index n₀ of the rod lens was 1.520 at a wavelength of 525 nm, the refractive index distribution approximates the expression (6) in a range of 0.2r to 0.8r from the center to the outer periphery, the refractive index distribution constant g at a wavelength of 525 nm was 0.91 mm⁻¹, and the difference in refractive index between the center and the outer periphery of the lens was 0.039. The rod lens was transparent, and a dye layer was formed in the outer periphery of the rod lens.

Using many of the obtained rod lenses, a rod lens array having two rod lens lines (lens length: 4.3 mm) at an alignment pitch of 0.515 mm (a gap of 15 μm between adjacent lenses) was prepared.

In the prepared rod lens array, when the light intensity and the average MTF before and after the heat resistance test were measured at a wavelength of 525 nm, the light intensity was extremely high, there was an extremely small deterioration in the resolution after the heat resistance test, and the heat resistance was extremely excellent. The results thereof are shown in Table 10.

In addition, an LED printer head was prepared using the prepared rod lens array.

When printing was performed by the LED printer head, a clear image was obtained and there was no change in the printed image even after the heat resistance test.

### Example 3

45 parts by mass of PMMA, 60 parts by mass of PhMA, 0.25 parts by mass of HCPK, and 0.1 parts by mass of HQ were heated and kneaded at 70° C. to obtain a first layer-forming solution (uncured material). This composition is the same as that of sample No. 11.

45 parts by mass of PMMA, 20 parts by mass of MMA, 35 parts by mass of PhMA, 0.25 parts by mass of HCPK, and 0.1 parts by mass of HQ were heated and kneaded at 70° C. to obtain a second layer-forming solution (uncured material). This composition is the same as that of sample No. 5.

45 parts by mass of PMMA, 40 parts by mass of MMA, 7.5 parts by mass of PhMA, 7.5 parts by mass of 4FM, 0.25 parts by mass of HCPK, and 0.1 parts by mass of HQ were heated and kneaded at 70° C. to obtain a third layer-forming solution (uncured material). This composition is the same as that of sample No. 27.

45 parts by mass of PMMA, 40 parts by mass of MMA, 15 parts by mass of 4FM, 0.25 parts by mass of HCPK, and 0.1 parts by mass of HQ were heated and kneaded at 70° C. to obtain a fourth layer-forming solution (uncured material). This composition is the same as that of sample No. 25.

45 parts by mass of PMMA, 20 parts by mass of MMA, 35 parts by mass of 4FM, 0.25 parts by mass of HCPK, and 0.1 parts by mass of HQ were heated and kneaded at 70° C. to obtain a fifth layer-forming solution (uncured material). This composition is the same as that of sample No. 4.

The composition of the forming solution of each layer is shown in Table 8.

The same kinds and amounts of dyes as those of Example 1 were added to the fourth layer-forming solution and the fifth layer-forming solution.

A rod lens base fiber was manufactured with the same method as that of Example 1, except that the forming solution of each layer prepared with the above-described composition was used; and the pulling speed was changed to 200 cm/min. This rod lens base fiber was cut into a length of 166 mm to obtain a rod lens having a radius of 0.30 mm.

In the rod lens obtained as above, the radius r was 0.30 mm and Tg was 105° C. In addition, the central refractive index n₀ of the rod lens was 1.527 at a wavelength of 525 nm, the refractive index distribution approximates the expression (6) in a range of 0.2r to 0.8r from the center to the outer periphery, the refractive index distribution constant g at a wavelength of 525 nm was 0.88 mm⁻¹, and the difference in refractive index between the center and the outer periphery of the lens was 0.053. The rod lens was transparent, and a dye layer was formed in the outer periphery of the rod lens.

Using many of the obtained rod lenses, a rod lens array having two rod lens lines (lens length: 4.4 mm) at an alignment pitch of 0.615 mm (a gap of 15 μm between adjacent lenses) was prepared.

In the prepared rod lens array, when the light intensity and the average MTF before and after the heat resistance test were measured at a wavelength of 525 nm, the light intensity was extremely high, there was a small deterioration in the resolution after the heat resistance test, and the heat resistance was excellent. The results thereof are shown in Table 10.

In addition, an LED printer head was prepared using the prepared rod lens array. When printing was performed by the LED printer head, a clear image was obtained and there was no significant change in the printed image even after the heat resistance test.

### Example 4

40 parts by mass of PMMA, 60 parts by mass of PhMA, 0.25 parts by mass of HCPK, and 0.1 parts by mass of HQ were heated and kneaded at 70° C. to obtain a first layer-forming solution (uncured material). This composition is the same as that of sample No. 11.

45 parts by mass of PMMA, 20 parts by mass of MMA, 35 parts by mass of PhMA, 0.25 parts by mass of HCPK, and 0.1 parts by mass of HQ were heated and kneaded at 70° C. to obtain a second layer-forming solution (uncured material). This composition is the same as that of sample No. 5.

45 parts by mass of PMMA, 50 parts by mass of MMA, 5 parts by mass of 4FM, 0.25 parts by mass of HCPK, and 0.1 parts by mass of HQ were heated and kneaded at 70° C. to obtain a third layer-forming solution (uncured material). This composition is the same as that of sample No. 28.

45 parts by mass of PMMA, 40 parts by mass of MMA, 15 parts by mass of 4FM, 0.25 parts by mass of HCPK, and 0.1 parts by mass of HQ were heated and kneaded at 70° C. to obtain a fourth layer-forming solution (uncured material). This composition is the same as that of sample No. 25.

45 parts by mass of PMMA, 20 parts by mass of MMA, 35 parts by mass of 4FM, 0.25 parts by mass of HCPK, and 0.1 parts by mass of HQ were heated and kneaded at 70° C. to obtain a fifth layer-forming solution (uncured material). This composition is the same as that of sample No. 4.

The composition of the forming solution of each layer is shown in Table 8.

The same kinds and amounts of dyes as those of Example 1 were added to the fourth layer-forming solution and the fifth layer-forming solution.

A rod lens base fiber was manufactured with the same method as that of Example 3, except that the forming solution of each layer prepared with the above-described composition was used. This rod lens base fiber was cut into a length of 166 mm to obtain a rod lens having a radius of 0.30 mm.

In the rod lens obtained as above, the radius r was 0.30 mm and Tg was 106° C. In addition, the central refractive index n₀ of the rod lens was 1.527 at a wavelength of 525 nm, the refractive index distribution approximates the expression (6) in a range of 0.2r to 0.8r from the center to the outer periphery, the refractive index distribution constant g at a wavelength of 525 nm was 0.88 mm⁻¹, and the difference in refractive index between the center and the outer periphery of the lens was 0.054. The rod lens was transparent, and a dye layer was formed in the outer periphery of the rod lens.

Using many of the obtained rod lenses, a rod lens array having two rod lens lines (lens length: 4.4 mm) at an alignment pitch of 0.615 mm (a gap of 15 μm between adjacent lenses) was prepared.

In the prepared rod lens array, when the light intensity and the average MTF before and after the heat resistance test were measured at a wavelength of 525 nm, the light intensity was extremely high, there was an small deterioration in the resolution after the heat resistance test, and the heat resistance was excellent. The results thereof are shown in Table 10. In addition, an LED printer head was prepared using the prepared rod lens array. When printing was performed by the LED printer head, a clear image was obtained and there was no significant change in the printed image even after the heat resistance test.

### Example 5

45 parts by mass of PMMA, 20 parts by mass of MMA, 35 parts by mass of PhMA, 0.25 parts by mass of HCPK, and 0.1 parts by mass of HQ were heated and kneaded at 70° C. to obtain a first layer-forming solution (uncured material). This composition is the same as that of sample No. 5.

45 parts by mass of PMMA, 30 parts by mass of MMA, 25 parts by mass of PhMA, 0.25 parts by mass of HCPK, and 0.1 parts by mass of HQ were heated and kneaded at 70° C. to obtain a second layer-forming solution (uncured material). This composition is the same as that of sample No. 23.

45 parts by mass of PMMA, 40 parts by mass of MMA, 15 parts by mass of PhMA, 0.25 parts by mass of HCPK, and 0.1 parts by mass of HQ were heated and kneaded at 70° C. to obtain a third layer-forming solution (uncured material). This composition is the same as that of sample No. 26.

50 parts by mass of PMMA, 10 parts by mass of MMA, 20 parts by mass of PhMA, 20 parts by mass of TBMA, 0.25 parts by mass of HCPK, and 0.1 parts by mass of HQ were heated and kneaded at 70° C. to obtain a fourth layer-forming solution (uncured material). This composition is the same as that of sample No. 76.

45 parts by mass of PMMA, 15 parts by mass of PhMA, 40 parts by mass of TBMA, 0.25 parts by mass of HCPK, and 0.1 parts by mass of HQ were heated and kneaded at 70° C. to obtain a fifth layer-forming solution (uncured material). This composition is the same as that of sample No. 98.

The composition of the forming solution of each layer is shown in Table 8.

The same kinds and amounts of dyes as those of Example 1 were added to the fourth layer-forming solution and the fifth layer-forming solution.

A rod lens base fiber was manufactured with the same method as that of Example 1, except that the forming solution of each layer prepared with the above-described composition was used; and the pulling speed was changed to 165 cm/min. This rod lens base fiber was cut into a length of 166 mm to obtain a rod lens having a radius of 0.330 mm.

In the rod lens obtained as above, the radius r was 0.330 mm and Tg was 114° C. In addition, the central refractive index n₀ of the rod lens was 1.513 at a wavelength of 525 nm, the refractive index distribution approximates the expression (6) in a range of 0.2r to 0.8r from the center to the outer periphery, the refractive index distribution constant g at a wavelength of 525 nm was 0.44 mm⁻¹, and the difference in refractive index between the center and the outer periphery of the lens was 0.016. The rod lens was transparent, and a dye layer was formed in the outer periphery of the rod lens.

Using many of the obtained rod lenses, a rod lens array having two rod lens lines (lens length: 8.5 mm) at an alignment pitch of 0.675 mm (a gap of 15 μm between adjacent lenses) was prepared.

In the prepared rod lens array, when the light intensity and the average MTF before and after the heat resistance test were measured at a wavelength of 525 nm, the light intensity was approximately the same as that of SLA12D, there was almost no deterioration in the resolution after the heat resistance test, and the heat resistance was extremely excellent. The results thereof are shown in Table 10.

In addition, an LED printer head was prepared using the prepared rod lens array. When printing was performed by the LED printer head, there was a noise due to the low light intensity; however, there was no change in the printed image before and after the heat resistance test.

### Comparative Example 1

45 parts by mass of PMMA, 10 parts by mass of MMA, 45 parts by mass of PhMA, 0.25 parts by mass of HCPK, and 0.1 parts by mass of HQ were heated and kneaded at 70° C. to obtain a first layer-forming solution (uncured material). This composition is the same as that of sample No. 2.

45 parts by mass of PMMA, 30 parts by mass of MMA, 25 parts by mass of PhMA, 0.25 parts by mass of HCPK, and 0.1 parts by mass of HQ were heated and kneaded at 70° C. to obtain a second layer-forming solution (uncured material). This composition is the same as that of sample No. 23.

45 parts by mass of PMMA, 20 parts by mass of MMA, 17.5 parts by mass of PhMA, 17.5 parts by mass of 4FM, 0.25 parts by mass of HCPK, and 0.1 parts by mass of HQ were heated and kneaded at 70° C. to obtain a third layer-forming solution (uncured material). This composition is the same as that of sample No. 6.

20 parts by mass of PMMA, 30 parts by mass of PhMA, 5 parts by mass of TBMA, 45 parts by mass of 4FM, 0.25 parts by mass of HCPK, and 0.1 parts by mass of HQ were heated and kneaded at 70° C. to obtain a fourth layer-forming solution (uncured material). This composition is the same as that of sample No. 47.

30 parts by mass of PMMA, 10 parts by mass of PhMA, 20 parts by mass of TBMA, 40 parts by mass of 4FM, 0.25 parts by mass of HCPK, and 0.1 parts by mass of HQ were heated and kneaded at 70° C. to obtain a fifth layer-forming solution (uncured material). This composition is the same as that of sample No. 84.

The composition of the forming solution of each layer is shown in Table 9.

The same kinds and amounts of dyes as those of Example 1 were added to the fourth layer-forming solution and the fifth layer-forming solution.

A rod lens base fiber was manufactured with the same method as that of Example I, except that the forming solution of each layer prepared with the above-described composition was used; and the pulling speed was changed to 200 cm/min. This rod lens base fiber was cut into a length of 166 mm to obtain a rod lens having a radius of 0.300 mm.

In the rod lens obtained as above, the radius r was 0.300 mm and Tg was 99.0° C. In addition, the central refractive index n₀ of the rod lens was 1.518 at a wavelength of 525 nm, the refractive index distribution approximates the expression (6) in a range of 0.2r to 0.8r from the center to the outer periphery, the refractive index distribution constant g at a wavelength of 525 nm was 0.79 mm⁻¹, and the difference in refractive index between the center and the outer periphery of the lens was 0.043. The rod lens was transparent, and a dye layer was formed in the outer periphery of the rod lens.

Using many of the obtained rod lenses, a rod lens array having two rod lens lines (lens length: 4.7 mm) at an alignment pitch of 0.615 mm (a gap of 15 μm between adjacent lenses) was prepared.

In the prepared rod lens array, when the light intensity and the average MTF before and after the heat resistance test were measured at a wavelength of 525 nm, the light intensity was extremely high; however, there was an extremely large deterioration in the resolution after the heat resistance test, and the heat resistance was poor. The results thereof are shown in Table 10.

In addition, an LED printer head was prepared using the prepared rod lens array. When printing was performed by the LED printer head, a clear image was obtained; however, the printed image after the heat resistance test was unclear.

### Comparative Example 2

35 parts by mass of PMMA, 65 parts by mass of PhMA, 0.25 parts by mass of HCPK, and 0.1 parts by mass of HQ were heated and kneaded at 70° C. to obtain a first layer-forming solution (uncured material). This composition is the same as that of sample No. 31.

45 parts by mass of PMMA, 10 parts by mass of MMA, 45 parts by mass of PhMA, 0.25 parts by mass of HCPK, and 0.1 parts by mass of HQ were heated and kneaded at 70° C. to obtain a second layer-forming solution (uncured material). This composition is the same as that of sample No. 2.

45 parts by mass of PMMA, 5 parts by mass of MMA, 30 parts by mass of PhMA, 20 parts by mass of TBMA, 0.25 parts by mass of HCPK, and 0.1 parts by mass of HQ were heated and kneaded at 70° C. to obtain a third layer-forming solution (uncured material). This composition is the same as that of sample No. 71.

35 parts by mass of PMMA, 25 parts by mass of PhMA, 40 parts by mass of TBMA, 0.25 parts by mass of HCPK, and 0.1 parts by mass of HQ were heated and kneaded at 70° C. to obtain a fourth layer-forming solution (uncured material). This composition is the same as that of sample No. 105.

30 parts by mass of PMMA, 10 parts by mass of MMA, 10 parts by mass of PhMA, 50 parts by mass of TBMA, 0.25 parts by mass of HCPK, and 0.1 parts by mass of HQ were heated and kneaded at 70° C. to obtain a fifth layer-forming solution (uncured material). This composition is the same as that of sample No. 127.

The composition of the forming solution of each layer is shown in Table 9.

The same kinds and amounts of dyes as those of Example 1 were added to the fourth layer-forming solution and the fifth layer-forming solution.

A rod lens base fiber was manufactured with the same method as that of Example 1, except that the forming solution of each layer prepared with the above-described composition was used; and the pulling speed was changed to 200 cm/min. This rod lens base fiber was cut into a length of 166 mm to obtain a rod lens having a radius of 0.300 mm.

In the rod lens obtained as above, the radius r was 0.300 mm and Tg was 114° C. In addition, the central refractive index n₀ of the rod lens was 1.530 at a wavelength of 525 nm, the refractive index distribution approximates the expression (6) in a range of 0.2r to 0.8r from the center to the outer periphery, the refractive index distribution constant g at a wavelength of 525 nm was 0.77 mm⁻¹, and the difference in refractive index between the center and the outer periphery of the lens was 0.041. The rod lens was cloudy, and a dye layer was formed in the outer periphery of the rod lens.

Using many of the obtained rod lenses, a rod lens array having two rod lens lines (lens length: 5.0 mm) at an alignment pitch of 0.615 mm (a gap of 15 μm between adjacent lenses) was prepared.

In the prepared rod lens array, when the light intensity and the average MTF before and after the heat resistance test were measured at a wavelength of 525 nm, the light intensity was extremely low due to the cloudy lens. In addition, the resolution was extremely low due to the effect of diffused light. There was a small deterioration in the resolution before and after the heat resistance test. The results thereof are shown in Table 10.

In addition, an LED printer head was prepared using the prepared rod lens array. When printing was performed by the LED printer head, the light intensity was extremely insufficient due to the cloudiness. In addition, since the resolution was extremely low even before the heat resistance, lens functions could not be exhibited.

TABLE 8

| | | | | Composition Ratio (Mass %) of Polymer Mixture | | | | | | |
|---|---|---|---|---|---|---|---|---|---|---|
| | | | | Polymer | Monomer | Monomer | | Monomer | Monomer | |
| | | | Sample | (M) | (m) | (a) | | (b) | (c) | |
| | | Polymer | No. | PMMA | MMA | PhMA | BzMA | TBMA | 8FM | 4FM |
| Example 1 | First Layer | A-1 | 5 | 45 | 20 | 35 | | | | |
| | Second Layer | A-2 | 26 | 45 | 40 | 15 | | | | |
| | Third Layer | P-1 | 27 | 45 | 40 | 7.5 | | | | 7.5 |
| | Fourth Layer | P-2 | 77 | 50 | 10 | 10 | | 20 | | 10 |
| | Fifth Layer | P-3 | 99 | 25 | | 17.5 | | 40 | | 17.5 |
| Example 2 | First Layer | A-3 | 2 | 45 | 10 | 45 | | | | |
| | Second Layer | A-4 | 23 | 45 | 30 | 25 | | | | |
| | Third Layer | P-1 | 27 | 45 | 40 | 7.5 | | | | 7.5 |
| | Fourth Layer | P-4 | 57 | 45 | 25 | 10 | | 5 | | 15 |
| | Fifth Layer | P-5 | 83 | 40 | | 10 | | 20 | | 30 |
| Example 3 | First Layer | A-5 | 11 | 40 | | 60 | | | | |
| | Second Layer | A-1 | 5 | 45 | 20 | 35 | | | | |
| | Third Layer | P-1 | 27 | 45 | 40 | 7.5 | | | | 7.5 |
| | Fourth Layer | C-1 | 25 | 45 | 40 | | | | | 15 |
| | Fifth Layer | C-2 | 4 | 45 | 20 | | | | | 35 |
| Example 4 | First Layer | A-5 | 11 | 40 | | 60 | | | | |
| | Second Layer | A-1 | 5 | 45 | 20 | 35 | | | | |
| | Third Layer | C-3 | 28 | 45 | 50 | | | | | 5 |
| | Fourth Layer | C-1 | 25 | 45 | 40 | | | | | 15 |
| | Fifth Layer | C-2 | 4 | 45 | 20 | | | | | 35 |
| Example 5 | First Layer | A-1 | 5 | 45 | 20 | 35 | | | | |
| | Second Layer | A-4 | 25 | 45 | 30 | 25 | | | | |
| | Third Layer | A-2 | 26 | 45 | 40 | 15 | | | | |
| | Fourth Layer | P-6 | 76 | 50 | 10 | 20 | | 20 | | |
| | Fifth Layer | P-7 | 98 | 45 | | 15 | | 40 | | |

| | | Expression (2) | | | | Expression (3) | Expression (1) |
|---|---|---|---|---|---|---|---|
| | | 0.357[b]-1.786 < [a] < 65-1.063[b] | | | [c] < 21.786-0.357[b] < 47.143-0.429[b] | | |
| | | 0.357[b]-1.786 | [a] | 65-1.063[b] | [c] | 21.786-0.357[b] | 47.143-0.429[b] |
| Example 1 | First Layer | −2 | 35 | 65 | | 22 | 47.143 |
| | Second Layer | −2 | 15 | 65 | | 22 | 47.143 |
| | Third Layer | −2 | 7.5 | 65 | 7.5 | 22 | 47.143 |
| | Fourth Layer | 5 | 10 | 44 | 10 | 15 | 38.563 |
| | Fifth Layer | 12 | 17.5 | 22 | 17.5 | 8 | 29.983 |
| Example 2 | First Layer | −2 | 45 | 65 | | 22 | 47.143 |
| | Second Layer | −2 | 25 | 65 | | 22 | 47.143 |
| | Third Layer | −2 | 7.5 | 65 | 7.5 | 22 | 47.143 |
| | Fourth Layer | 0 | 10 | 60 | 15 | 20 | 44.998 |
| | Fifth Layer | 5 | 10 | 44 | 30 | 15 | 38.563 |
| Example 3 | First Layer | −2 | 60 | 65 | | 22 | 47.143 |
| | Second Layer | −2 | 35 | 65 | | 22 | 47.143 |
| | Third Layer | −2 | 7.5 | 65 | 7.5 | 22 | 47.143 |
| | Fourth Layer | −2 | 0 | 65 | 15 | 22 | 47.143 |
| | Fifth Layer | −2 | 0 | 65 | 35 | 22 | 47.143 |
| Example 4 | First Layer | −2 | 60 | 65 | | 22 | 47.143 |
| | Second Layer | −2 | 35 | 65 | | 22 | 47.143 |
| | Third Layer | −2 | 0 | 65 | 5 | 22 | 47.143 |
| | Fourth Layer | −2 | 0 | 65 | 15 | 22 | 47.143 |
| | Fifth Layer | −2 | 0 | 65 | 35 | 22 | 47.143 |
| Example 5 | First Layer | −2 | 35 | 65 | 0 | 22 | 47.143 |
| | Second Layer | −2 | 25 | 65 | 0 | 22 | 47.143 |
| | Third Layer | −2 | 15 | 65 | 0 | 22 | 47.143 |
| | Fourth Layer | 5 | 20 | 44 | 0 | 15 | 38.563 |
| | Fifth Layer | 12 | 15 | 22 | 0 | 8 | 29.985 |

TABLE 9

| | | | | Composition Ratio (Mass %) of Polymer Mixture | | | | | | |
|---|---|---|---|---|---|---|---|---|---|---|
| | | | | Polymer | Monomer | | | Monomer | Monomer | |
| | | | Sample | (M) | (m) | Monomer (a) | | (b) | (c) | |
| | | Polymer | No. | PMMA | MMA | PhMA | BzMA | TBMA | 8FM | 4FM |
| Comparative | First Layer | A-3 | 2 | 45 | 10 | 45 | | | | |
| Example 1 | Second Layer | A-4 | 23 | 45 | 30 | 25 | | | | |
| | Third Layer | P-8 | 6 | 45 | 20 | 17.5 | | | | 17.5 |
| | Fourth Layer | P-9 | 47 | 20 | | 30 | | 5 | | 45 |
| | Fifth Layer | P-10 | 84 | 30 | | 10 | | 20 | | 40 |
| Comparative | First Layer | A-6 | 31 | 35 | | 65 | | | | |
| Example 2 | Second Layer | A-3 | 2 | 45 | 10 | 45 | | | | |
| | Third Layer | P-11 | 71 | 45 | 5 | 30 | | 20 | | |
| | Fourth Layer | P-12 | 105 | 35 | | 25 | | 40 | | |
| | Fifth Layer | P-13 | 127 | 30 | 10 | 10 | | 50 | | |

| | | Expression (2) | | | | Expression (3) | Expression (1) |
|---|---|---|---|---|---|---|---|
| | | 0.357[b]-1.786 < [a] < 65-1.063[b] | | | [c] < 21.786-0.357[b] < 47.143-0.429[b] | | |
| | | 0.357[b]-1.786 | [a] | 65-1.063[b] | [c] | 21.786-0.357[b] | 47.143-0.429[b] |
| Comparative | First Layer | −2 | 45 | 65 | 0 | 22 | 47.143 |
| Example 1 | Second Layer | −2 | 25 | 65 | 0 | 22 | 47.143 |
| | Third Layer | −2 | 17.5 | 65 | 17.5 | 22 | 47.143 |
| | Fourth Layer | 0 | 30 | 60 | 45 | 20 | 44.998 |
| | Fifth Layer | 5 | 10 | 44 | 40 | 15 | 38.563 |
| Comparative | First Layer | −2 | 65 | 65 | 0 | 22 | 47.143 |
| Example 2 | Second Layer | −2 | 45 | 65 | 0 | 22 | 47.143 |
| | Third Layer | 5 | 30 | 44 | 0 | 15 | 38.563 |
| | Fourth Layer | 12 | 25 | 22 | 0 | 8 | 29.983 |
| | Fifth Layer | 16 | 10 | 12 | 0 | 4 | 25.693 |

TABLE 10

| | | | | | Difference in | | | | Average | Average |
|---|---|---|---|---|---|---|---|---|---|---|
| | | | Refractive | | Refractive | | | | MTF | MTF |
| | | | Index | | Index between | | | Light | (%) before | (%) |
| | | | Distribution | Central | Center and | | | Intensity (%) | Heat | after Heat |
| | Radius r | Lens Length | Constant g | Refractive | Outer | Lens | Lens | with respect | Resistance | Resistance |
| | (mm) | (mm) | (mm⁻¹) | index | Periphery | Transparency | Tg (° C.) | to 8LA12D | Test | Test |
| Example 1 | 0.215 | 4.5 | 0.85 | 1.513 | 0.025 | Transparent | 110 | 172 | 83 | 81 |
| Example 2 | 0.25 | 4.3 | 0.91 | 1.52 | 0.039 | Transparent | 108 | 298 | 85 | 80 |
| Example 3 | 0.3 | 4.4 | 0.88 | 1.527 | 0.053 | Transparent | 105 | 394 | 86 | 75 |
| Example 4 | 0.3 | 4.4 | 0.88 | 1.527 | 0.054 | Transparent | 106 | 397 | 86 | 76 |
| Example 5 | 0.33 | 8.5 | 0.44 | 1.513 | 0.016 | Transparent | 114 | 102 | 75 | 73 |
| Comparative | 0.3 | 4.7 | 0.79 | 1.518 | 0.043 | Transparent | 99 | 269 | 84 | 56 |
| Example 1 | | | | | | | | | | |
| Comparative | 0.3 | 5 | 0.77 | 1.53 | 0.041 | Cloudy | 114 | 52 | 23 | 21 |
| Example 2 | | | | | | | | | | |

### Example 6

46 parts by mass of PMMA, 24 parts by mass of MMA, 30 parts by mass of TCDMA, 0.25 parts by mass of 1-hydroxycyclohexyl phenyl ketone (HCPK), and 0.1 parts by mass of hydroquinone (HQ) were heated and kneaded at 70° C. to obtain a first layer-forming solution (uncured material). This composition is the same as that of sample No. 132.

45 parts by mass of PMMA, 30.6 parts by mass of MMA, 3 parts by mass of PhMA, 16.4 parts by mass of TCDMA, 5 parts by mass of TBMA, 0.25 parts by mass of HCPK, and 0.1 parts by mass of HQ were heated and kneaded at 70° C. to obtain a second layer-forming solution (uncured material). This composition is the same as that of sample No. 133.

48 parts by mass of PMMA, 36.2 parts by mass of MMA, 5.8 parts by mass of PhMA, 10 parts by mass of TBMA, 0.25 parts by mass of HCPK, and 0.1 parts by mass of HQ were heated and kneaded at 70° C. to obtain a third layer-forming solution (uncured material). This composition is the same as that of sample No. 134.

44.8 parts by mass of PMMA, 13.9 parts by mass of MMA, 12.1 parts by mass of PhMA, 14.2 parts by mass of TBMA, 15 parts by mass of 8FM, 0.25 parts by mass of HCPK, and 0.1 parts by mass of HQ were heated and kneaded at 70° C. to obtain a fourth layer-forming solution (uncured material). This composition is the same as that of sample No. 135.

40.3 parts by mass of PMMA, 3.4 parts by mass of MMA, 15.9 parts by mass of PhMA, 10.4 parts by mass of TBMA, 30 parts by mass of 8FM, 0.25 parts by mass of HCPK, and 0.1 parts by mass of HQ were heated and kneaded at 70° C. to obtain a fifth layer-forming solution (uncured material). This composition is the same as that of sample No. 136.

The composition of the forming solution of each layer is shown in Table 11.

The same kinds and amounts of dyes as those of Example 1 were added to the fourth layer-forming solution and the fifth layer-forming solution.

Such 5 kinds of forming solutions were arranged such that the refractive index after curing is sequentially reduced from the center to the outer periphery and were simultaneously extruded from a concentric 5-layer multi-component spinning nozzle to obtain a filament. The temperature of the multi-component spinning nozzle was 50° C.

The discharge ratio of each layer was first layer/second layer/third layer/fourth layer/fifth layer=24.0/31.1/32.2/10.2/2.5 in terms of the ratio of the thickness (radius in the first layer) of each layer in a radial direction of the rod lens

In this case, the first layer was the innermost layer, and the fifth layer was the outermost layer.

Next, a rod lens base fiber was manufactured from the obtained forming solutions using the device 10 of manufacturing a plastic rod lens base fiber illustrated in FIG. 2.

Specifically, nitrogen gas was introduced from the inert gas introducing pipe 13 into the receiving body 12, and the inert gas in the receiving body 12 was discharged from the inert gas discharge pipe 14.

In addition, a filament A extruded from the concentric multi-component spinning nozzle 11 was pulled (200 cm/min) by the pull roller (nip roller) 17 and was caused to pass through the interdiffusion portion 12b having a length of 30 cm, thereby causing interdiffusion to occur between the respective layers.

Next, the filament A was caused to pass through the center of the first curing portion (light irradiation unit) 12c in which eighteen 40 W chemical lamps having a length of 120 cm were disposed around a central axis at regular intervals, to cure the filament A while interdiffusion was caused to occur between the respective layers. Next, the filament A was caused to pass through the center of the second curing portion (light irradiation unit) 12d in which three 2 KW high-pressure mercury lamps were disposed around a central axis at regular intervals, to further cure the filament A. The flow rate of nitrogen in the interdiffusion portion 12b was 72 L/min.

The radius of the rod lens base fiber obtained as above was 0.30 mm.

Next, the obtained rod lens base fiber was cut into a length of 166 mm to obtain a rod lens.

In the rod lens obtained as above, the radius r was 0.30 mm and Tg was 105° C. In addition, the central refractive index n₀ of the rod lens was 1.496 at a wavelength of 525 nm, the refractive index distribution approximates the expression (6) in a range of 0.2r to 0.8r from the center to the outer periphery, and the refractive index distribution constant g at a wavelength of 525 nm was 0.52 mm⁻¹. In addition, in a range of 0 to r from the center to the outer periphery, the maximum value of the difference |K_{α}−K_{β}| between K values at two arbitrary points α and β was 4.7. The rod lens was transparent, and a dye layer was formed in the outer periphery of the rod lens.

Using many of the obtained rod lenses, a rod lens array having two rod lens lines (lens length: 8.0 mm) at an alignment pitch of 0.61 mm (a gap of 10 μm between adjacent lenses) was prepared.

As shown in Table 13, in the rod lens array obtained as above, the conjugation lengths Tc at wavelengths of 470 nm, 525 nm, and 630 nm were substantially the same and thus, a lens having a low chromatic aberration was obtained. In addition, deterioration in the average MTF after the heat resistance test was extremely small at wavelengths of 470 nm, 525 nm, and 630 nm and the heat resistance was extremely excellent.

In addition, a color image sensor head was prepared using the prepared rod lens array. When reading was performed by the color image sensor head, a clear image was obtained without color bleeding, and a clear image was obtained in a state where a document is disposed with a gap. In addition, there was almost no change in the read image before and after the heat resistance test.

### Example 7

43 parts by mass of PMMA, 22 parts by mass of MMA, 5 parts by mass of PhMA, 30 parts by mass of TCDMA, 0.25 parts by mass of HCPK, and 0.1 parts by mass of HQ were heated and kneaded at 70° C. to obtain a first layer-forming solution (uncured material). This composition is the same as that of sample No. 137.

43 parts by mass of PMMA, 19.2 parts by mass of MMA, 6.3 parts by mass of PhMA, 26.5 parts by mass of TCDMA, 5 parts by mass of TBMA, 0.25 parts by mass of HCPK, and 0.1 parts by mass of HQ were heated and kneaded at 70° C. to obtain a second layer-forming solution (uncured material). This composition is the same as that of sample No. 138.

43 parts by mass of PMMA, 17.2 parts by mass of MMA, 8 parts by mass of PhMA, 21 parts by mass of TCDMA, 10.8 parts by mass of TBMA, 0.25 parts by mass of HCPK, and 0.1 parts by mass of HQ were heated and kneaded at 70° C. to obtain a third layer-forming solution (uncured material). This composition is the same as that of sample No. 139.

47 parts by mass of PMMA, 24.7 parts by mass of MMA, 9.9 parts by mass of PhMA, 6.6 parts by mass of TCDMA, 11.8 parts by mass of TBMA, 0.25 parts by mass of HCPK, and 0.1 parts by mass of HQ were heated and kneaded at 70° C. to obtain a fourth layer-forming solution (uncured material). This composition is the same as that of sample No. 140.

45 parts by mass of PMMA, 18.5 parts by mass of MMA, 14.5 parts by mass of PhMA, 7 parts by mass of TBMA, 15 parts by mass of 8FM, 0.25 parts by mass of HCPK, and 0.1 parts by mass of HQ were heated and kneaded at 70° C. to obtain a fifth layer-forming solution (uncured material). This composition is the same as that of sample No. 141.

The composition of the forming solution of each layer is shown in Table 11.

The same kinds and amounts of dyes as those of Example 1 were added to the fourth layer-forming solution and the fifth layer-forming solution.

A rod lens base fiber was manufactured with the same method as that of Example 6, except that the forming solution of each layer prepared with the above-described composition was used; and the discharge ratio of each layer was changed to first layer/second layer/third layer/fourth layer/fifth layer=24.0/31.1/40.2/2.2/2.5. This rod lens base fiber was cut into a length of 166 mm to obtain a rod lens having a radius of 0.30 mm.

This rod lens base fiber was drawn at 3.15 times in an atmosphere of 135° C. and was relaxed at a relaxation ratio of 500/700 in an atmosphere of 115° C.

In the rod lens obtained as above, the radius r was 0.20 mm and Tg was 110° C. In addition, the central refractive index n₀ of the rod lens was 1.503 at a wavelength of 525 nm, the refractive index distribution approximates the expression (6) in a range of 0.2r to 0.8r from the center to the outer periphery, and the refractive index distribution constant g at a wavelength of 525 nm was 0.68 mm⁻¹. In addition, in a range of 0 to r from the center to the outer periphery, the maximum value of the difference between K values at two arbitrary points α and β was 2.8. The rod lens was transparent, and a dye layer was formed in the outer periphery of the rod lens.

Using many of the obtained rod lenses, a rod lens array having two rod lens lines (lens length: 5.5 mm) at an alignment pitch of 0.41 mm (a gap of 10 μm between adjacent lenses) was prepared.

As shown in Table 13, in the rod lens array obtained as above, the conjugation lengths Tc at wavelengths of 470 nm, 525 nm, and 630 nm were substantially the same and thus, a lens having a low chromatic aberration was obtained. In addition, deterioration in the average MTF after the heat resistance test was extremely small at wavelengths of 470 nm, 525 nm, and 630 nm, and the heat resistance was extremely excellent.

In addition, a color image sensor head was prepared using the prepared rod lens array. When reading was performed by the color image sensor head, a clear image was obtained without color bleeding, and a clear image was obtained in a state where a document is disposed with a gap. In addition, there was almost no change in the read image before and after the heat resistance test.

### Example 8

44 parts by mass of PMMA, 15 parts by mass of MMA, 7.5 parts by mass of PhMA, 30 parts by mass of TCDMA, 3.5 parts by mass of TBMA, 0.25 parts by mass of HCPK, and 0.1 parts by mass of HQ were heated and kneaded at 70° C. to obtain a first layer-forming solution (uncured material). This composition is the same as that of sample No. 142.

44 parts by mass of PMMA, 17 parts by mass of MMA, 8 parts by mass of PhMA, 25.5 parts by mass of TCDMA, 5.5 parts by mass of TBMA, 0.25 parts by mass of HCPK, and 0.1 parts by mass of HQ were heated and kneaded at 70° C. to obtain a second layer-forming solution (uncured material). This composition is the same as that of sample No. 143.

44.5 parts by mass of PMMA, 17.7 parts by mass of MMA, 8.8 parts by mass of PhMA, 18.5 parts by mass of TCDMA, 10.5 parts by mass of TBMA, 0.25 parts by mass of HCPK, and 0.1 parts by mass of HQ were heated and kneaded at 70° C. to obtain a third layer-forming solution (uncured material). This composition is the same as that of sample No. 144.

45.8 parts by mass of PMMA, 17 parts by mass of MMA, 9.7 parts by mass of PhMA, 11.5 parts by mass of TCDMA, 16 parts by mass of TBMA, 0.25 parts by mass of HCPK, and 0.1 parts by mass of HQ were heated and kneaded at 70° C. to obtain a fourth layer-forming solution (uncured material). This composition is the same as that of sample No. 145.

45 parts by mass of PMMA, 5 parts by mass of MMA, 15 parts by mass of PhMA, 2 parts by mass of TCDMA, 20 parts by mass of TBMA, 13 parts by mass of 4FM, 0.25 parts by mass of HCPK, and 0.1 parts by mass of HQ were heated and kneaded at 70° C. to obtain a fifth layer-forming solution (uncured material). This composition is the same as that of sample No. 146.

The composition of the forming solution of each layer is shown in Table 11.

The same kinds and amounts of dyes as those of Example 1 were added to the fourth layer-forming solution and the fifth layer-forming solution.

A rod lens base fiber was manufactured with the same method as that of Example 6, except that the forming solution of each layer prepared with the above-described composition was used; and the discharge ratio of each layer was changed to first layer/second layer/third layer/fourth layer/fifth layer=16.0/11.1/60.2/10.2/2.5. This rod lens base fiber was cut into a length of 166 mm to obtain a rod lens having a radius of 0.30 mm.

This rod lens base fiber was drawn at 2.02 times in an atmosphere of 135° C. and was relaxed at a relaxation ratio of 500/700 in an atmosphere of 115° C.

In the rod lens obtained as above, the radius r was 0.25 mm and Tg was 110° C. In addition, the central refractive index n₀ of the rod lens was 1.503 at a wavelength of 525 nm, the refractive index distribution approximates the expression (6) in a range of 0.2r to 0.8r from the center to the outer periphery, and the refractive index distribution constant g at a wavelength of 525 nm was 0.25 mm⁻¹. In addition, in a range of 0 to r from the center to the outer periphery, the maximum value of the difference between K values at two arbitrary points α and β was 0.3. The rod lens was transparent, and a dye layer was formed in the outer periphery of the rod lens.

Using many of the obtained rod lenses, a rod lens array having two rod lens lines (lens length: 16.0 mm) at an alignment pitch of 0.515 mm (a gap of 15 μm between adjacent lenses) was prepared.

As shown in Table 13, in the rod lens array obtained as above, the conjugation lengths Tc at wavelengths of 470 nm, 525 nm, and 630 nm were the same and thus, a lens having no chromatic aberration was obtained. In addition, there was almost no deterioration in the average MTF after the heat resistance test at wavelengths of 470 nm, 525 nm, and 630 nm, and heat resistance was extremely excellent.

In addition, a color image sensor head was prepared using the prepared rod lens array. When reading was performed by the color image sensor head, a clear image was obtained without color bleeding, and a clear image was obtained in a state where a document is disposed with a gap. In addition, there was almost no change in the read image before and after the heat resistance test.

### Example 9

40 parts by mass of PMMA, 10 parts by mass of MMA, 20 parts by mass of PhMA, 20 parts by mass of TCDMA, 10 parts by mass of TBMA, 0.25 parts by mass of HCPK, and 0.1 parts by mass of HQ were heated and kneaded at 70° C. to obtain a first layer-forming solution (uncured material). This composition is the same as that of sample No. 200.

44 parts by mass of PMMA, 15 parts by mass of MMA, 7.5 parts by mass of PhMA, 30 parts by mass of TCDMA, 3.5 parts by mass of TBMA, 0.25 parts by mass of HCPK, and 0.1 parts by mass of HQ were heated and kneaded at 70° C. to obtain a second layer-forming solution (uncured material). This composition is the same as that of sample No. 142.

44.5 parts by mass of PMMA, 17.7 parts by mass of MMA, 8.8 parts by mass of PhMA, 18.5 parts by mass of TCDMA, 10.5 parts by mass of TBMA, 0.25 parts by mass of HCPK, and 0.1 parts by mass of HQ were heated and kneaded at 70° C. to obtain a third layer-forming solution (uncured material). This composition is the same as that of sample No. 144.

45.8 parts by mass of PMMA, 17 parts by mass of MMA, 9.7 parts by mass of PhMA, 11.5 parts by mass of TCDMA, 16 parts by mass of TBMA, 0.25 parts by mass of HCPK, and 0.1 parts by mass of HQ were heated and kneaded at 70° C. to obtain a fourth layer-forming solution (uncured material). This composition is the same as that of sample No. 145.

45.5 parts by mass of PMMA, 7.5 parts by mass of MMA, 10.5 parts by mass of PhMA, 6.5 parts by mass of TCDMA, 30 parts by mass of TBMA, 0.25 parts by mass of HCPK, and 0.1 parts by mass of HQ were heated and kneaded at 70° C. to obtain a fifth layer-forming solution (uncured material). This composition is the same as that of sample No. 152.

The composition of the forming solution of each layer is shown in Table 11.

The same kinds and amounts of dyes as those of Example 1 were added to the fourth layer-forming solution and the fifth layer-forming solution.

A rod lens base fiber was manufactured with the same method as that of Example 6, except that the forming solution of each layer prepared with the above-described composition was used. This rod lens base fiber was cut into a length of 166 mm to obtain a rod lens having a radius of 0.300 mm.

In the rod lens obtained as above, the radius r was 0.300 mm and Tg was 110.0° C. In addition, the central refractive index n₀ of the rod lens was 1.506 at a wavelength of 525 nm, the refractive index distribution approximates the expression (6) in a range of 0.2r to 0.8r from the center to the outer periphery, and the refractive index distribution constant g at a wavelength of 525 nm was 0.45 mm⁻¹. In addition, in a range of 0 to r from the center to the outer periphery, the maximum value of the difference between K values at two arbitrary points α and β was 10.5. The rod lens was transparent, and a dye layer was formed in the outer periphery of the rod lens.

Using many of the obtained rod lenses, a rod lens array having two rod lens lines (lens length: 8.0 mm) at an alignment pitch of 0.615 mm (a gap of 15 μm between adjacent lenses) was prepared.

As shown in Table 13, in the rod lens array obtained as above, the conjugation lengths Tc at wavelengths of 470 nm, 525 nm, and 630 nm were greatly different and thus, a lens having a large chromatic aberration was obtained. In addition, there was almost no deterioration in the average MTF after the heat resistance test at wavelengths of 470 nm, 525 nm, and 630 nm, and heat resistance was extremely excellent.

In addition, a color image sensor head was prepared using the prepared rod lens array. When reading was performed by the color image sensor head, color bleeding was observed and an unclear image was obtained. In addition, when reading was performed in a state where a document was disposed with a gap, substantially the same image as an image read in a state where the document was disposed without a gap was obtained. In addition, there was no change in the read image before and after the heat resistance test.

### Comparative Example 3

46 parts by mass of PMMA, 24 parts by mass of MMA, 30 parts by mass of TCDMA, 0.25 parts by mass of HCPK, and 0.1 parts by mass of HQ were heated and kneaded at 70° C. to obtain a first layer-forming solution (uncured material). This composition is the same as that of sample No. 132.

45 parts by mass of PMMA, 29 parts by mass of MMA, 5 parts by mass of BzMA, 15 parts by mass of TCDMA, 6 parts by mass of 8FM, 0.25 parts by mass of HCPK, and 0.1 parts by mass of HQ were heated and kneaded at 70° C. to obtain a second layer-forming solution (uncured material). This composition is the same as that of sample No. 188.

49 parts by mass of PMMA, 37 parts by mass of MMA, 6 parts by mass of BzMA, 8 parts by mass of 8FM, 0.25 parts by mass of HCPK, and 0.1 parts by mass of HQ were heated and kneaded at 70° C. to obtain a third layer-forming solution (uncured material). This composition is the same as that of sample No. 189.

47 parts by mass of PMMA, 23 parts by mass of MMA, 10 parts by mass of BzMA, 20 parts by mass of 8FM, 0.25 parts by mass of HCPK, and 0.1 parts by mass of HQ were heated and kneaded at 70° C. to obtain a fourth layer-forming solution (uncured material). This composition is the same as that of sample No. 190.

39 parts by mass of PMMA, 3 parts by mass of MMA, 17 parts by mass of BzMA, 41 parts by mass of 8FM, 0.25 parts by mass of HCPK, and 0.1 parts by mass of HQ were heated and kneaded at 70° C. to obtain a fifth layer-forming solution (uncured material). This composition is the same as that of sample No. 191.

The composition of the forming solution of each layer is shown in Table 12.

A rod lens base fiber was manufactured with the same method as that of Example 6, except that the forming solution of each layer prepared with the above-described composition was used; and the number of the 40 W chemical lamps of the first curing portion (light irradiation portion) was reduced to half, that is, nine. This rod lens base fiber was cut into a length of 166 mm to obtain a rod lens having a radius of 0.30 mm.

In the rod lens obtained as above, the radius r was 0.30 mm and Tg was 92° C. In addition, the central refractive index n₀ of the rod lens was 1.497 at a wavelength of 525 nm, the refractive index distribution approximates the expression (6) in a range of 0.2r to 0.8r from the center to the outer periphery, and the refractive index distribution constant g at a wavelength of 525 nm was 0.49 mm⁻¹. In addition, in a range of 0 to r from the center to the outer periphery, the maximum value of the difference between K values at two arbitrary points α and β was 1.9. The rod lens was transparent, and a dye layer was formed in the outer periphery of the rod lens.

Using many of the obtained rod lenses, a rod lens array having two rod lens lines (lens length: 8.0 mm) at an alignment pitch of 0.615 mm (a gap of 15 μm between adjacent lenses) was prepared.

As shown in Table 13, in the rod lens array obtained as above, the conjugation lengths Tc at wavelengths of 470 nm, 525 nm, and 630 nm were substantially the same and thus, a lens having a low chromatic aberration was obtained; however, there was an extremely large deterioration in the average MTF after the heat resistance test at wavelengths of 470 nm, 525 nm, and 630 nm, and heat resistance was poor.

In addition, a color image sensor head was prepared using the prepared rod lens array. When reading was performed by the color image sensor head, a clear image was obtained without color bleeding, and a clear image was obtained in a state where a document is disposed with a gap. However, when reading was performed after the heat resistance test, the read image was unclear.

### Comparative Example 4

43 parts by mass of PMMA, 10 parts by mass of MMA, 4 parts by mass of PhMA, 12 parts by mass of TCDMA, 11 parts by mass of TBMA, 20 parts by mass of 4FM, 0.25 parts by mass of HCPK, and 0.1 parts by mass of HQ were heated and kneaded at 70° C. to obtain a first layer-forming solution (uncured material). This composition is the same as that of sample No. 192.

43 parts by mass of PMMA, 7 parts by mass of MMA, 5 parts by mass of PhMA, 10 parts by mass of TCDMA, 10 parts by mass of TBMA, 25 parts by mass of 4FM, 0.25 parts by mass of HCPK, and 0.1 parts by mass of HQ were heated and kneaded at 70° C. to obtain a second layer-forming solution (uncured material). This composition is the same as that of sample No. 193.

42 parts by mass of PMMA, 17 parts by mass of MMA, 6 parts by mass of PhMA, 5 parts by mass of TCDMA, 30 parts by mass of 4FM, 0.25 parts by mass of HCPK, and 0.1 parts by mass of HQ were heated and kneaded at 70° C. to obtain a third layer-forming solution (uncured material). This composition is the same as that of sample No. 194.

44 parts by mass of PMMA, 11 parts by mass of MMA, 7 parts by mass of PhMA, 3 parts by mass of TCDMA, 35 parts by mass of 4FM, 0.25 parts by mass of HCPK, and 0.1 parts by mass of HQ were heated and kneaded at 70° C. to obtain a fourth layer-forming solution (uncured material). This composition is the same as that of sample No. 195.

40 parts by mass of PMMA, 5 parts by mass of MMA, 10 parts by mass of PhMA, 45 parts by mass of 4FM, 0.25 parts by mass of HCPK, and 0.1 parts by mass of HQ were heated and kneaded at 70° C. to obtain a fifth layer-forming solution (uncured material). This composition is the same as that of sample No. 196.

The composition of the forming solution of each layer is shown in Table 12.

The same kinds and amounts of dyes as those of Example 1 were added to the fourth layer-forming solution and the fifth layer-forming solution.

A rod lens base fiber was manufactured with the same method as that of Comparative Example 3, except that the forming solution of each layer prepared with the above-described composition was used. This rod lens base fiber was cut into a length of 166 mm to obtain a rod lens having a radius of 0.300 mm.

In the rod lens obtained as above, the radius r was 0.300 mm and Tg was 95° C. In addition, the central refractive index n₀ of the rod lens was 1.482 at a wavelength of 525 nm, the refractive index distribution approximates the expression (6) in a range of 0.2r to 0.8r from the center to the outer periphery, and the refractive index distribution constant g at a wavelength of 525 nm was 0.21 mm⁻¹. In addition, in a range of 0 to r from the center to the outer periphery, the maximum value of the difference |K_{α}−K_{β}| between K values at two arbitrary points α and β was 4.6. The lens was transparent, the rod lens was transparent, and a dye layer was formed in the outer periphery of the rod lens.

Using many of the obtained rod lenses, a rod lens array having two rod lens lines (lens length: 20.0 mm) at an alignment pitch of 0.615 mm (a gap of 15 μm between adjacent lenses) was prepared.

As shown in Table 13, in the rod lens array obtained as above, the conjugation lengths Tc at wavelengths of 470 nm, 525 nm, and 630 nm were substantially the same and thus, a lens having a low chromatic aberration was obtained; however, there was an extremely large deterioration in the average MTF after the heat resistance test at wavelengths of 470 nm, 525 nm, and 630 nm, and heat resistance was poor.

In addition, a color image sensor head was prepared using the prepared rod lens array. When reading was performed by the color image sensor head, a clear image was obtained without color bleeding, and a clear image was obtained in a state where a document is disposed with a gap. However, when reading was performed after the heat resistance test, the read image was unclear.

### Comparative Example 5

43 parts by mass of PMMA, 22 parts by mass of MMA, 5 parts by mass of PhMA, 30 parts by mass of TCDMA, 0.25 parts by mass of HCPK, and 0.1 parts by mass of HQ were heated and kneaded at 70° C. to obtain a first layer-forming solution (uncured material). This composition is the same as that of sample No. 137.

44.5 parts by mass of PMMA, 17.7 parts by mass of MMA, 8.8 parts by mass of PhMA, 18.5 parts by mass of TCDMA, 10.5 parts by mass of TBMA, 0.25 parts by mass of HCPK, and 0.1 parts by mass of HQ were heated and kneaded at 70° C. to obtain a second layer-forming solution (uncured material). This composition is the same as that of sample No. 144.

30 parts by mass of PMMA, 10 parts by mass of PhMA, 20 parts by mass of TCDMA, 40 parts by mass of TBMA, 0.25 parts by mass of HCPK, and 0.1 parts by mass of HQ were heated and kneaded at 70° C. to obtain a third layer-forming solution (uncured material). This composition is the same as that of sample No. 207.

45 parts by mass of PMMA, 18.5 parts by mass of MMA, 14.5 parts by mass of PhMA, 7 parts by mass of TBMA, 15 parts by mass of 8FM, 0.25 parts by mass of HCPK, and 0.1 parts by mass of HQ were heated and kneaded at 70° C. to obtain a fourth layer-forming solution (uncured material). This composition is the same as that of sample No. 141.

44.8 parts by mass of PMMA, 13.9 parts by mass of MMA, 12.1 parts by mass of PhMA, 14.2 parts by mass of TBMA, 15 parts by mass of 8FM, 0.25 parts by mass of HCPK, and 0.1 parts by mass of HQ were heated and kneaded at 70° C. to obtain a fifth layer-forming solution (uncured material). This composition is the same as that of sample No. 135.

The composition of the forming solution of each layer is shown in Table 12.

The same kinds and amounts of dyes as those of Example 1 were added to the fourth layer-forming solution and the fifth layer-forming solution.

A rod lens base fiber was manufactured with the same method as that of Example 6, except that the forming solution of each layer prepared with the above-described composition was used. This rod lens base fiber was cut into a length of 166 mm to obtain a rod lens having a radius of 0.300 mm.

In the rod lens obtained as above, the radius r was 0.300 mm and Tg was 106° C. In addition, the central refractive index n₀ of the rod lens was 1.502 at a wavelength of 525 nm, the refractive index distribution approximates the expression (6) in a range of 0.2r to 0.8r from the center to the outer periphery, and the refractive index distribution constant g at a wavelength of 525 nm was 0.50 mm⁻¹. In addition, in a range of 0 to r from the center to the outer periphery, the maximum value of the difference between K values at two arbitrary points α and β was 2.9. The rod lens was cloudy, and a dye layer was formed in the outer periphery of the rod lens.

Using many of the obtained rod lenses, a rod lens array having two rod lens lines (lens length: 8.0 mm) at an alignment pitch of 0.615 mm (a gap of 15 μm between adjacent lenses) was prepared.

As shown in Table 13, in the rod lens array obtained as above, the conjugation lengths Tc at wavelengths of 470 nm, 525 nm, and 630 nm were substantially the same and thus, a lens having a low chromatic aberration was obtained. However, since the lens was cloudy, the resolution was low. In addition, deterioration in the average MTF after the heat resistance test was extremely small at wavelengths of 470 nm, 525 nm, and 630 nm.

In addition, a color image sensor head was prepared using the prepared rod lens array. When reading was performed by the color image sensor head, color bleeding is small but the lens is cloudy. Therefore, the resolution is low and thus, only an unclear image was obtained.

### Comparative Example 6

48 parts by mass of PMMA, 36.2 parts by mass of MMA, 5.8 parts by mass of PhMA, 10 parts by mass of TBMA, 0.25 parts by mass of HCPK, and 0.1 parts by mass of HQ were heated and kneaded at 70° C. to obtain a first layer-forming solution (uncured material). This composition is the same as that of sample No. 134.

45 parts by mass of PMMA, 18.5 parts by mass of MMA, 14.5 parts by mass of PhMA, 7 parts by mass of TBMA, 15 parts by mass of 8FM, 0.25 parts by mass of HCPK, and 0.1 parts by mass of HQ were heated and kneaded at 70° C. to obtain a second layer-forming solution (uncured material). This composition is the same as that of sample No. 141.

44.8 parts by mass of PMMA, 13.9 parts by mass of MMA, 12.1 parts by mass of PhMA, 14.2 parts by mass of TBMA, 15 parts by mass of 8FM, 0.25 parts by mass of HCPK, and 0.1 parts by mass of HQ were heated and kneaded at 70° C. to obtain a third layer-forming solution (uncured material). This composition is the same as that of sample No. 135.

40.3 parts by mass of PMMA, 3.4 parts by mass of MMA, 15.9 parts by mass of PhMA, 10.4 parts by mass of TBMA, 30 parts by mass of 8FM, 0.25 parts by mass of HCPK, and 0.1 parts by mass of HQ were heated and kneaded at 70° C. to obtain a fourth layer-forming solution (uncured material). This composition is the same as that of sample No. 136.

40 parts by mass of PMMA, 5 parts by mass of MMA, 10 parts by mass of PhMA, 45 parts by mass of 4FM, 0.25 parts by mass of HCPK, and 0.1 parts by mass of HQ were heated and kneaded at 70° C. to obtain a fifth layer-forming solution (uncured material). This composition is the same as that of sample No. 196.

The composition of the forming solution of each layer is shown in Table 12.

The same kinds and amounts of dyes as those of Example 1 were added to the fourth layer-forming solution and the fifth layer-forming solution.

A rod lens base fiber was manufactured with the same method as that of Example 6, except that the forming solution of each layer prepared with the above-described composition was used. This rod lens base fiber was cut into a length of 166 mm to obtain a rod lens having a radius of 0.300 mm.

In the rod lens obtained as above, the radius r was 0.300 mm and Tg was 95° C. In addition, the central refractive index n₀ of the rod lens was 1.492 at a wavelength of 525 nm, the refractive index distribution approximates the expression (6) in a range of 0.2r to 0.8r from the center to the outer periphery, and the refractive index distribution constant g at a wavelength of 525 nm was 0.53 mm⁻¹. In addition, in a range of 0 to r from the center to the outer periphery, the maximum value of the difference |K_{α}−K_{β}| between K values at two arbitrary points α and β was 8.0. The rod lens was transparent, and a dye layer was formed in the outer periphery of the rod lens.

Using many of the obtained rod lenses, a rod lens array having two rod lens lines (lens length: 8.0 mm) at an alignment pitch of 0.615 mm (a gap of 15 μm between adjacent lenses) was prepared.

As shown in Table 13, in the rod lens array obtained as above, the conjugation lengths Tc at wavelengths of 470 nm, 525 nm, and 630 nm were greatly different and thus, a lens having a large chromatic aberration was obtained. In addition, there was an extremely large deterioration in the average MTF after the heat resistance test at wavelengths of 470 nm, 525 nm, and 630 nm, and heat resistance was poor.

In addition, a color image sensor head was prepared using the prepared rod lens array. When reading was performed by the color image sensor head, color bleeding was observed and an unclear image was obtained. In addition, when reading was performed in a state where a document was disposed with a gap, substantially the same image as an image read in a state where the document was disposed without a gap was obtained. In addition, when reading was performed after the heat resistance test, a more unclear image was obtained.

### Comparative Example 7

35 parts by weight of PMMA, 50 parts by weight of TCDMA, 15 parts by weight of MMA, 0.2 parts by weight of HCPK, and 0.1 parts by weight of HQ were heated and kneaded at 70° C. to form a first layer (center portion)-forming solution. In addition, 37 parts by weight of PMMA, 13 parts by weight of MMA, 50 parts by weight of TBMA, 0.2 parts by weight of HCPK, and 0.1 parts by weight of HQ were heated and kneaded at 70° C. to form a second layer (outer peripheral portion)-forming solution.

Such 2 kinds of forming solutions were simultaneously extruded from a concentric 2-layer multi-component spinning nozzle to obtain a filament. The temperature of the multi-component spinning nozzle was 60° C.

The discharge ratio of each layer was first layer/second layer=1/1 in terms of the ratio of the thickness (radius in the first layer) of each layer in a radial direction of the rod lens. In this case, the first layer was the inside layer, and the second layer was the outside layer.

Next, a rod lens base fiber was manufactured from the obtained forming solutions using the device 10 of manufacturing a plastic rod lens base fiber illustrated in FIG. 2.

Specifically, nitrogen gas was introduced from the inert gas introducing pipe 13 into the receiving body 12, and the inert gas in the receiving body 12 was discharged from the inert gas discharge pipe 14.

In addition, a filament A extruded from the concentric multi-component spinning nozzle 11 was pulled (50 cm/min) by the pull roller (nip roller) 17 and was caused to pass through the interdiffusion portion 12b having a length of 60 cm, thereby causing interdiffusion to occur between the respective layers.

Next, the filament A was caused to pass through the center of the first curing portion (light irradiation unit) 12c in which twelve 40 W chemical lamps having a length of 120 cm were disposed around a central axis at regular intervals, to cure the filament A while interdiffusion was caused to occur between the respective layers. Next, the filament A was caused to pass through the center of the second curing portion (light irradiation unit) 12d in which three 2 KW high-pressure mercury lamps were disposed around a central axis at regular intervals, to further cure the filament A. The flow rate of nitrogen in the interdiffusion portion 12b was 72 L/min.

The radius of the rod lens base fiber obtained as above was 0.40 mm.

Next, the obtained rod lens base fiber was cut into a length of 166 mm to obtain a rod lens.

In the rod lens obtained as above, the radius r was 0.40 mm and Tg was 110° C. In addition, the central refractive index n₀ of the rod lens was 1.504 at a wavelength of 525 nm, the refractive index distribution approximates the expression (6) in a range of 0.2r to 0.8r from the center to the outer periphery, and the refractive index distribution constant g at a wavelength of 525 nm was 0.46 mm⁻¹. In addition, in a range of 0 to r from the center to the outer periphery, the maximum value of the difference |K_{α}−K_{β}| between K values at two arbitrary points α and β was 6.6. The lens was cloudy.

Using many of the obtained rod lenses, a rod lens array having two rod lens lines (lens length: 9.0 mm) at an alignment pitch of 0.815 mm (a gap of 15 μm between adjacent lenses) was prepared.

As shown in Table 13, in the rod lens array obtained as above, the conjugation lengths Tc at wavelengths of 470 nm, 525 nm, and 630 nm were greatly different and thus, a lens having a large chromatic aberration was obtained. In addition, since the lens was cloudy, an image was deformed and the resolution was extremely low. In addition, deterioration in the average MTF after the heat resistance test was extremely small at wavelengths of 470 nm, 525 nm, and 630 nm.

In addition, a color image sensor head was prepared using the prepared rod lens array. When reading was performed by the color image sensor head, color bleeding was observed. In addition, since the lens was cloudy, the resolution was extremely low, an image was deformed, only an extremely unclear image was obtained, and lens functions could not be exhibited.

TABLE 11

| | | | | Composition Ratio (Mass %) of Polymer Mixture | | | | | | | |
|---|---|---|---|---|---|---|---|---|---|---|---|
| | | | | Polymer | Monomer | Monomer | | Monomer | Monomer | | |
| | | | Sample | (M) | (m) | (a) | | (b) | (d) | Monomer (c) | |
| | | Polymer | No. | PMMA | MMA | PhMA | BzMA | TBMA | TCDMA | 8FM | 4FM |
| Example 6 | First Layer | | 132 | 46 | 24 | 0 | | | 30 | | |
| | Second Layer | Q-1 | 133 | 45 | 30.6 | 3 | | 5 | 16.4 | | |
| | Third Layer | | 134 | 48 | 36.2 | 5.8 | | 10 | | | |
| | Fourth Layer | | 135 | 44.8 | 13.9 | 12.1 | | 14.2 | | 15 | |
| | Fifth Layer | | 136 | 40.3 | 3.4 | 15.9 | | 10.4 | | 30 | |
| Example 7 | First Layer | | 137 | 43 | 22 | 5 | | | 30 | | |
| | Second Layer | Q-2 | 138 | 43 | 19.2 | 6.3 | | 5 | 26.5 | | |
| | Third Layer | Q-3 | 139 | 43 | 17.2 | 8 | | 10.8 | 21 | | |
| | Fourth Layer | Q-4 | 140 | 47 | 24.7 | 9.9 | | 11.8 | 6.6 | | |
| | Fifth Layer | | 141 | 45 | 18.5 | 14.5 | | 7 | | 15 | |
| Example 8 | First Layer | Q-5 | 142 | 44 | 15 | 7.5 | | 3.5 | 30 | | |
| | Second Layer | Q-6 | 143 | 44 | 17 | 8 | | 5.5 | 25.5 | | |
| | Third Layer | Q-7 | 144 | 44.5 | 17.7 | 8.8 | | 10.5 | 18.5 | | |
| | Fourth Layer | Q-8 | 145 | 45.8 | 17 | 9.7 | | 16 | 11.5 | | |
| | Fifth Layer | Q-9 | 146 | 45 | 5 | 15 | | 20 | 2 | | 13 |
| Example 9 | First Layer | | 200 | 40 | 10 | 20 | | 10 | 20 | | |
| | Second Layer | Q-5 | 142 | 44 | 15 | 7.5 | | 3.5 | 30 | | |
| | Third Layer | Q-7 | 144 | 44.5 | 17.7 | 8.8 | | 10.5 | 18.5 | | |
| | Fourth Layer | Q-8 | 145 | 45.8 | 17 | 9.7 | | 16 | 11.5 | | |
| | Fifth Layer | Q-10 | 152 | 45.5 | 7.5 | 10.5 | | 30 | 6.5 | | |

| | | | | | | Expression (1) | | |
|---|---|---|---|---|---|---|---|---|
| | | | | | | 0.357[b]-1.786 < [a] < | | |
| | | | | Composition in | | 65-1.063[b] | | |
| | | K = n_{D} − V(n_{D} − 1) | | Range of 0.5r to r | | 0.357[b]- | | |
| | | K | \|K_{α} − K_{β}\| < 5 | 5% ≦ [a] | 2% ≦ [b] | 1.786 | [a] | 65-1.063[b] |
| Example 6 | First Layer | 166.4 | 4.7 | — | — | −2 | 0 | 65 |
| | Second Layer | 164.8 | | — | — | 0 | 3 | 57 |
| | Third Layer | 163.8 | | 5.8 | 10 | 1.8 | 5.8 | 49 |
| | Fourth Layer | 161.6 | | 12.1 | 14.2 | 3.3 | 12.1 | 42 |
| | Fifth Layer | 161.7 | | 15.9 | 10.4 | 1.9 | 15.9 | 48 |
| Example 7 | First Layer | 161.4 | 2.8 | — | — | −2 | 5 | 65 |
| | Second Layer | 160.6 | | — | — | 0 | 6.3 | 57 |
| | Third Layer | 159.6 | | 8 | 10.8 | 2.1 | 8 | 48 |
| | Fourth Layer | 158.9 | | 9.9 | 11.8 | 2.4 | 9.9 | 46 |
| | Fifth Layer | 158.6 | | 14.5 | 7 | 0.7 | 14.5 | 54 |
| Example 8 | First Layer | 158.9 | 0.3 | — | — | −0.5 | 7.5 | 59 |
| | Second Layer | 158.9 | | — | — | 0.2 | 8 | 56 |
| | Third Layer | 159 | | 8.8 | 10.5 | 2 | 8.8 | 48 |
| | Fourth Layer | 158.8 | | 9.7 | 16 | 3.9 | 9.7 | 39 |
| | Fifth Layer | 158.7 | | 15 | 30 | 5.4 | 15 | 33 |
| Example 9 | First Layer | 148.5 | 10.5 | — | — | 1.8 | 20 | 49 |
| | Second Layer | 158.9 | | — | — | −0.5 | 7.5 | 59 |
| | Third Layer | 159 | | 8.8 | 10.5 | 2 | 8.8 | 48 |
| | Fourth Layer | 158.8 | | 9.7 | 16 | 3.9 | 9.7 | 39 |
| | Fifth Layer | 159 | | 10.5 | 30 | 8.9 | 10.5 | 17 |

TABLE 12

| | | | | Composition Ratio (Mass %) of Polymer Mixture | | | | | | | |
|---|---|---|---|---|---|---|---|---|---|---|---|
| | | | | Polymer | Monomer | | | Monomer | Monomer | | |
| | | | Sample | (M) | (m) | Monomer (a) | | (b) | (d) | Monomer (c) | |
| | | Polymer | No. | PMMA | MMA | PhMA | BzMA | TBMA | TCDMA | 8FM | 4FM |
| Comparative | First Layer | | 132 | 46 | 24 | | | | 30 | | |
| Example 3 | Second Layer | | 188 | 45 | 29 | | 5 | | 15 | 6 | |
| | Third Layer | | 189 | 49 | 37 | | 6 | | | 8 | |
| | Fourth Layer | | 190 | 47 | 23 | | 10 | | | 20 | |
| | Fifth Layer | | 191 | 39 | 3 | | 17 | | | 41 | |
| Comparative | First Layer | Q-11 | 192 | 43 | 10 | 4 | | 11 | 12 | | 20 |
| Example 4 | Second Layer | Q-12 | 193 | 43 | 7 | 5 | | 10 | 10 | | 25 |
| | Third Layer | | 194 | 42 | 17 | 6 | | | 5 | | 30 |
| | Fourth Layer | | 195 | 44 | 11 | 7 | | | 3 | | 35 |
| | Fifth Layer | | 196 | 40 | 5 | 10 | | | | | 45 |
| Comparative | Sixth Layer | | 137 | 43 | 22 | 5 | | | 30 | | |
| Example 5 | Seventh Layer | Q-7 | 144 | 44.5 | 17.7 | 8.8 | | 10.5 | 18.5 | | |
| | Eighth Layer | Q-13 | 207 | 30 | | 10 | | 40 | 20 | | |
| | Ninth Layer | | 141 | 45 | 18.5 | 14.5 | | 7 | | 15 | |
| | Tenth Layer | | 135 | 44.8 | 13.9 | 12.1 | | 14.2 | | 15 | |
| Comparative | First Layer | | 134 | 48 | 36.2 | 5.8 | | 10 | | | |
| Example 6 | Second Layer | | 141 | 45 | 18.5 | 14.5 | | 7 | | 15 | |
| | Third Layer | | 135 | 44.8 | 13.9 | 12.1 | | 14.2 | | 15 | |
| | Fourth Layer | | 136 | 40.3 | 3.4 | 15.9 | | 10.4 | | 30 | |
| | Fifth Layer | | 196 | 40 | 5 | 10 | | | | | 45 |
| Comparative | First Layer | | | 35 | 15 | | | | 50 | | |
| Example 7 | Second Layer | | | 37 | 13 | | | 50 | | | |

| | | | | | | Expression (1) | | |
|---|---|---|---|---|---|---|---|---|
| | | | | | | 0.357[b]-1.786 < [a] < | | |
| | | | | Composition in | | 65-1.063[b] | | |
| | | K = n_{D} − V(n_{D} − 1) | | Range of 0.5r to r | | 0.357[b]- | | |
| | | K | \|K_{α} − Kₒ\| < 5 | 5% ≦ [a] | 2% ≦ [b] | 1.786 | [a] | 65-1.063[b] |
| Comparative | First Layer | 166.7 | 1.9 | — | — | −2 | 0 | 65 |
| Example 3 | Second Layer | 164.8 | | — | — | −2 | 5 | 65 |
| | Third Layer | 166.6 | | 6 | 0 | −2 | 6 | 65 |
| | Fourth Layer | 166.2 | | 10 | 0 | −2 | 10 | 65 |
| | Fifth Layer | 165.9 | | 17 | 0 | −2 | 17 | 65 |
| Comparative | First Layer | 171.9 | 4.6 | — | — | 2.1 | 4 | 47 |
| Example 4 | Second Layer | 173 | | — | — | 1.8 | 5 | 49 |
| | Third Layer | 174.3 | | 6 | 0 | −2 | 6 | 65 |
| | Fourth Layer | 175.5 | | 7 | 0 | −2 | 7 | 65 |
| | Fifth Layer | 176.5 | | 10 | 0 | −2 | 10 | 65 |
| Comparative | Sixth Layer | 161.4 | 2.9 | — | — | −2 | 5 | 65 |
| Example 5 | Seventh Layer | 159 | | — | — | 2 | 8.8 | 48 |
| | Eighth Layer | 158.8 | | 10 | 40 | 12.5 | 10 | 1 |
| | Ninth Layer | 158.6 | | 14.5 | 7 | 0.7 | 14.5 | 54 |
| | Tenth Layer | 161.5 | | 12.1 | 14.2 | 3.3 | 12.1 | 42 |
| Comparative | First Layer | 163.8 | 8 | — | — | 2 | 5.8 | 49 |
| Example 6 | Second Layer | 158.6 | | — | — | 1 | 14.5 | 54 |
| | Third Layer | 161.6 | | 12.1 | 14.2 | 3 | 12.1 | 42 |
| | Fourth Layer | 161.7 | | 15.9 | 10.4 | 2 | 15.9 | 48 |
| | Fifth Layer | 176.6 | | 10 | 0 | −2 | 10 | 65 |
| Comparative | First Layer | 164.4 | 6.6 | — | — | −2 | 0 | 65 |
| Example 7 | Second Layer | 171 | | 0 | 50 | 16 | 0 | −15 |

TABLE 13

| | | | | | | | | | | | Average MTF | | | | | |
|---|---|---|---|---|---|---|---|---|---|---|---|---|---|---|---|---|
| | | | Refractive | | | | | | | | (%) before | | | Average MTF | | |
| | | | index | | | | Conjugation | | | | Heat Resistance | | | (%) after Heat | | |
| | | Lens | Distribution | | Lens | Lens | Length TC (mm) | | | | Test | | | Resistance Test | | |
| | Radius | Length | Constant g | \|Kα − | Tg | Trans- | 470 | 525 | 630 | | 470 | 525 | 630 | 470 | 525 | 630 |
| | r (mm) | (mm) | (mm⁻¹) | Kβ\| | (° C.) | parency | nm | nm | nm | ΔTC | nm | nm | nm | nm | nm | nm |
| Example 6 | 0.3 | 8 | 0.52 | 4.7 | 105 | Transparent | 12.7 | 12.8 | 13 | 0.3 | 81 | 84 | 79 | 78 | 79 | 75 |
| Example 7 | 0.2 | 5.5 | 0.68 | 2.8 | 110 | Transparent | 11.6 | 11.7 | 11.8 | 0.2 | 81 | 78 | 76 | 75 | 73 | 73 |
| Example 8 | 0.25 | 16 | 0.25 | 0.3 | 110 | Transparent | 26.9 | 26.9 | 26.9 | 0 | 75 | 76 | 75 | 73 | 72 | 74 |
| Example 9 | 0.3 | 8 | 0.45 | 10.5 | 110 | Transparent | 19.2 | 19.6 | 20.1 | 0.9 | 78 | 80 | 76 | 75 | 77 | 74 |
| Comparative | 0.3 | 8 | 0.49 | 1.9 | 92 | Transparent | 14.8 | 14.9 | 15 | 0.2 | 75 | 78 | 73 | 37 | 46 | 42 |
| Example 3 | | | | | | | | | | | | | | | | |
| Comparative | 0.3 | 20 | 0.21 | 4.6 | 95 | Transparent | 30.2 | 30.4 | 30.6 | 0.4 | 79 | 85 | 83 | 51 | 58 | 45 |
| Example 4 | | | | | | | | | | | | | | | | |
| Comparative | 0.3 | 8 | 0.5 | 2.9 | 106 | Cloudy | 13.6 | 13.7 | 13.8 | 0.2 | 51 | 52 | 49 | 45 | 49 | 47 |
| Example 5 | | | | | | | | | | | | | | | | |
| Comparative | 0.3 | 8 | 0.53 | 8 | 95 | Transparent | 11.6 | 12 | 12.4 | 0.8 | 68 | 72 | 69 | 41 | 45 | 33 |
| Example 6 | | | | | | | | | | | | | | | | |
| Comparative | 0.4 | 9 | 0.46 | 6.6 | 110 | Cloudy | 14.3 | 14.6 | 15 | 0.7 | 38 | 36 | 34 | 33 | 32 | 30 |
| Example 7 | | | | | | | | | | | | | | | | |

### INDUSTRIAL APPLICABILITY

The rod lens according to the present invention has a high light intensity, a small chromatic aberration, and has excellent heat resistance; and thus is suitable for copying machines and LED printers.

### REFERENCE SIGNS LIST

1: plastic rod lens
O: center
10: device of manufacturing plastic rod lens base fiber
11: concentric multi-component spinning nozzle
12: receiving body
13: inert gas introducing pipe
14: inert gas discharge pipe
15: first light irradiation unit
16: second light irradiation unit
17: pull roller
20: drawing and relaxing device
21: first nip roller
22: second nip roller
23: third nip roller
24: first heating furnace
25: second heating furnace
30: plastic rod lens array
31: plastic rod lens
32: substrate
33: adhesive
40: LED printer head
41: housing
42: printed wiring board
43: LED array
45: rod lens array holder
46: plate spring
50: color image sensor head
51: line image sensor (photoelectric conversion element)
52: case
52a: first concave portion
52b: second concave portion
52c: third concave portion
52d: step portion
54: document tray
54a: document placement surface
56: linear light source
100: photoconductor drum
200: image reading apparatus
Ax: optical axis of rod lens array
G: document

1. A transparent plastic rod lens which has a cylindrical shape with a radius r in which a refractive index n_{D} is reduced from a center thereof to an outer periphery thereof, the plastic rod lens comprising
a polymer mixture (I),
wherein the polymer mixture (I) includes, as constitutional units,
an aromatic ring-containing monomer (a) unit and
at least one monomer unit selected from a group consisting of a (meth)acrylate (b) unit which has a branched hydrocarbon group having 3 or more carbon atoms, a fluorine-containing monomer (c) unit, and an alicyclic ring-containing (meth)acrylate (d) unit, and
a glass transition temperature is higher than or equal to 100° C.

2. The plastic rod lens according to claim 1,
wherein the polymer mixture (I) further includes a methyl methacrylate (m) unit as a constitutional unit.

3. The plastic rod lens according to claim 1,
wherein the polymer mixture (I) is a polymer mixture (II) which includes, as constitutional units, the (a) unit and at least one of the (b) unit and the (c) unit,
a difference in refractive index between a center portion and an outer peripheral portion is 0.02 to 0.06, and
compositions of the constitutional units of the polymer mixture (II) satisfy the following expression (1) at any position in a range of 0 to r from the center to the outer periphery.
0.357[b]−1.786<[a]<65−1.063[b] (1)
(wherein in the expression (1), [a] represents the content (mass %) of the constitutional unit (a); and [b] represents the content (mass %) of the constitutional unit (b))

4. The plastic rod lens according to claim 3,
wherein the polymer mixture (II) further includes a methyl methacrylate (m) unit as a constitutional unit.

5. The plastic rod lens according to claim 3,
wherein the (a) unit is phenyl methacrylate,
the (b) unit is at least one selected from a group consisting of t-butyl methacrylate, isobutyl methacrylate, and isopropyl methacrylate, and
the (c) unit is 2,2,3,3-tetrafluoropropyl methacrylate.

6. The plastic rod lens according to claim 3,
wherein the content [a] of the (a) unit in the polymer mixture (II) is 10 mass % to 60 mass % at any position in a range of 0 to 0.5r from the center to the outer periphery, and
the content [c] of the (c) unit in the polymer mixture (II) is 5 mass % to 45 mass % at any position in a range of 0.8r to r from the center to the outer periphery.

7. The plastic rod lens according to claim 3,
wherein compositions of the constitutional units of the polymer mixture (II) satisfy the following expression (2) at any position in a range of 0.8r to r from the center to the outer periphery.
[c]<47.143−0.429[b] (2)
(wherein in the expression (2), [b] represents the content (mass %) of the constitutional unit (b); and [c] represents the content (mass %) of the constitutional unit (c))

8. The plastic rod lens according to claim 3,
wherein compositions of the constitutional units of the polymer mixture (II) satisfy the following expression (3) at any position in a range of 0 to 0.8r from the center to the outer periphery.
[c]<21.786−0.357[b] (3)
(wherein in the expression (3), [b] represents the content (mass %) of the constitutional unit (b); and [c] represents the content (mass %) of the constitutional unit (c))

9. The plastic rod lens according to claim 1,
wherein the polymer mixture (I) is a polymer mixture (III) which includes, as constitutional units, the (a) unit, the (b) unit, and the (d) unit,
refractive indices and Abbe numbers satisfy the following expression (4) at different arbitrary positions α and β in a range of 0 to r from the center to the outer periphery, and

|{n_{α}×ν_{α}/(n_{α}−1)}−{n_{β}×ν_{β}/(n_{β}−1)}|<5 (4)
(wherein n_{α} and n_{β} represent the refractive indices n_{D} at the positions α and β, respectively; and ν_{α} and ν_{β} represent the Abbe numbers at the positions α and β, respectively)
compositions of the constitutional units of the polymer mixture (III) satisfy the following expression (5) at any position in a range of 0 to r from the center to the outer periphery
0.5[b]−10<[a]<72.5−1.75 [b] (5)
(wherein, in the expression (5), [a] represents the content (mass %) of the constitutional unit (a); and [b] represents the content (mass %) of the constitutional unit (b))

10. The plastic rod lens according to claim 9,
wherein the polymer mixture (III) further includes a methyl methacrylate (m) unit as a constitutional unit.

11. The plastic rod lens according to claim 9,
wherein the (a) unit is phenyl methacrylate,
the (b) unit is at least one selected from a group consisting of t-butyl methacrylate, isobutyl methacrylate, and isopropyl methacrylate, and
the (d) unit is tricyclo[5.2.1.0^{2,6}]decanyl methacrylate.

12. The plastic rod lens according to claim 9,
wherein the content [a] of the (a) unit in the polymer mixture (III) is 5 mass % to 72.5 mass % and the content [b] of the (b) unit in the polymer mixture (III) is 2 mass % to 36.7 mass % in a range of 0.5r to r from the center to the outer periphery

13. A plastic rod lens array comprising
at least one rod lens line that is provided between two substrates,
wherein the rod lens line is formed by arranging a plurality of the plastic rod lenses according to claim 1 such that central axes of the plastic rod lenses are substantially parallel to each other.

14. A plastic rod lens array comprising
at least one rod lens line that is provided between two substrates,
wherein the rod lens line is formed by arranging a plurality of the plastic rod lenses according to claim 3 such that central axes of the plastic rod lenses are substantially parallel to each other.

15. A plastic rod lens array comprising
at least one rod lens line that is provided between two substrates,
wherein the rod lens line is formed by arranging a plurality of the plastic rod lenses according to claim 9 such that central axes of the plastic rod lenses are substantially parallel to each other.

16. A color image sensor head into which the plastic rod lens array according to claim 13 is incorporated.

17. An LED printer head into which the plastic rod lens array according to claim 13 is incorporated.

18. An LED printer head into which the plastic rod lens array according to claim 14 is incorporated.

19. A color image sensor head into which the plastic rod lens array according to claim 15 is incorporated.
